(19) United States
(12) Patent Application Publication
(10) Pub. No.: US 2023/0259027 A1
(43) Pub. Date: Aug. 17, 2023

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Masahiro Fukushima, Joetsu-shi (JP)

(73) Assignee: Shin-Etsu Chemical Co., Ltd., Tokyo (JP)

(21) Appl. No.: 18/095,221

(22) Filed: Jan. 10, 2023

(30) Foreign Application Priority Data
Jan. 27, 2022 (JP) 2022-010588
Oct. 17, 2022 (JP) 2022-166325

(51) Int. Cl. G03F 7/029; G03F 7/004; G03F 7/039; G03F 7/20

(52) U.S. Cl. CPC G03F 7/029; G03F 7/0048; G03F 7/0392; G03F 7/2006

(57) ABSTRACT

A resist composition comprising a sulfonim salt having an acid labile group of aromatic group-containing cyclic secondary or tertiary ester type in the cation as the acid generator exhibits a high sensitivity and reduced LWR or improved CDU.

### CROSS-REFERENCE TO RELATED APPLICATION

This non-provisional application claims priority under 35 U.S.C. §119(a) on Patent Application Nos. 2022-010588 and 2022-166325 filed in Japan on Jan. 27, 2022 and Oct. 17, 2022, respectively, the entire contents of which are hereby incorporated by reference.

### TECHNICAL FIELD

This invention relates to a resist composition and a patterning process using the composition.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To insure resolution for fine patterns of sub-45-nm size, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

For forming patterns of smaller size, it is necessary not only to suppress acid diffusion, but also to enhance dissolution contrast. For enhancing dissolution contrast, a base polymer of polarity switch type capable of generating a phenol or carboxy group through acid-catalyzed deprotection reaction is used. On use of a resist material containing this base polymer, it is possible to form both a positive pattern by alkaline development and a negative pattern by organic solvent development. The positive pattern is formed at a higher resolution because the alkaline development provides a higher dissolution contrast. The base polymer adapted to generate a carboxy group exhibits higher alkaline solubility and hence, a higher dissolution contrast than the base polymer adapted to generate a phenol group. For such reasons, the base polymer of carboxy generation type is often used.

There is known a non-chemically amplified resist material of backbone decomposition type comprising as the base polymer a copolymer of α-chloroacrylate with α-methylstyrene wherein the copolymer backbone is decomposed upon light exposure so that the copolymer reduces its molecular weight and turns more soluble in organic solvent developer. Although this resist material is devoid of the influence of acid diffusion, its dissolution contrast is low. The above-mentioned chemically amplified resist material having polarity switch function exhibits a higher resolution.

For further enhancing dissolution contrast, it is proposed to add an acid generator having a polarity switch function as well as the base polymer having a polarity switch function to the resist material. Patent Documents 3 and 4 disclose a resist material comprising a sulfonium salt having an acid labile group of tertiary ester type in the cation moiety. Patent Documents 5 and 6 disclose a resist material comprising a sulfonium salt having an acid labile group in the anion moiety. However, the acid labile groups of alicyclic structure and dimethylphenylcarbinol type described in these patent documents are still insufficient in dissolution contrast enhancement and swell suppression.

Citation List

| | |
|---|---|
| Patent Document 1: | JP-A 2006-045311 (USP 7482108) |
| Patent Document 2: | JP-A 2006-178317 |
| Patent Document 3: | JP-A 2011-006400 |
| Patent Document 4: | JP-A 2021-070692 |
| Patent Document 5: | JP-A 2014-224236 |
| Patent Document 6: | WO 2021/200056 |
| Non-Patent Document 1: | SPIE Vol. 6520 65203L-1 (2007) |

### SUMMARY OF INVENTION

For resist materials, it is desired to have an acid generator capable of improving the LWR of line patterns or the CDU of hole patterns and enhancing sensitivity. To this end, it is necessary to outstandingly improve the dissolution contrast during development.

An object of the present invention is to provide a resist composition, especially positive resist composition which exhibits a higher sensitivity and improved LWR or CDU, and a patterning process using the resist composition.

The inventors have found that a resist composition comprising a sulfonium salt having an acid labile group of aromatic group-containing cyclic secondary or tertiary ester type in the cation moiety exhibits excellent properties such as a high contrast and low swell by virtue of effective acid-catalyzed elimination reaction and high affinity to alkaline developer. The resist composition is improved in LWR, CDU, and resolution, and has a wide process margin.

In one aspect, the invention provides a resist composition comprising an acid generator containing a sulfonium salt having the formula (1).

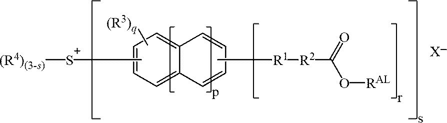

Herein p is 0 or 1, q is an integer of 0 to 4, r is 1 or 2, s is an integer of 1 to 3,
R¹ is a single bond, ether bond, thioether bond or ester bond,
R³ is a single bond or a C₁-C₂₀ alkanediyl group which may contain fluorine or hydroxy,
R³ is hydroxy, carboxy, nitro, cyano, fluorine, chlorine, bromine, iodine, amino, or a C₁-C₂₀ saturated hydrocarbyl group. C₁-C₂₀ saturated hydrocarbyloxy group, C₂-C₂₀ saturated hydrocarbylcarbonyloxy group, C₂-C₂₀ saturated hydrocarbyloxycarbonyl group, or C₁-C₄ saturated hydrocarbylsulfonyloxy group, which may contain at least one moiety selected from fluorine, chlorine, bromine, iodine, hydroxy, amino and ether bond,
R⁴ is a C₁-C₂₀ hydrocarbyl group which may contain a heteroatom, in case of s=l, two groups R⁴ may be the same or different and may bond together to form a ring with the sulfur atom to which they are attached,
X⁻ is a non-nucleophilic counter ion, and
R^{AL} is an acid labile group having any one of the formulae (AL-1) to (AL-4).

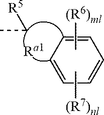

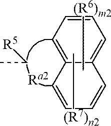

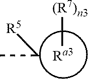

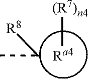

Herein ml is an integer of 0 to 4, n1 is an integer of 0 to 3, ml+nl is from 0 to 4, m2 is an integer of 0 to 6, n2 is an integer of 0 to 3, m2+n2 is from 0 to 6, n3 is an integer of 0 to 4, n4 is an integer of 0 to 4,
R⁵ is hydrogen, or a C₁-C₁₂ saturated hydrocarbyl group, C₂-C₈ alkenyl group, C₂-C₈ alkynyl group, or C₆-C₁₀ aryl group, which may contain oxygen or sulfur,
R⁶ is fluorine, iodine, an optionally fluorinated C₁-C₄ alkyl group, optionally fluorinated C₁-C₄ alkoxy group, or optionally fluorinated C₁-C₄ alkylthio group.
R⁷ is hydroxy, nitro, cyano, chlorine, bromine, amino, phenyl, a C₂-C₄ alkoxycarbonyl group, or C₁-C₄ alkylsulfonyl group, in case of n2=2 or 3, two groups R⁷ may bond together to form a ring with the carbon atoms to which they are attached,
R⁸ is a C₂-C₆ alkenyl group,
the arc R^{a1} is a C₂-C₁₀ tetravalent saturated hydrocarbon group which may contain oxygen, sulfur, nitrogen or a C₆-C₁₀ aromatic moiety in a carbon-carbon bond,
the arc R^{a2} is a C₂-C₁₀ tetravalent saturated hydrocarbon group which may contain oxygen, sulfur or nitrogen in a carbon-carbon bond,
the circle R^{a3} is a C₃-C₁₀ (n3+2)-valent alicyclic hydrocarbon group having a double bond in the ring and/or an alkylidene moiety bonded to a carbon atom in the ring,
the circle R^{a4} is a C₃-C₁₀ (n4+2)-valent cyclic saturated hydrocarbon group, and
the broken line designates a valence bond.

In a preferred embodiment, the non-nucleophilic counter ion is a sulfonate, imide or methide anion.

Preferably, ml is an integer of 1 to 4 and m2 is an integer of 1 to 6.

The resist composition may further comprise an organic solvent and/or a surfactant.

The resist composition may further comprise a base polymer. Preferably, the base polymer comprises repeat units having the formula (al) or repeat units having the formula (a2).

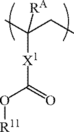

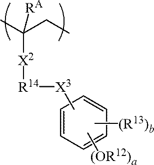

Herein R^{A} is each independently hydrogen or methyl,
X¹ is a single bond, phenylene, naphthylene, or a C₁-C₁₂ linking group containing at least one moiety selected from an ester bond, ether bond and lactone ring,
X² is a single bond or ester bond,
X³ is a single bond, ether bond or ester bond,
R¹¹ and R¹² are each independently an acid labile group,
R¹³ is fluorine, trifluoromethyl, cyano, a Ci-Cs saturated hydrocarbyl group, C₁-C₆ saturated hydrocarbyloxy group, C₂-C₇ saturated hydrocarbylcarbonyl group. C₂-C₇ saturated hydrocarbylcarbonyloxy group, or C₂-C₇ saturated hydrocarbyloxycarbonyl group,
R¹⁴ is a single bond or a C₁-C₆ alkanediyl group in which some constituent -CH₂-may be replaced by an ether bond or ester bond,
a is 1 or 2, b is an integer of 0 to 4, and a+b is from 1 to 5.

The resist composition is typically a chemically amplified positive resist composition.

In a preferred embodiment, the base polymer comprises repeat units of at least one type selected from repeat units having the formulae (f1) to (f3).

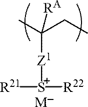

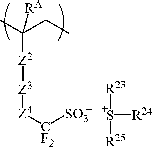

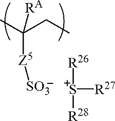

Herein R^{A} is each independently hydrogen or methyl,
Z¹ is a single bond, a C₁-C₆ aliphatic hydrocarbylene group, phenylene, naphthylene or a C₇-C₁₈ group obtained by combining the foregoing, or —O—Z¹¹—, —C(═O)—O—Z¹¹—or —C(═O)—NH—Z¹¹, wherein Z¹¹ is a C₁-C₆ aliphatic hydrocarbylene group, phenylene, naphthylene or a C₇-C₁₈ group obtained by combining the foregoing, which may contain a carbonyl moiety, ester bond, ether bond or hydroxy moiety,
Z² is a single bond or ester bond,
Z³ is a single bond, —Z³¹—C(═O)—O—, —Z³¹—O— or —Z³¹—O—C(═O)—, wherein Z³¹ is a C₁-C₁₂ hydrocarbylene group, phenylene or a C₇-C₁₈ group obtained by combining the foregoing, which may contain a carbonyl moiety, ester bond, ether bond, iodine or bromine,
Z⁴ is methylene, 2,2,2-trifluoro-1,1-ethanediyl or carbonyl,
Z⁵ is a single bond, methylene, ethylene, phenylene, fluorinated phenylene, trifluoromethyl-substituted phenylene, —O—Z⁵¹—, —C(═O)—O—Z⁵¹—, or —C(═O)—NTH—Z⁵¹—, wherein Z⁵¹ is a C₁-C₆ aliphatic hydrocarbylene group, phenylene, fluorinated phenylene, or trifluoromethyl-substituted phenylene group, which may contain a carbonyl moiety, ester bond, ether bond, hydroxy moiety or halogen,
R²¹ to R²⁸ are each independently halogen or a C₁-C₂₀ hydrocarbyl group which may contain a heteroatom, a pair of R²³ and R²⁴, or R²⁶ and R²⁷ may bond together to form a ring with the sulfur atom to which they are attached, and
M⁻ is a non-nucleophilic counter ion.

In another aspect, the invention provides a pattern forming process comprising the steps of applying the resist composition defined herein onto a substrate to form a resist film thereon, exposing the resist film to high-energy radiation, and developing the exposed resist film in a developer.

The high-energy radiation is typically KrF excimer laser, ArF excimer laser, EB, or EUV of wavelength 3 to 15 nm.

### ADVANTAGEOUS EFFECTS OF INVENTION

In the resist composition comprising a sulfonium salt having formula (1) and a base polymer containing an acid labile group, an acid is generated upon exposure, like conventional acid generators, and a polarity switch occurs due to the acid-catalyzed reaction whereby the alkali dissolution rate is increased. In the unexposed region, the acid generator itself is not dissolved in the developer. In the exposed region, a carboxy group is generated under the action of the acid generated by the acid generator whereby the alkali dissolution rate is increased. Accordingly, a resist composition having improved LWR or CDU is constructed.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, the broken line designates a valence bond; Me stands for methyl, and Ac for acetyl. As used herein, the term “fluorinated” refers to a fluorine-substituted or fluorine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
CDU: critical dimension uniformity

### Resist Composition

The resist composition of the invention comprises an acid generator containing a sulfonium salt having an acid labile group of aromatic group-containing cyclic secondary or tertiary ester type in the cation.

### Sulfonium Salt

The sulfonium salt having an acid labile group of aromatic group-containing cyclic secondary or tertiary ester type in the cation is represented by the formula (1).

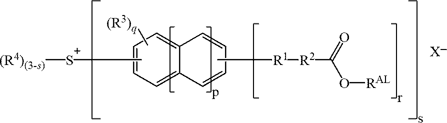

In formula (1), p is 0 or 1, q is an integer of 0 to 4, r is 1 or 2, and s is an integer of 1 to 3.

In formula (1), R¹ is a single bond, ether bond, thioether bond or ester bond, preferably an ether bond or ester bond.

In formula (1), R² is a single bond or a C₁-C₂₀ alkanediyl group which may contain fluorine or hydroxy. Examples of the alkanediyl group include methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, decane-1,10-diyl, undecane-1,11-diyl, and dodecane-1,2-diyl.

In formula (1), R³ is hydroxy, carboxy, nitro, cyano, fluorine, chlorine, bromine, iodine, amino, or a C₁-C₂₀ saturated hydrocarbyl group. C₁-C₂₀ saturated hydrocarbyloxy group, C₂-C₂₀ saturated hydrocarbylcarbonyloxy group, C₂-C₂₀ saturated hydrocarbyloxycarbonyl group, or C₁-C₄ saturated hydrocarbylsulfonyloxy group, which may contain at least one moiety selected from fluorine, chlorine, bromine, iodine, hydroxy, amino and ether bond.

The saturated hydrocarbyl group and saturated hydrocarbyl moiety of the saturated hydrocarbyloxy group, saturated hydrocarbylcarbonyloxy group, saturated hydrocarbyloxycarbonyl group, and saturated hydrocarbylsulfonyloxy group, represented by R³, may be straight, branched or cyclic. Examples thereof include alkyl groups such as methyl, ethyl, n-propyl, isopropyl, n-butyl, isobutyl, sec-butyl, tert-butyl, n-pentyl, neopentyl, n-hexyl, n-heptyl, n-octyl, 2-ethylhexyl n-nonyl, n-decyl, n-undecyl, n-dodecyl, n-tridecyl, n-pentadecyl, and n-hexadecyl; and cyclic saturated hydrocarbyl groups such as cyclopentyl and cyclohexyl.

In formula (1), R⁴ is a C₁-C₂₀ hydrocarbyl group which may contain a heteroatom. The hydrocarbyl group may be saturated or unsaturated and straight, branched or cyclic. Examples thereof include C₁-C₂₀ saturated hydrocarbyl groups, C₂-C₂₀ unsaturated aliphatic hydrocarbyl groups, C₆-C₂₀ aryl groups, and C₇-C₂₀ aralkyl groups, and combinations thereof.

The saturated hydrocarbyl group may be straight, branched or cyclic. Examples thereof include alkyd groups such as methyl, ethyl, n-propyl, isopropyl, n-butyl, isobutyl sec-butyl, tert-butyl, n-pentyl, neopentyl, n-hexyl, n-heptyl, n-octyl, 2-ethylhexyl, n-nonyl, n-decyl, n-undecyl, n-dodecyl, n-tridecyl, n-pentadecyl, and n-hexadecyl; and cyclic saturated hydrocarbyl groups such as cyclopentyl and cyclohexyl.

The unsaturated aliphatic hydrocarbyl group may be straight, branched or cyclic. Examples thereof include alkenyl groups such as vinyl, 1-propenyl, 2-propenyl, butenyl, and hexenyl; alkynyl groups such as ethynyl, propynyl and butynyl; and cyclic unsaturated hydrocarbyl groups such as cyclohexenyl.

Examples of the aryl group include phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, and tert-butylnaphthyl.

Exemplary of the aralkyl group are benzyl and phenethyl.

In the foregoing hydrocarbyl groups, some or all of the hydrogen atoms may be substituted by a moiety containing a heteroatom such as oxygen, sulfur, nitrogen or halogen, and some constituent -CH₂- may be replaced by a moiety containing a heteroatom such as oxygen, sulfur or nitrogen, so that the group may contain a hydroxy, carboxy, halogen, cyano, amino, nitro, sultone ring, sulfo, sulfonium salt-containing moiety, ether bond, ester bond, carbonyl, sulfide bond, sulfonyl, or amide bond.

In case of s=1, two groups R⁴ may be the same or different and may bond together to form a ring with the sulfur atom to which they are attached. Examples of the ring are shown below.

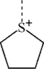

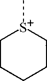

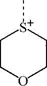

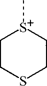

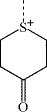

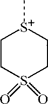

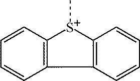

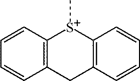

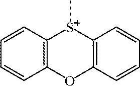

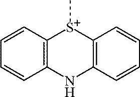

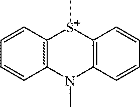

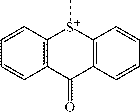

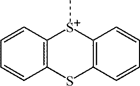

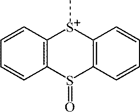

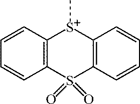

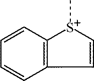

Herein the broken line designates a point of attachment to the aromatic ring in formula (1).

In formula (1), R^{AL} is an acid labile group having any one of the formulae (AL-1) to (AL-4).

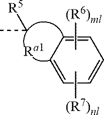

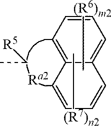

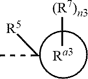

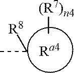

In formulae (AL-1) to (AL-4), m1 is an integer of 0 to 4, n1 is an integer of 0 to 3, m1+n1 is from 0 to 4, m2 is an integer of 0 to 6, n2 is an integer of 0 to 3, m2+n2 is from 0 to 6, n3 is an integer of 0 to 4, and n4 is an integer of 0 to 4.

In formulae (AL-1) to (AL-3), R⁵ is hydrogen, or a C₁-C₁₂ saturated hydrocarbyl group, C₂₋C₈ alkenyl group, C₂-C₈ alkynyl group, or C₆-C₁₀ aryl group, which may contain oxygen or sulfur.

Of the groups represented by R⁵, the C₁-C₁₂ saturated hydrocarbyl group may be straight, branched or cyclic. Examples thereof include C₁-C₁₂ alkyl groups such as methyl, ethyl, n-propyl, isopropyl, n-butyl, isobutyl, sec-butyl, tert-butyl, n-pentyl, neopentyl, and n-hexyl; and C₃-C₁₂ cyclic saturated hydrocarbyl groups such as cyclopropyl, cyclobutyl, cyclopentyl and cyclohexyl. Examples of the C₂-C₈ alkenyl group include vinyl, 1 -propenyl, 2-propenyl, butenyl and hexenyl. Examples of the C₂-C₈ alkynyl group include ethynyl and butynyl. Examples of the C₆-C₁₀ aryl group include phenyl and naphthyl.

In formulae (AL-1) and (AL-2), R⁶ is fluorine, iodine, an optionally fluorinated C₁-C₄ alkyl group, optionally fluorinated C₁-C₄ alkoxy group, or optionally fluorinated C₁-C₄ alkylthio group. R⁶ is preferably fluorine, a fluorinated C₁-C₄ alkyd group, fluorinated C₁-C₄ alkoxy group, or fluorinated C₁-C₄ alkylthio group. Inclusion of a fluorinated acid labile group in the cation ensures a high dissolution contrast.

In formulae (AL-1 ) to (AL-4), R⁷ is hydroxy, nitro, cyano, chlorine, bromine, amino, phenyl, a C₂-C₄ alkoxycarbonyl group, or C₁-C₄ alkylsulfonyl group. In case of n2=2 or 3, two groups R⁷ may bond together to form a ring with the carbon atoms to which they are attached.

In formula (AL-4). R⁸ is a C₂-C₆ alkenyl group. Examples thereof include vinyl, 1-propenyl, 2-propenyl, butenyl and hexenyl.

In formula (AL-1), the arc R^{a1} is a C₂-C₁₀ tetravalent saturated hydrocarbon group which may contain oxygen, sulfur, nitrogen or a C₆-C₁₀ aromatic moiety in a carbon-carbon bond (or between carbon atoms). In formula (AL-2), the arc R^{a2} is a C₂-C₁₀ tetravalent saturated hydrocarbon group which may contain oxygen, sulfur or nitrogen in a carbon-carbon bond. Examples of the tetravalent saturated hydrocarbon group include groups obtained by removing two hydrogen atoms on a common carbon atom from alkanediyl groups such as methanediyl, ethane-1,2-diyl, propane-1,3-diyl, butane-1,4-diyl, pentane-1.5-diyl, hexane-1.6-diyl, heptane-1,7-diyl, octane-1,8-diyl, nonane-1,9-diyl, and decane-1,10-diyl.

In formula (AL-3), the circle R^{a3} is a C₃-C₁₀ (n3+2)-valent alicyclic hydrocarbon group having a double bond in the ring and/or an alkylidene moiety bonded to a carbon atom in the ring. Examples thereof include groups derived from cycloalkenes such as cyclopropene, cyclobutene, cyclopentene, and cyclohexene; groups derived from cycloalkanes such as cyclopropane, cyclobutane, cyclopentane and cyclohexane, which are substituted with an alkylidene moiety such as methylidene; and groups derived from cycloalkenes substituted with an alkylidene moiety.

In formula (AL-4), the circle R^{a4} is a C₃-C₁₀ (n4+2)-valent cyclic saturated hydrocarbon group. Examples thereof include groups derived from cycloalkanes such as cyclopropane, cyclobutane, cyclopentane and cyclohexane.

R^{AL} is preferably a group of formula (AL-1) wherein ml is an integer of 1 to 4, a group of formula (AL-2) wherein m2 is an integer of 1 to 6, a group of formula (AL-3) wherein n3 is an integer of 1 to 4, or a group of formula (AL-4) wherein n4 is an integer of 1 to 4.

The base polymer and the sulfonium salt turn soluble in alkaline developer as a result of their acid labile groups undergoing acid-catalyzed deprotection reaction, whereby a higher dissolution contrast is achieved. As a result, a higher sensitivity is achieved as well as a reduced LWR or improved CDU. Since the exposure dose achieving an improvement in the solubility of the base polymer via deprotection reaction is equal to the exposure dose for causing the sulfonium salt to be dissolved, a significant improvement in contrast is achievable.

Where the acid labile group in the base polymer and the acid labile group in the sulfonium salt are of the same structure, the sulfonium salt located in proximity to the takes place simultaneously, the sulfonium salt having a lower molecular weight turns soluble in alkaline developer on the side of lower exposure dose. In the case of a conventional sulfonium salt substituted with an acid labile group, which is similar to the acid labile group on the base polymer, there exists a gap in deprotection reactivity between the base polymer and the sulfonium salt and so, the dissolution contrast-improving effect is low.

For eliminating the gap in deprotection reactivity between the base polymer and the sulfonium salt, it is preferred in the practice of the invention to use in the sulfonium salt an acid labile group of lower deprotection reactivity than the acid labile group in the base polymer. In the case of aromatic group-containing acid labile groups, for example, their deprotection reactivity can be adjusted low by introducing an electron withdrawing group such as halogen, cyano or nitro into the aromatic group or changing the bond with ester to a secondary bond.

Examples of the cation of the sulfonium salt having formula (1) are shown below, but not limited thereto.

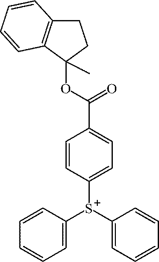

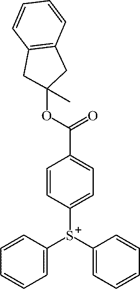

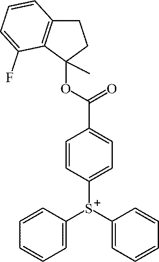

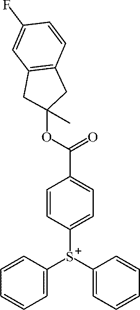

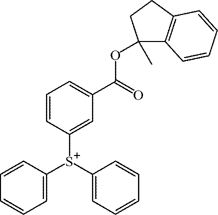

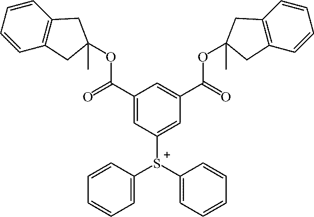

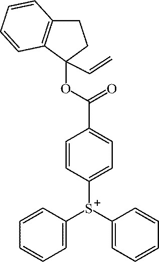

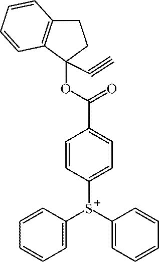

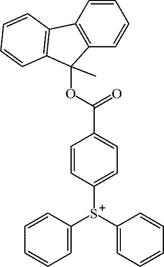

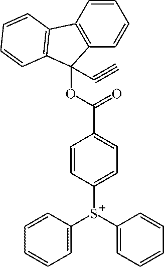

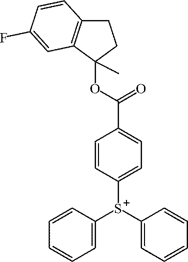

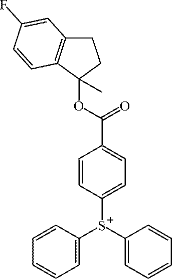

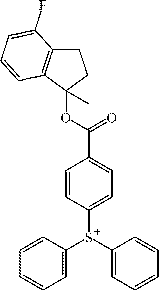

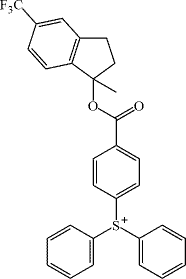

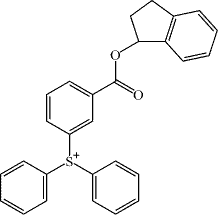

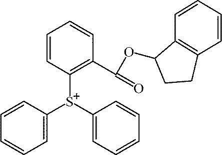

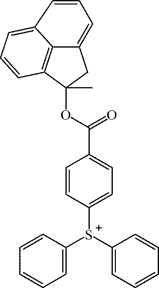

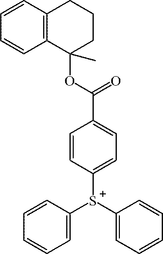

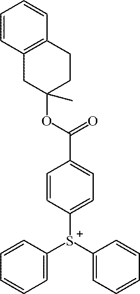

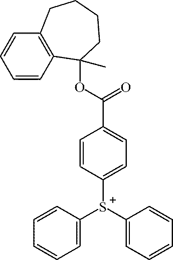

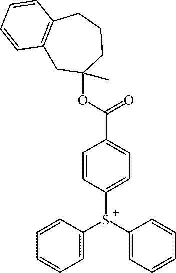

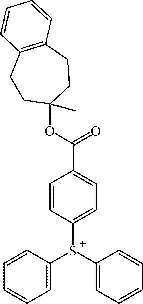

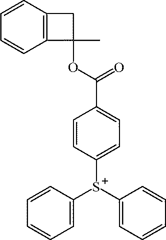

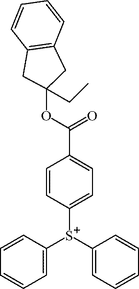

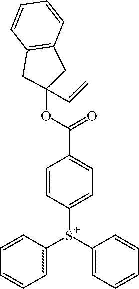

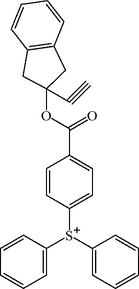

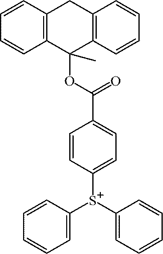

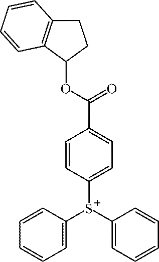

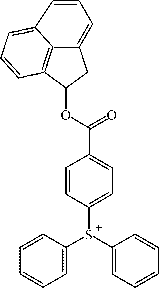

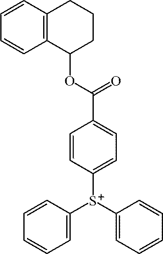

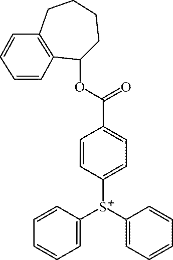

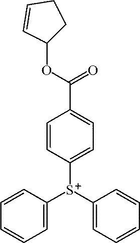

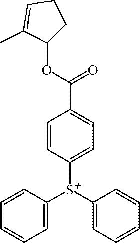

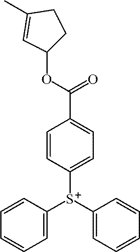

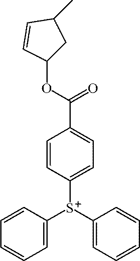

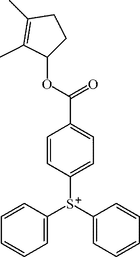

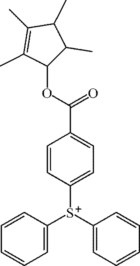

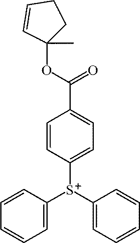

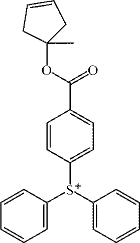

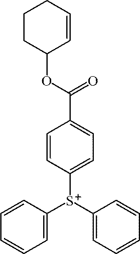

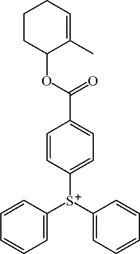

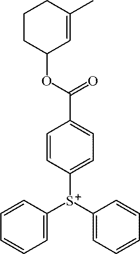

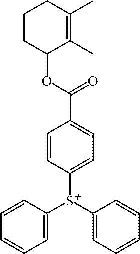

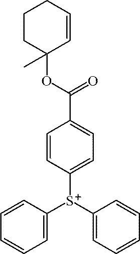

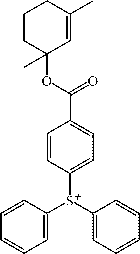

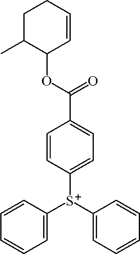

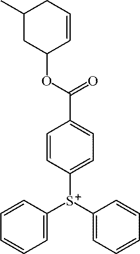

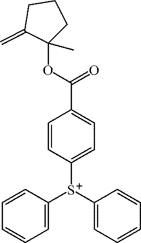

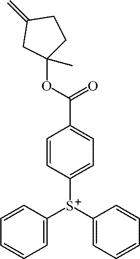

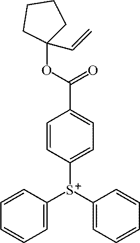

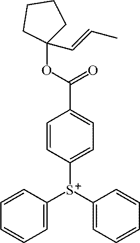

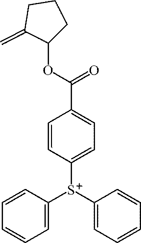

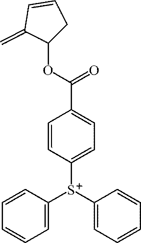

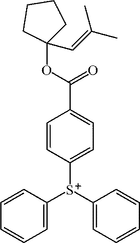

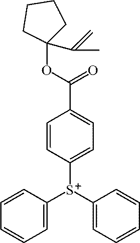

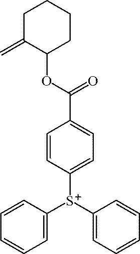

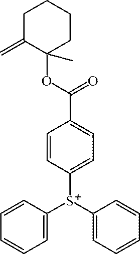

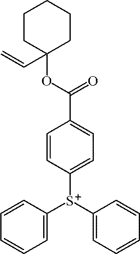

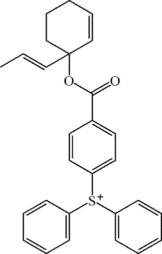

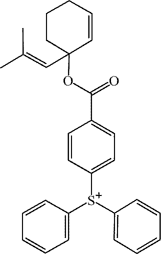

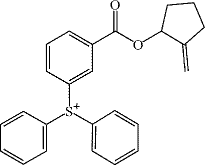

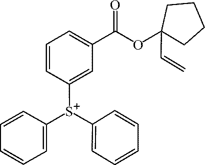

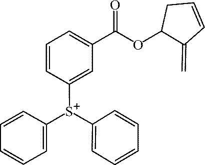

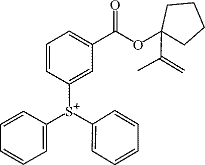

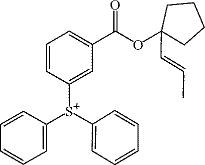

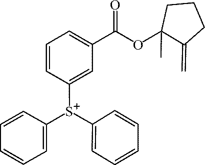

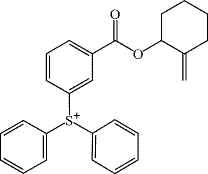

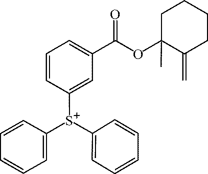

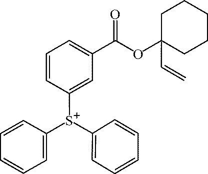

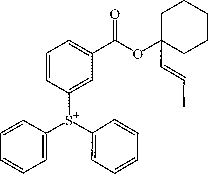

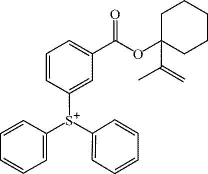

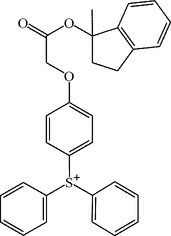

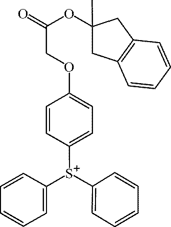

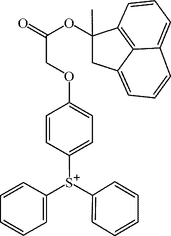

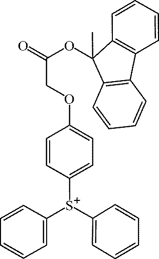

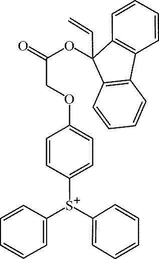

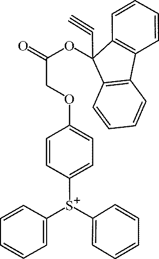

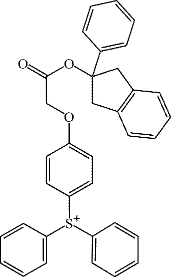

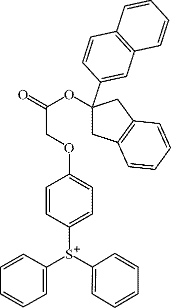

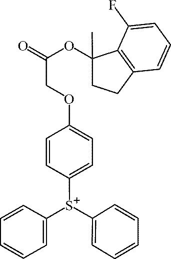

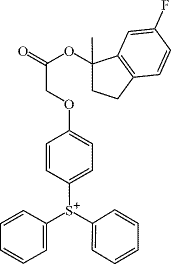

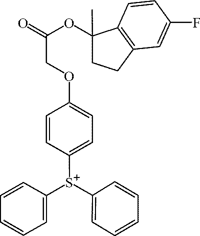

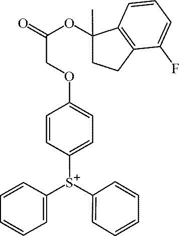

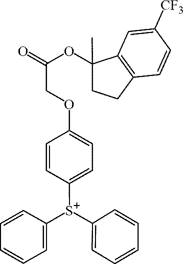

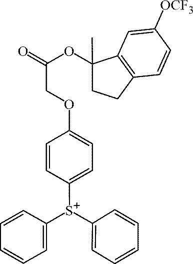

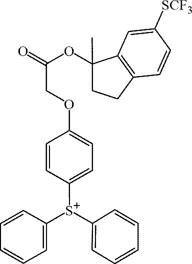

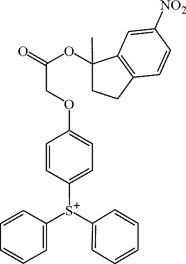

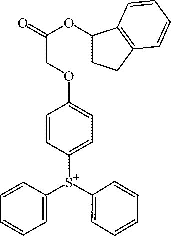

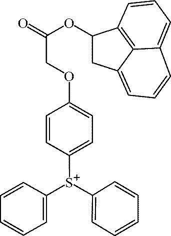

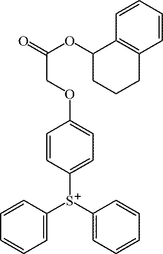

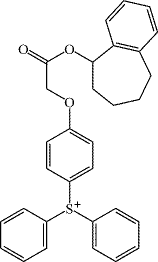

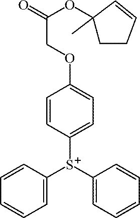

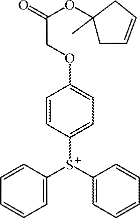

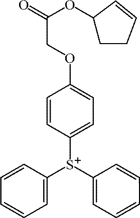

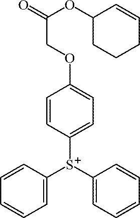

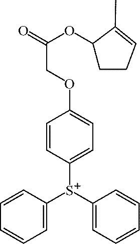

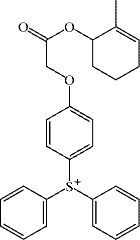

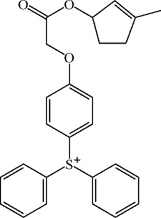

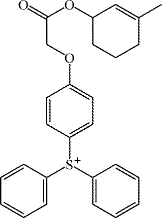

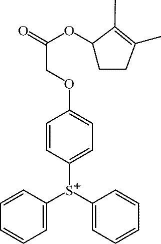

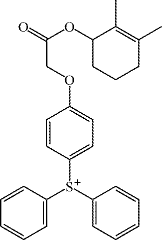

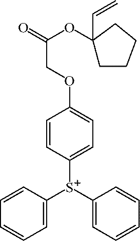

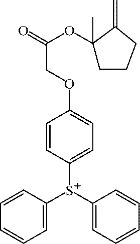

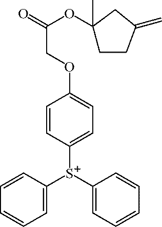

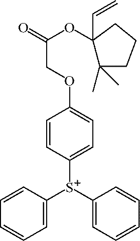

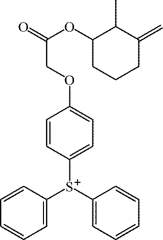

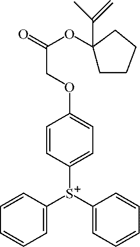

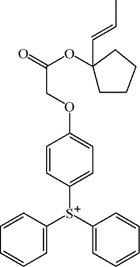

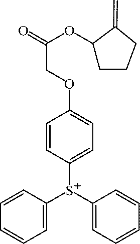

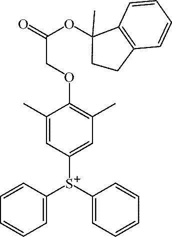

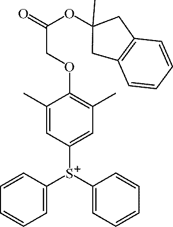

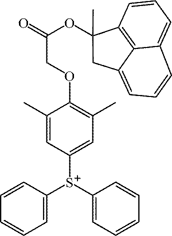

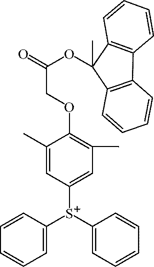

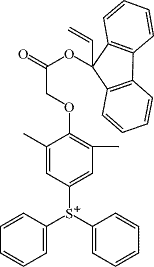

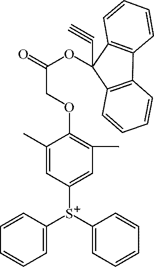

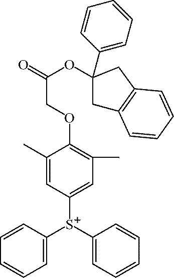

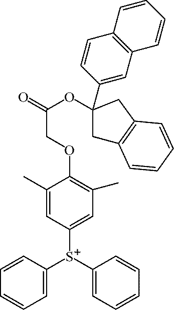

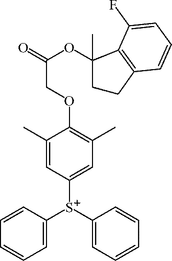

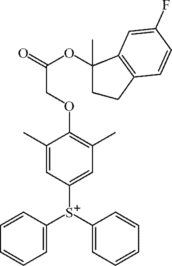

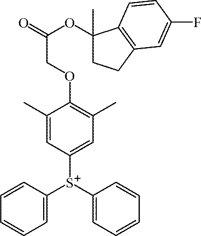

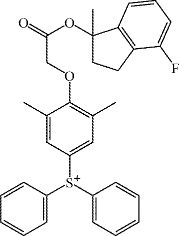

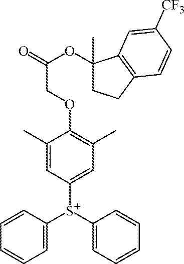

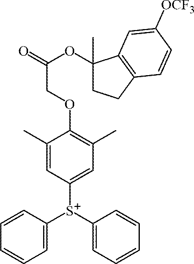

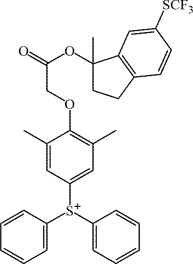

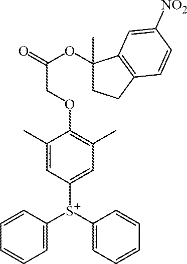

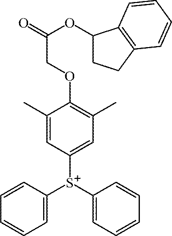

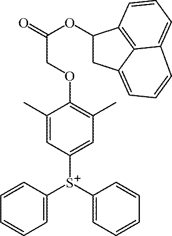

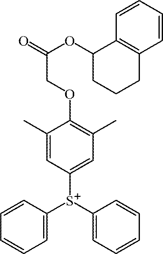

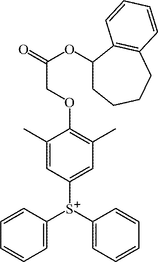

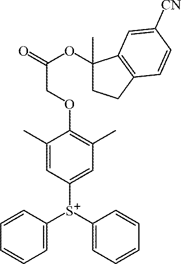

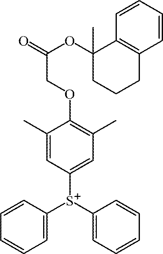

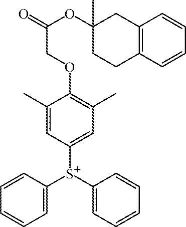

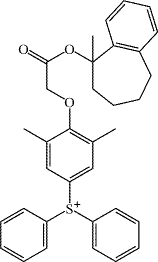

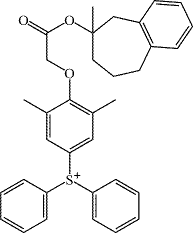

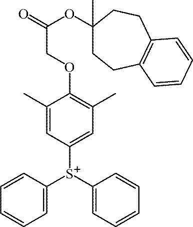

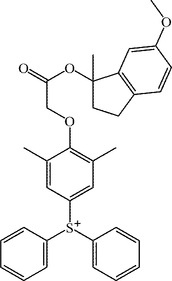

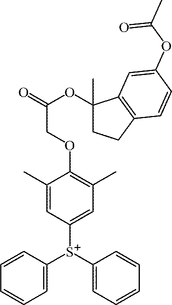

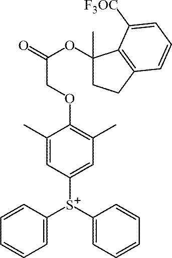

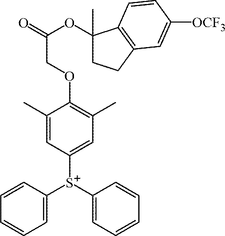

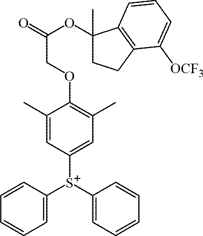

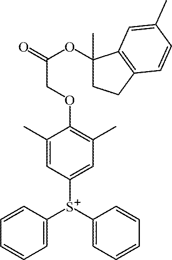

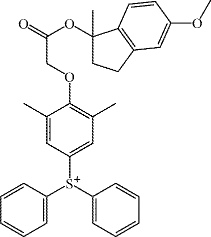

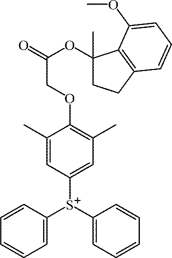

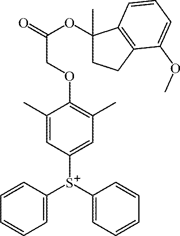

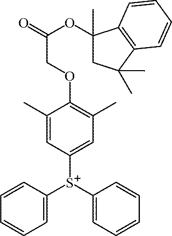

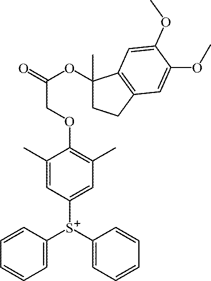

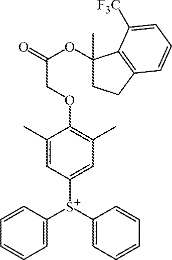

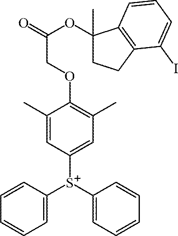

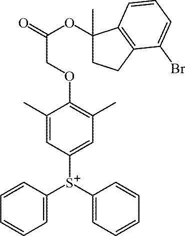

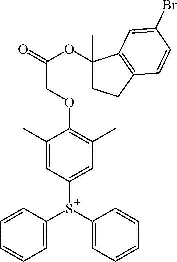

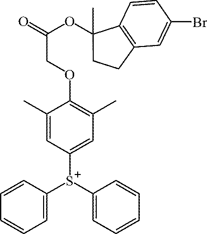

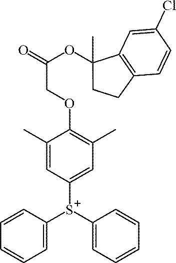

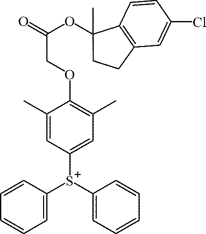

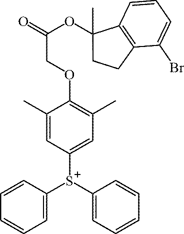

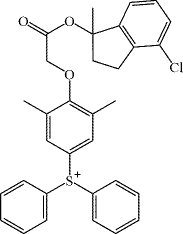

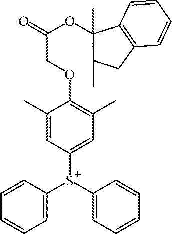

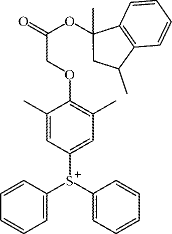

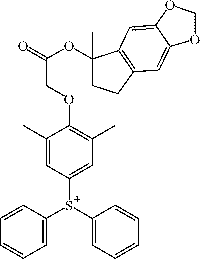

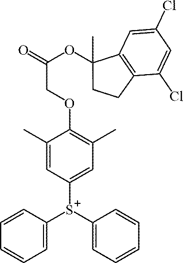

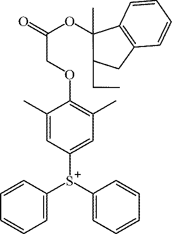

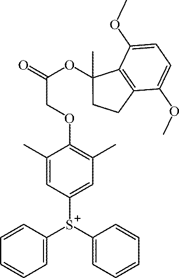

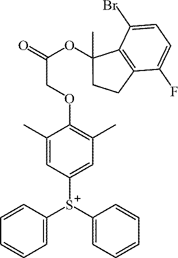

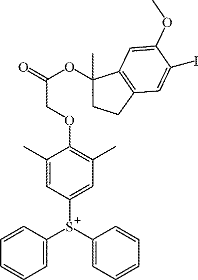

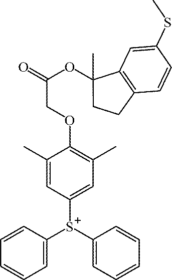

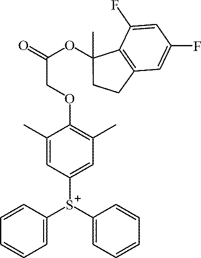

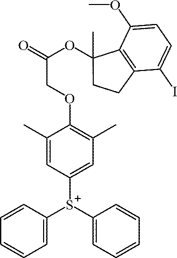

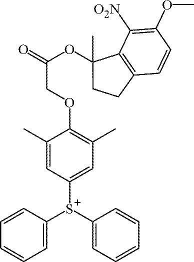

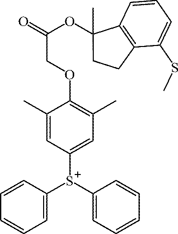

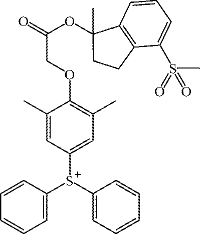

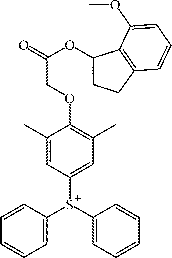

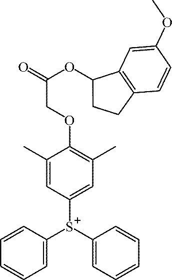

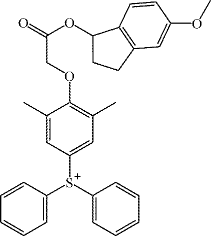

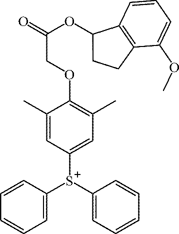

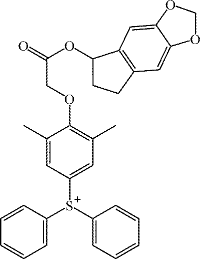

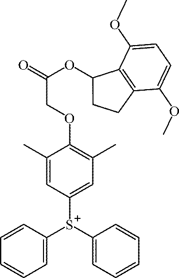

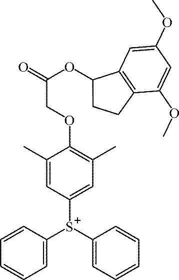

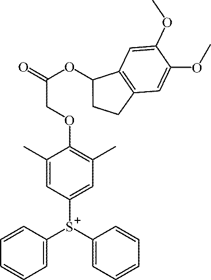

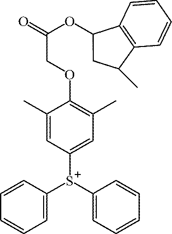

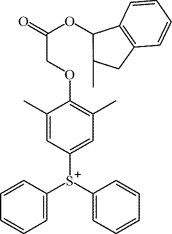

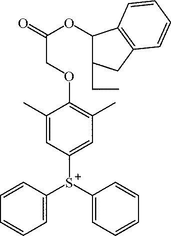

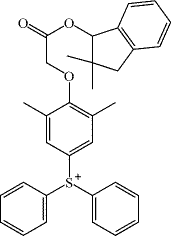

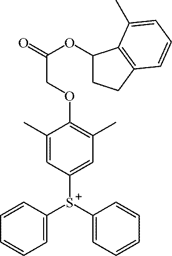

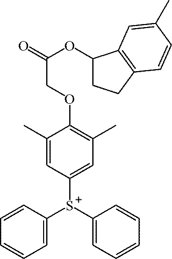

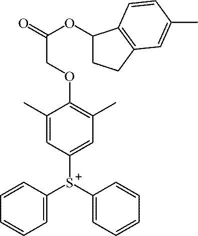

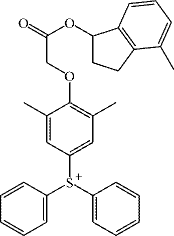

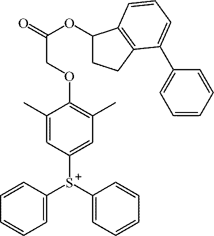

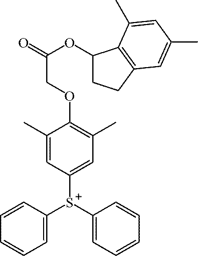

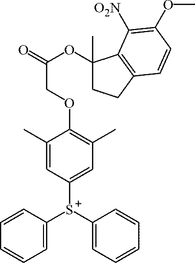

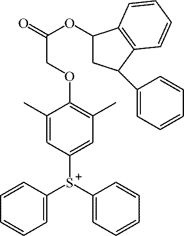

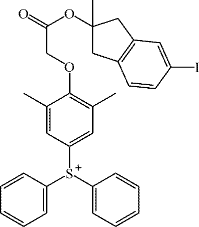

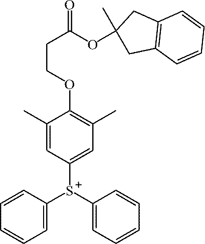

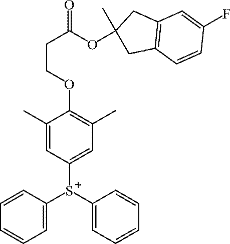

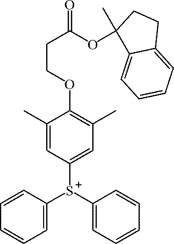

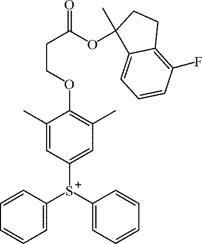

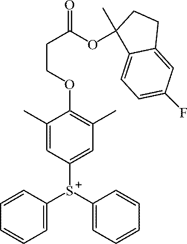

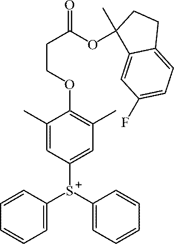

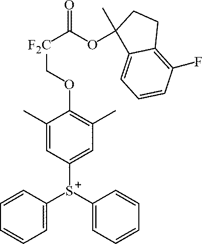

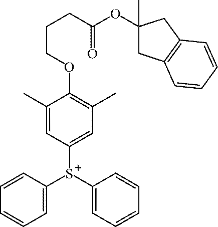

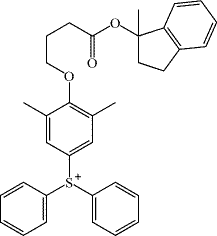

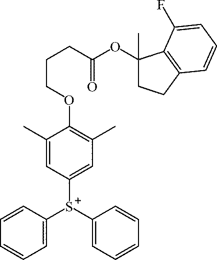

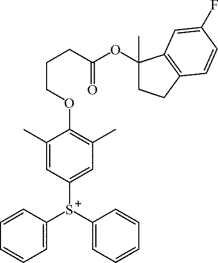

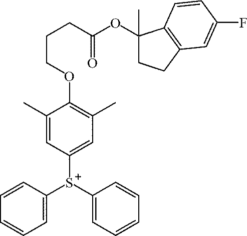

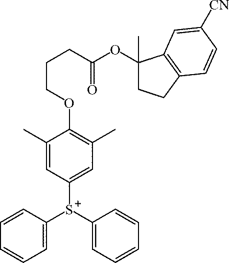

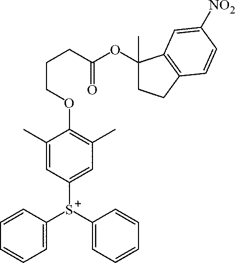

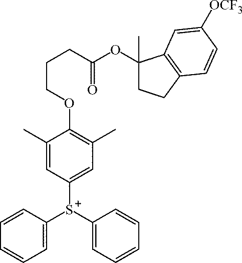

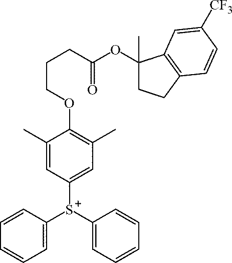

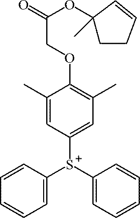

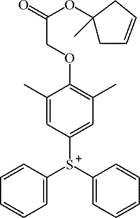

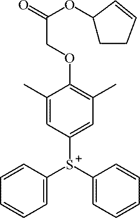

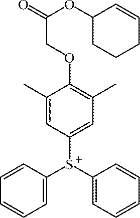

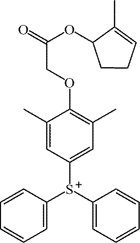

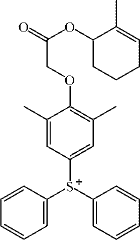

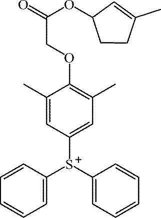

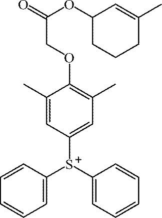

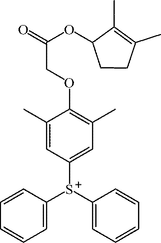

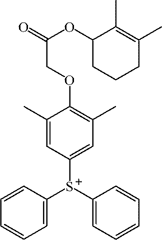

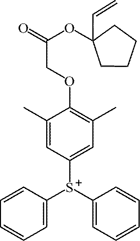

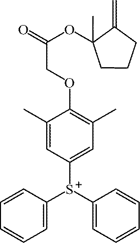

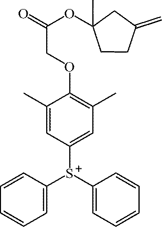

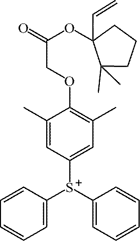

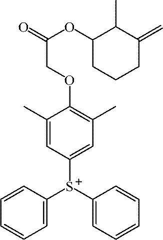

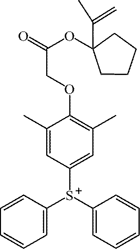

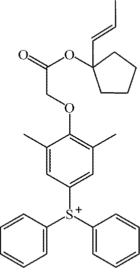

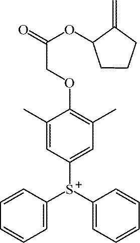

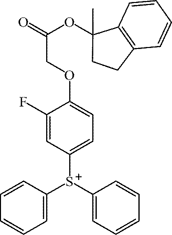

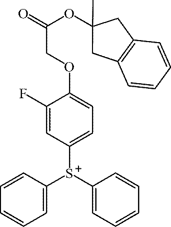

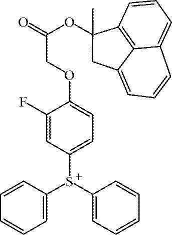

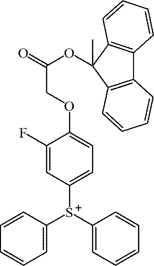

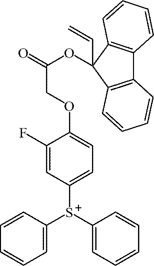

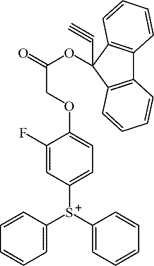

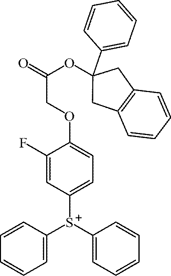

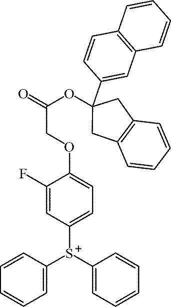

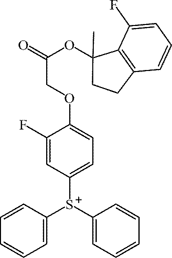

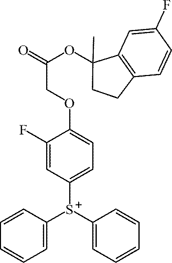

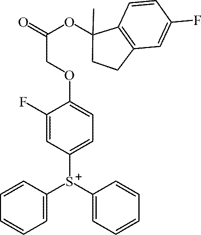

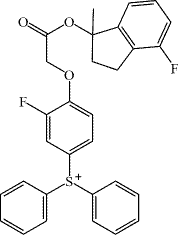

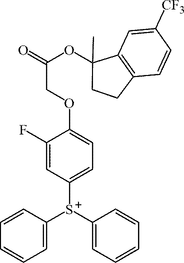

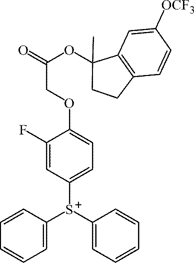

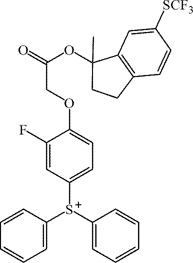

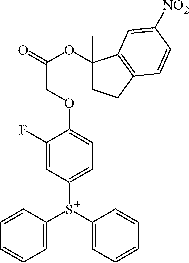

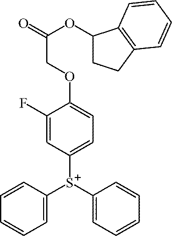

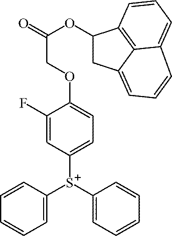

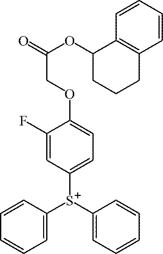

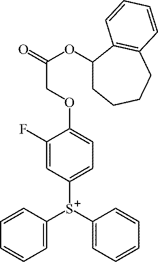

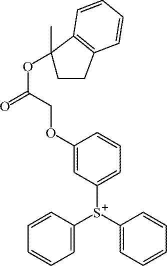

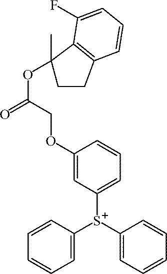

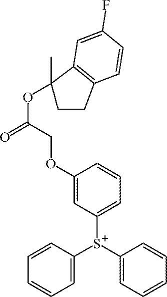

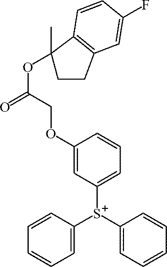

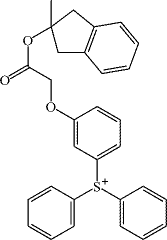

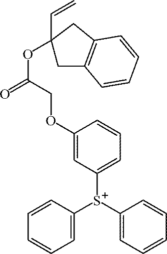

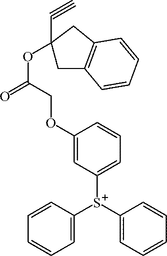

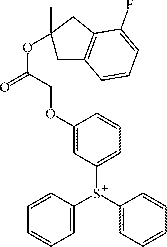

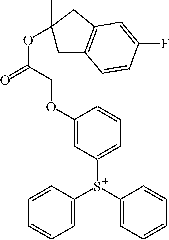

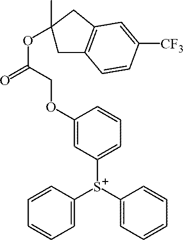

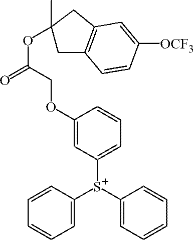

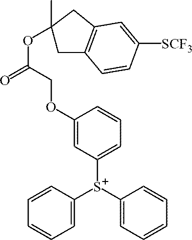

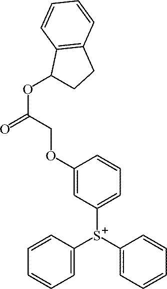

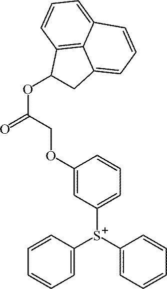

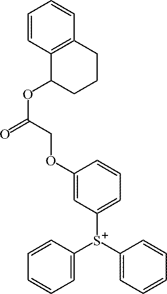

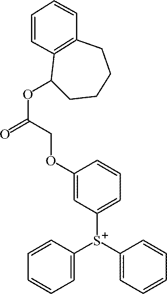

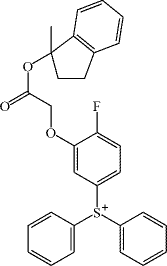

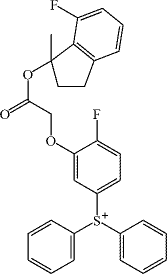

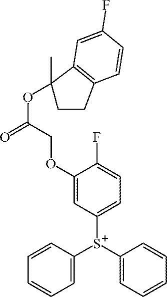

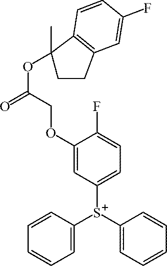

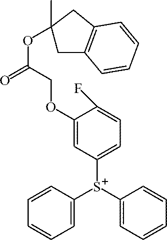

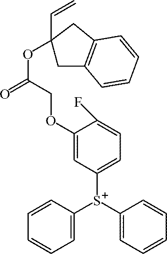

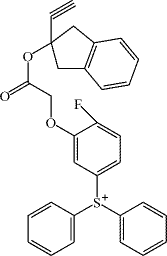

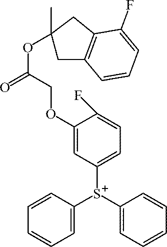

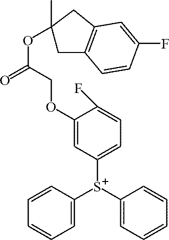

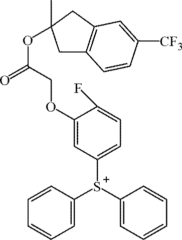

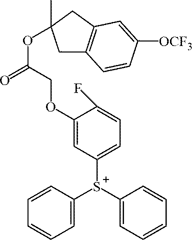

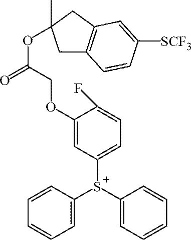

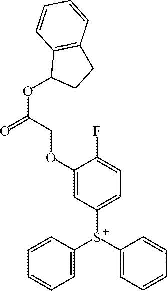

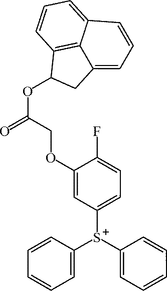

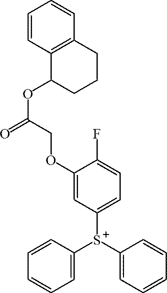

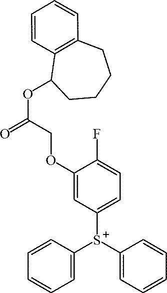

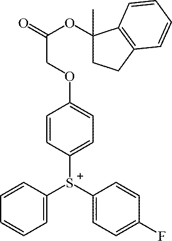

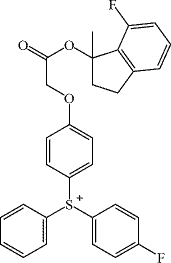

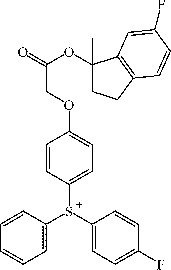

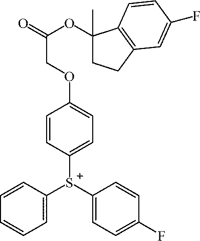

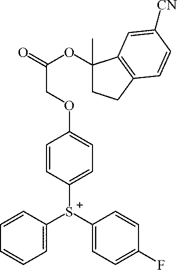

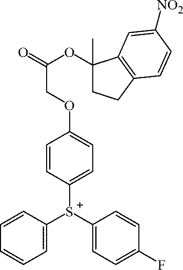

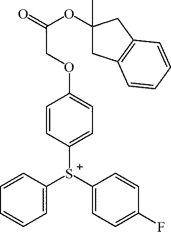

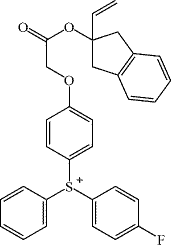

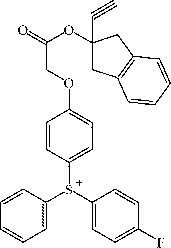

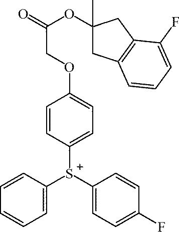

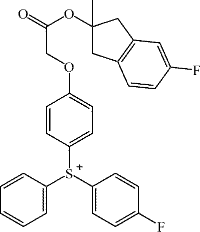

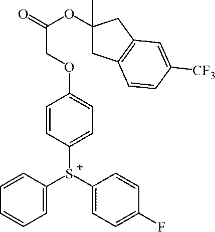

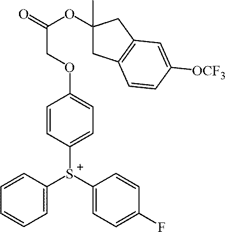

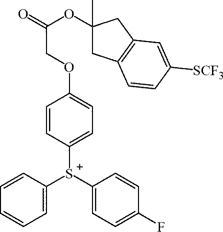

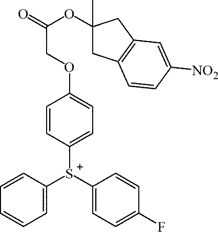

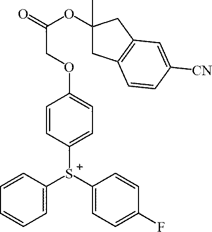

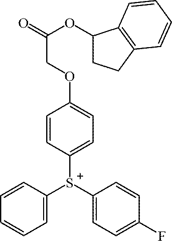

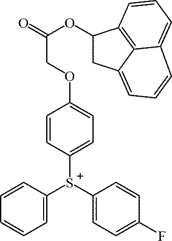

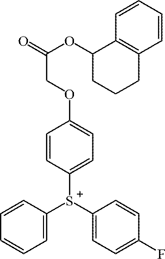

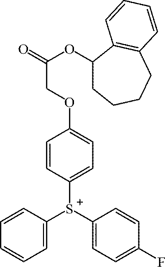

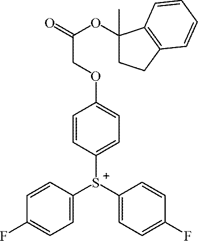

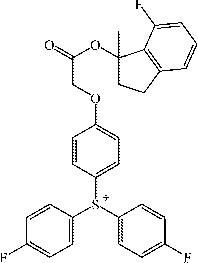

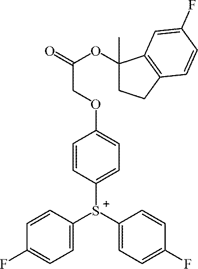

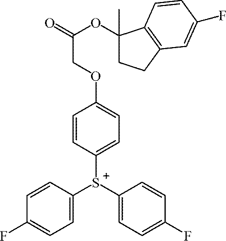

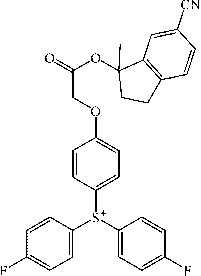

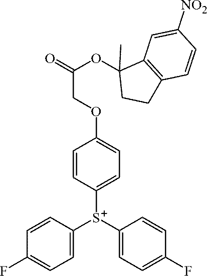

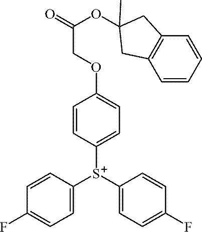

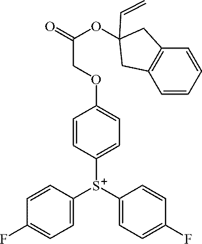

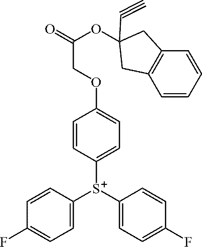

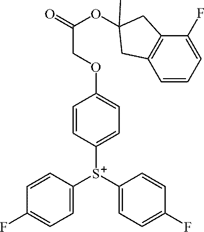

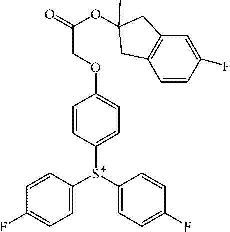

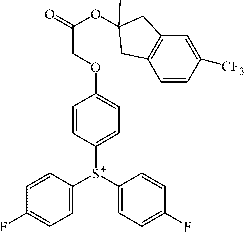

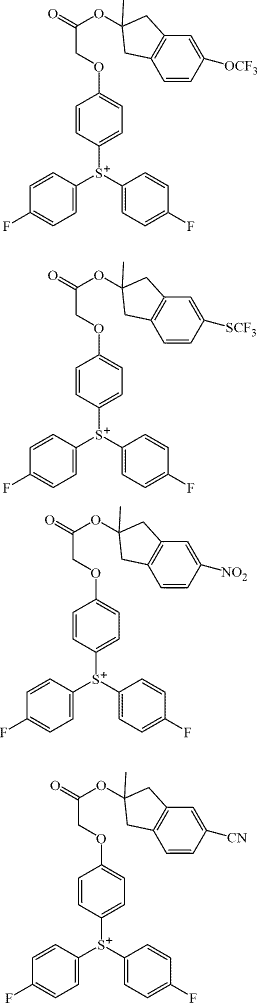

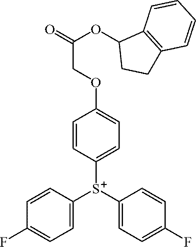

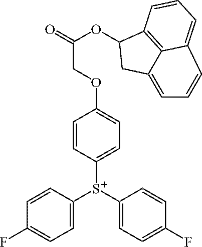

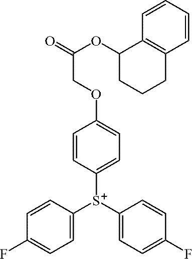

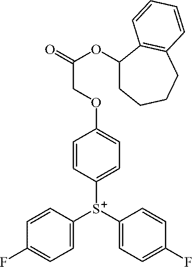

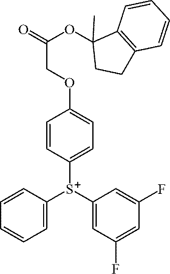

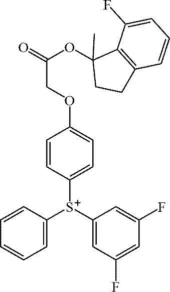

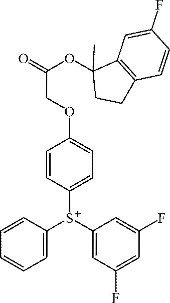

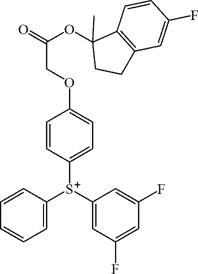

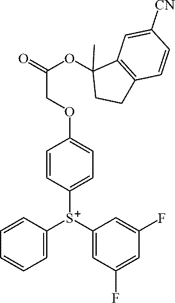

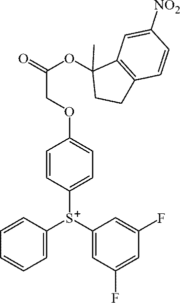

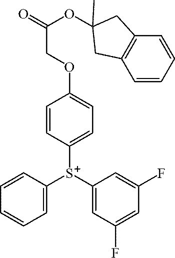

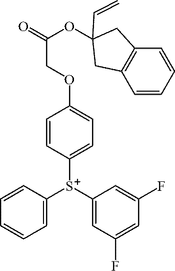

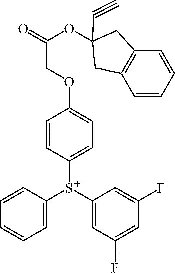

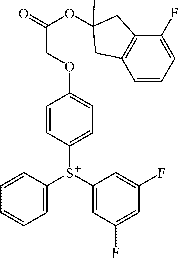

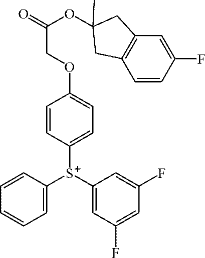

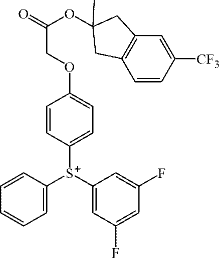

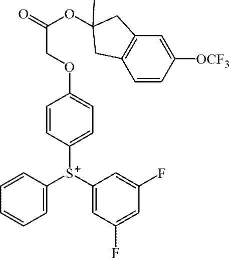

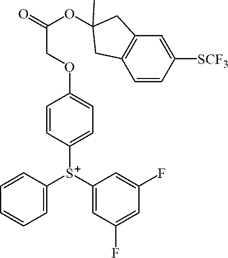

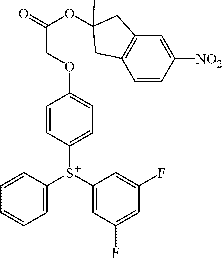

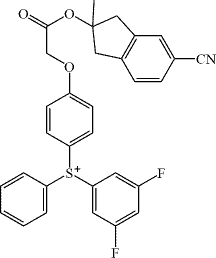

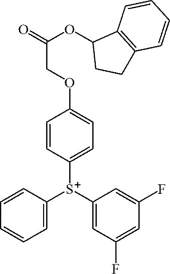

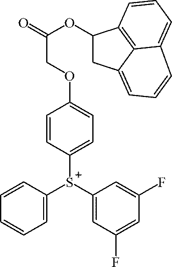

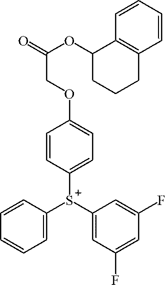

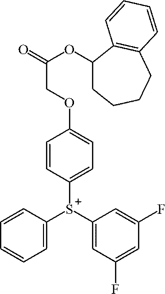

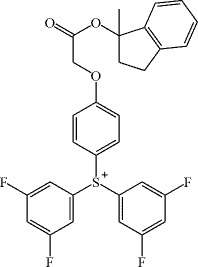

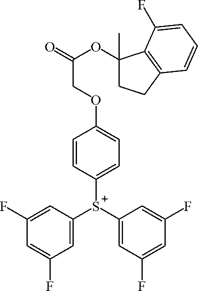

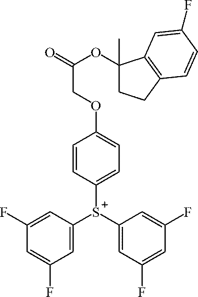

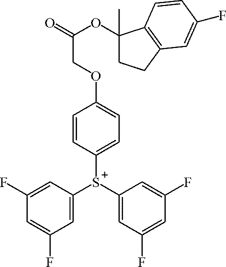

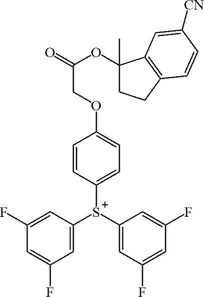

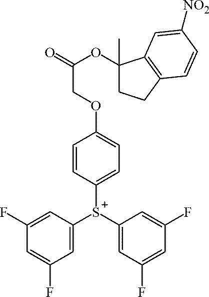

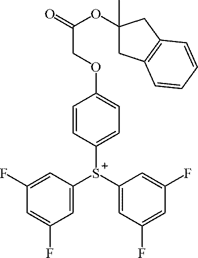

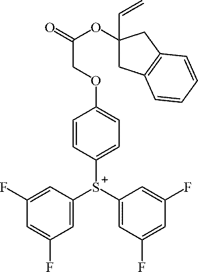

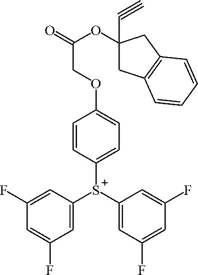

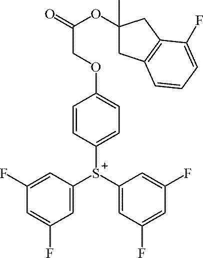

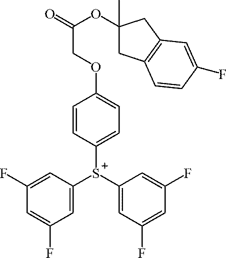

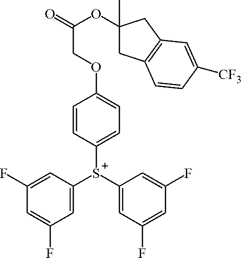

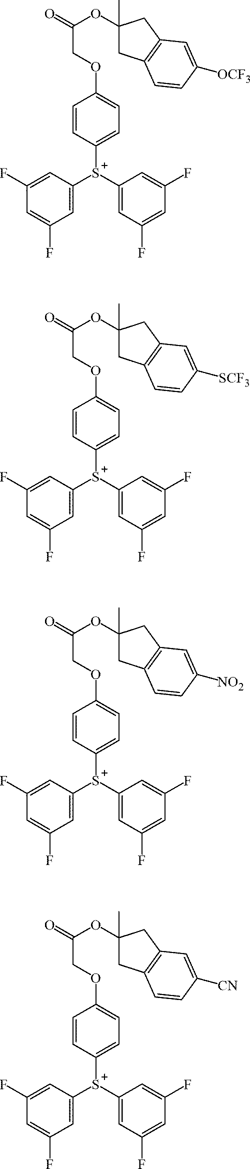

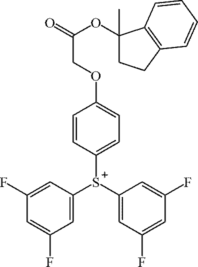

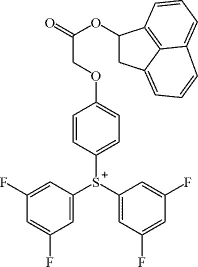

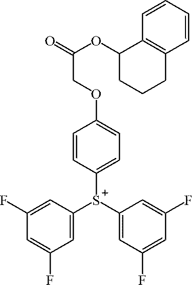

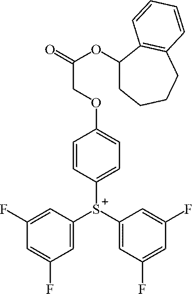

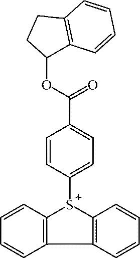

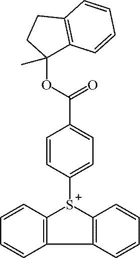

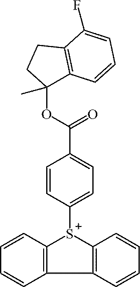

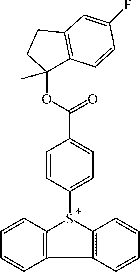

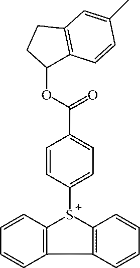

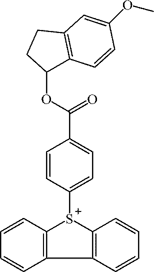

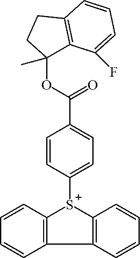

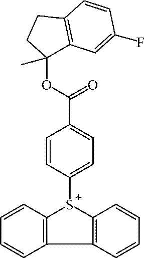

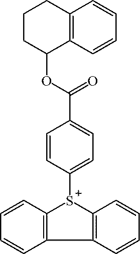

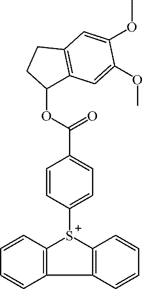

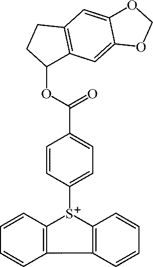

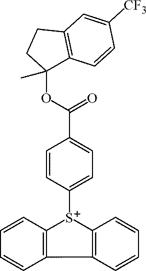

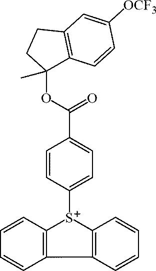

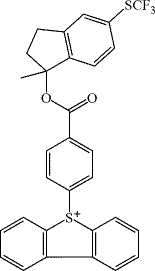

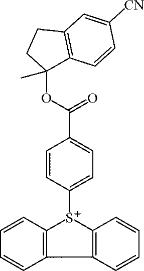

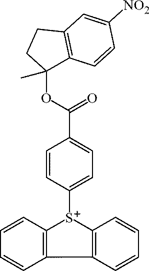

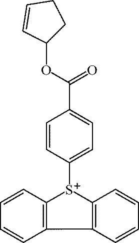

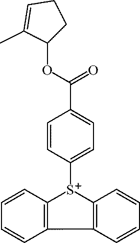

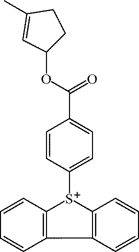

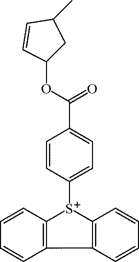

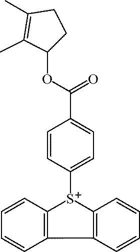

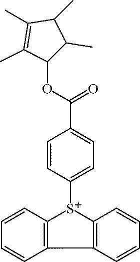

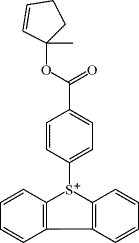

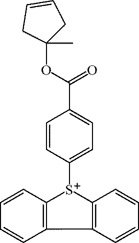

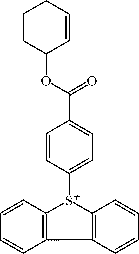

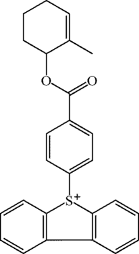

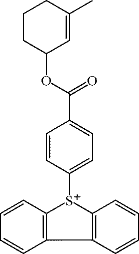

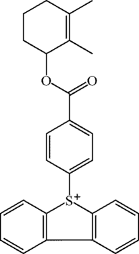

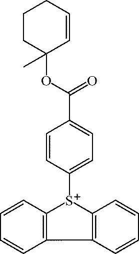

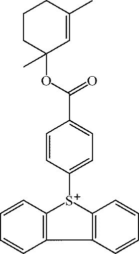

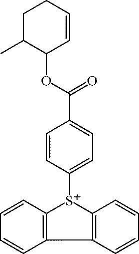

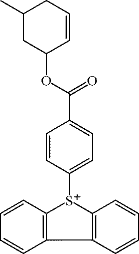

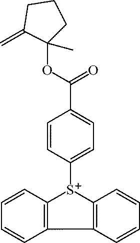

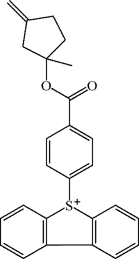

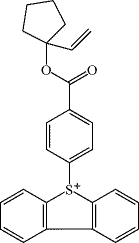

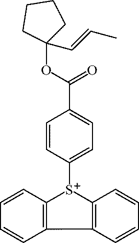

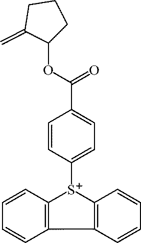

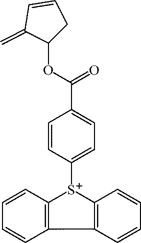

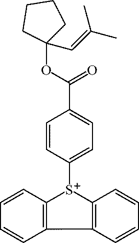

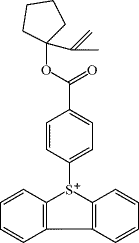

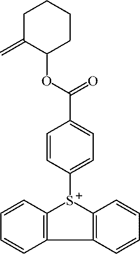

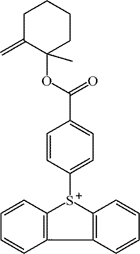

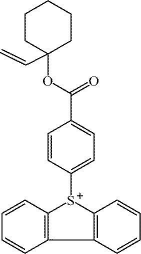

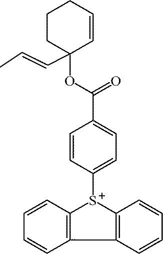

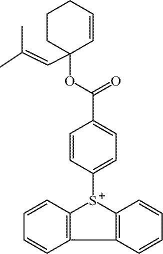

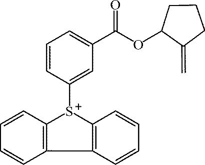

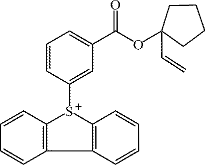

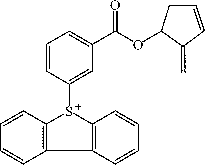

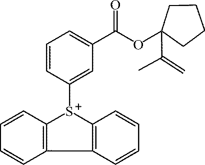

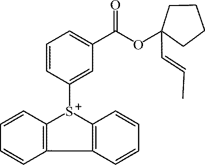

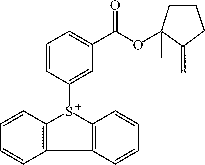

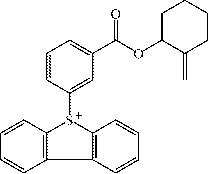

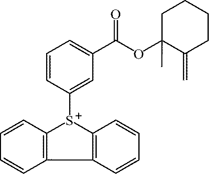

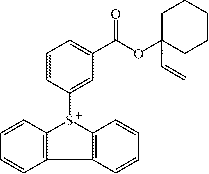

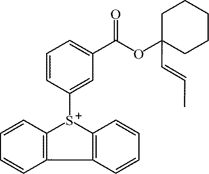

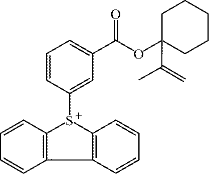

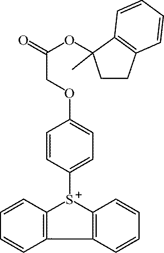

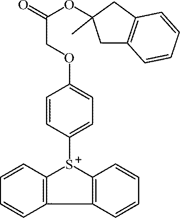

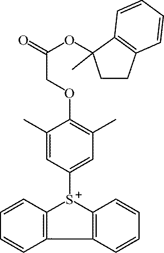

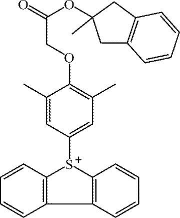

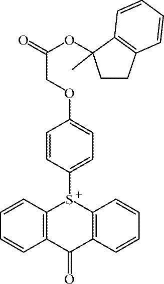

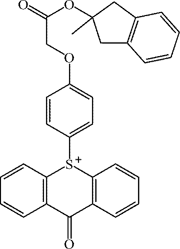

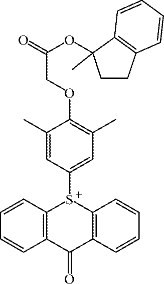

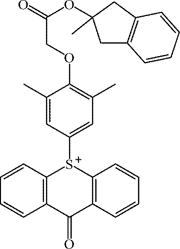

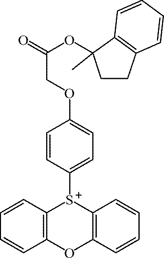

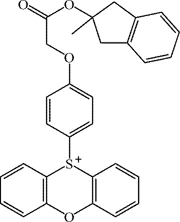

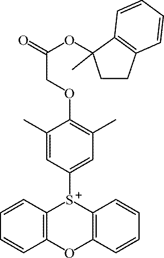

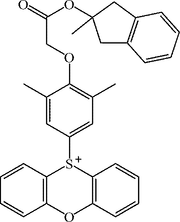

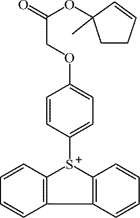

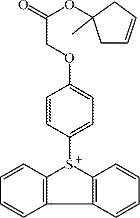

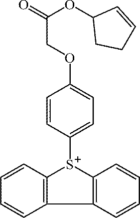

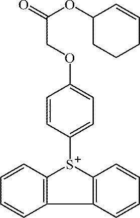

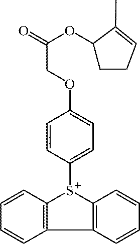

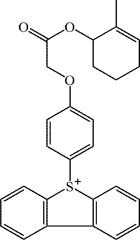

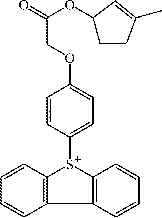

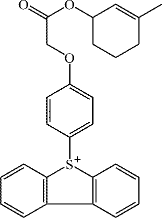

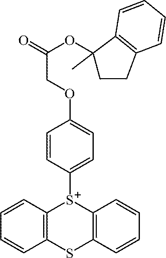

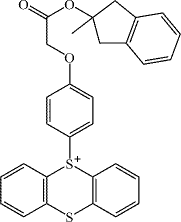

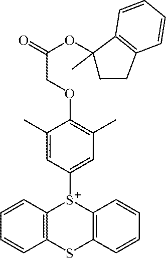

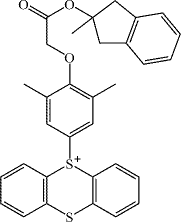

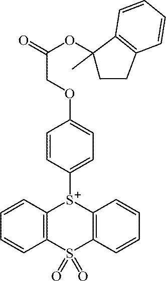

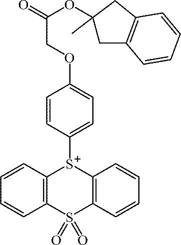

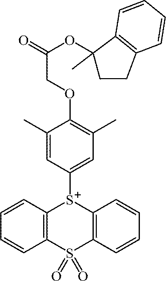

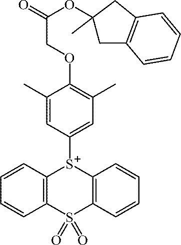

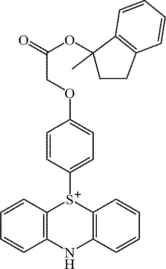

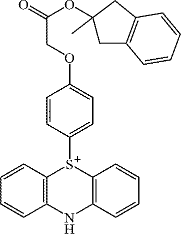

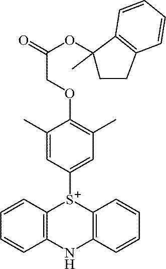

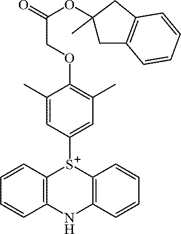

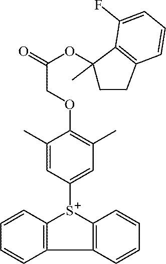

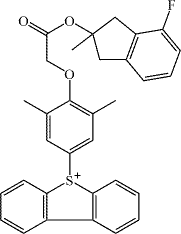

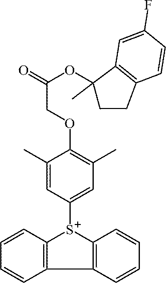

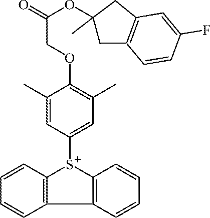

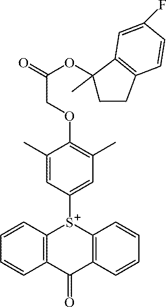

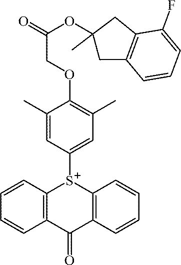

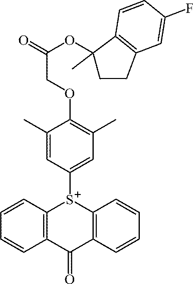

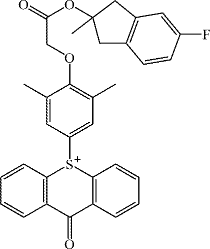

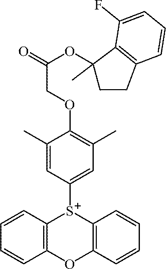

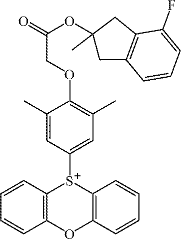

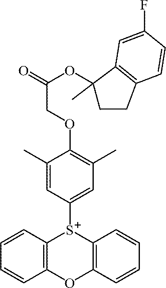

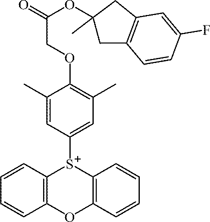

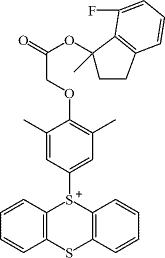

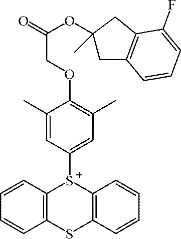

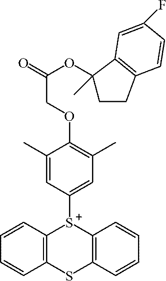

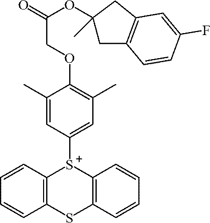

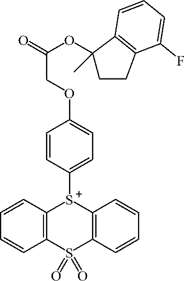

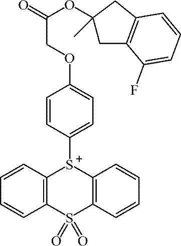

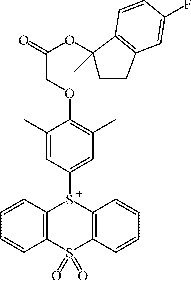

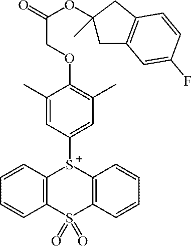

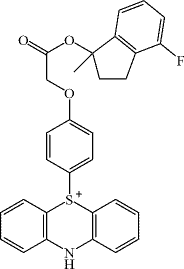

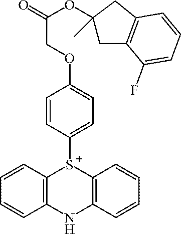

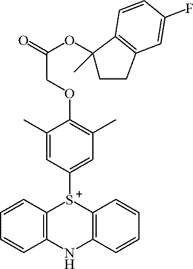

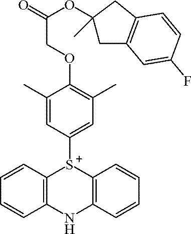

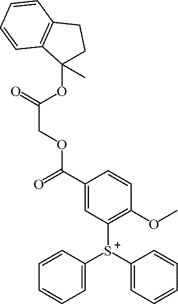

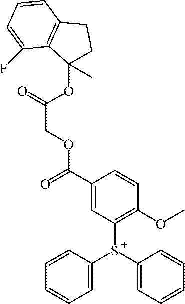

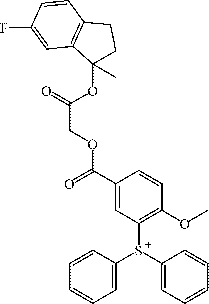

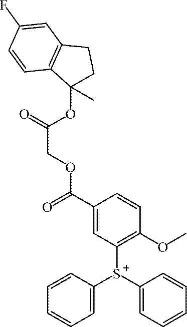

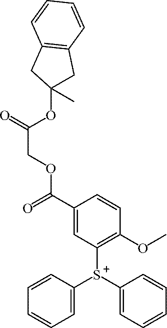

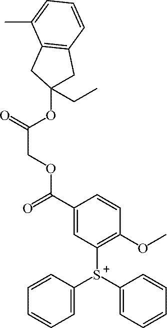

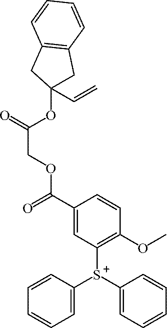

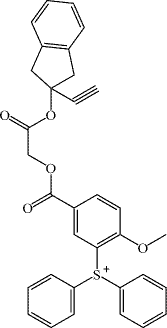

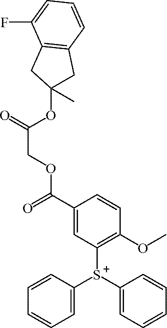

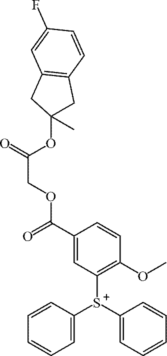

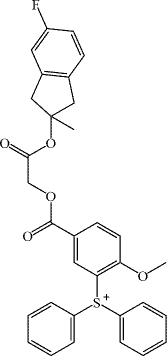

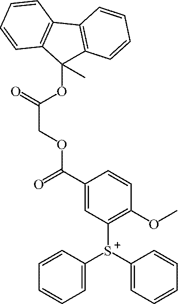

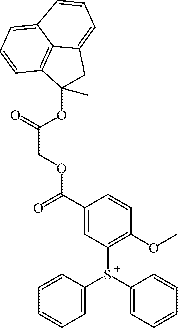

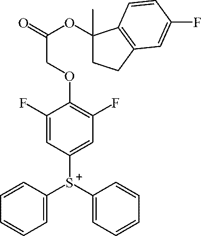

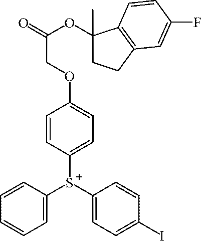

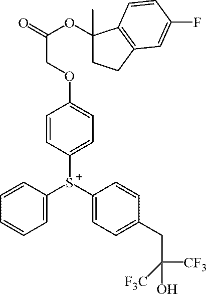

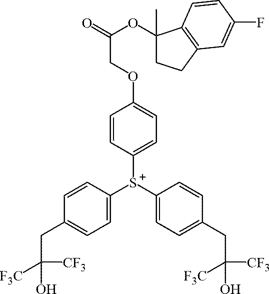

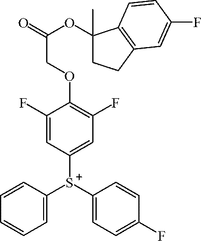

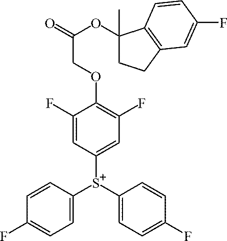

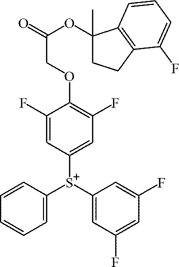

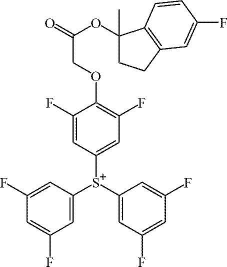

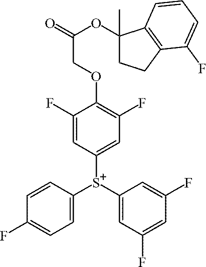

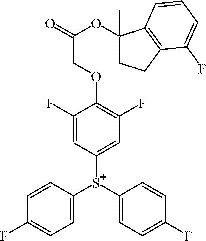

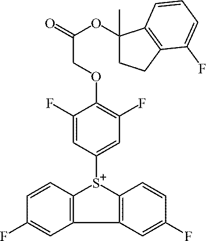

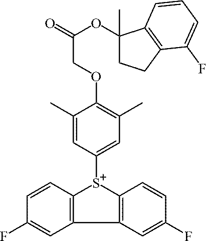

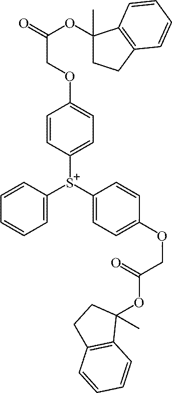

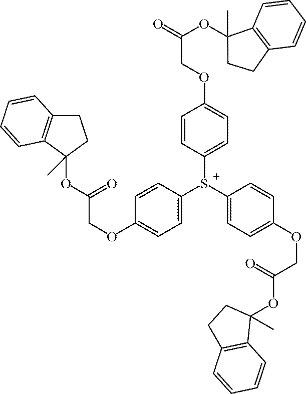

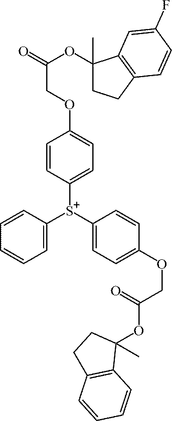

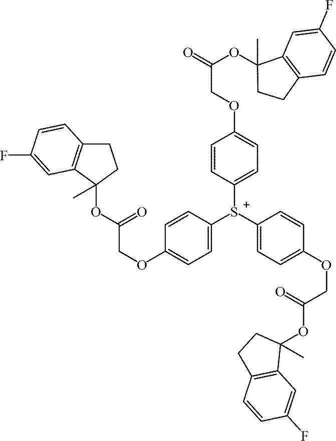

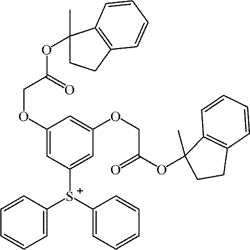

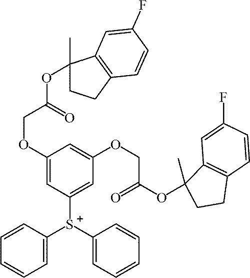

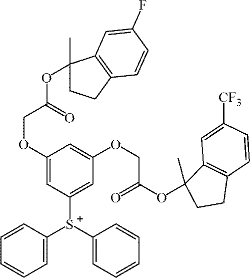

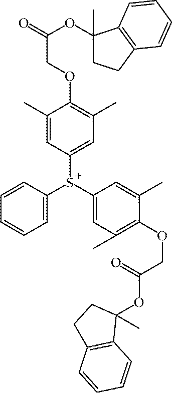

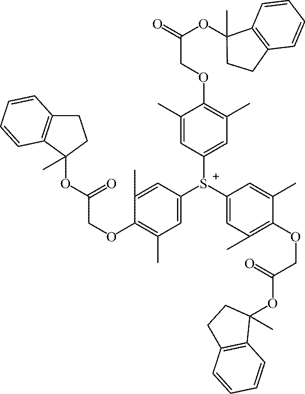

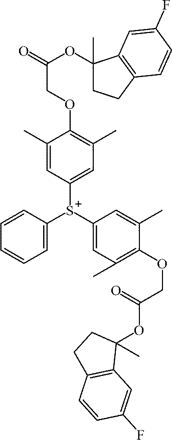

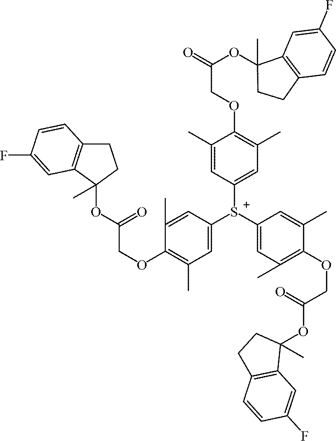

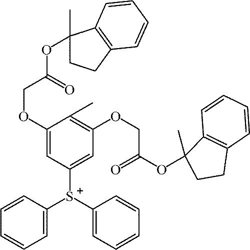

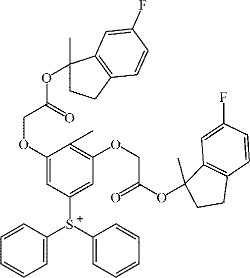

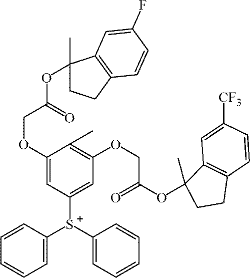

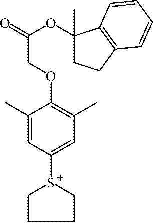

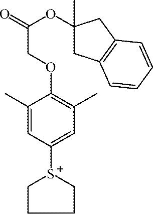

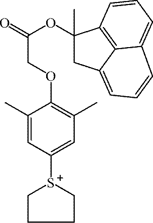

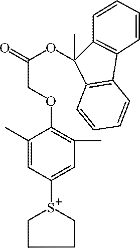

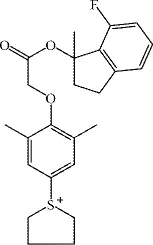

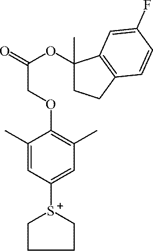

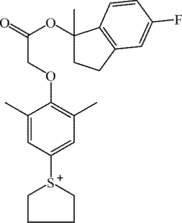

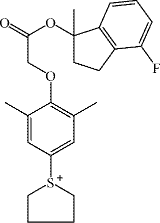

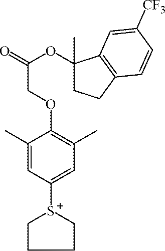

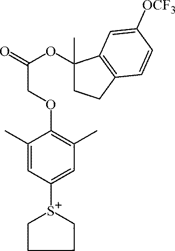

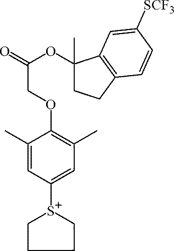

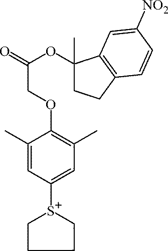

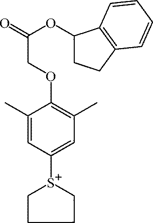

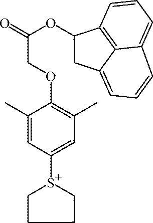

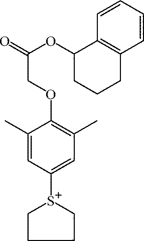

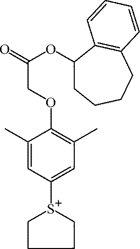

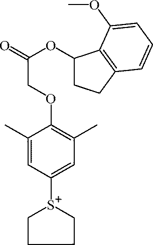

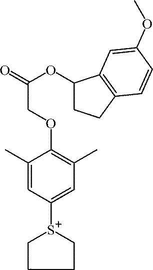

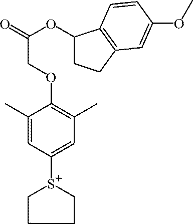

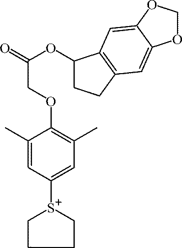

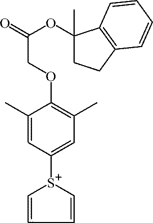

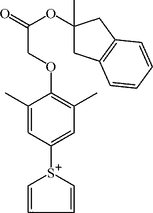

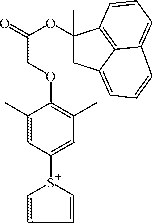

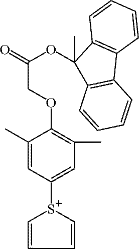

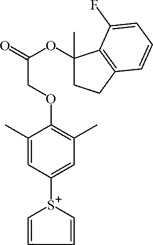

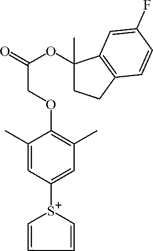

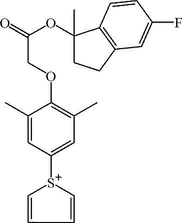

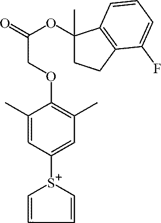

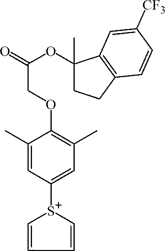

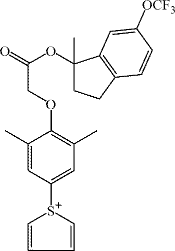

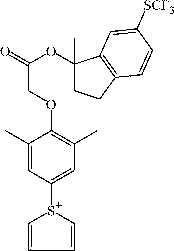

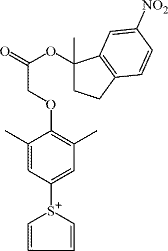

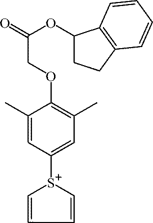

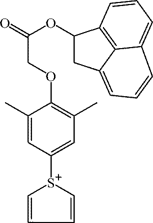

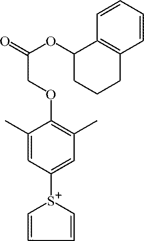

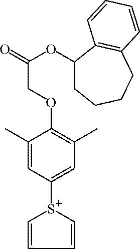

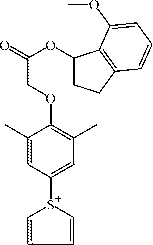

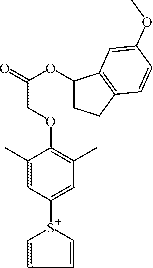

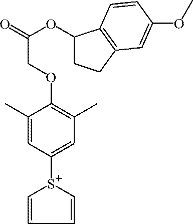

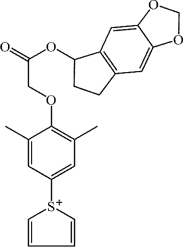

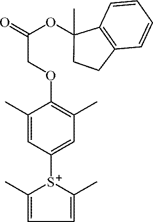

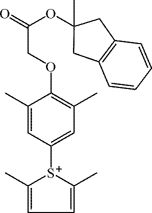

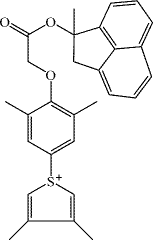

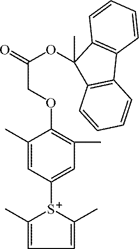

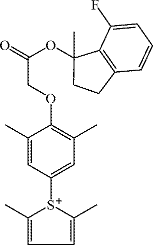

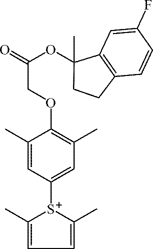

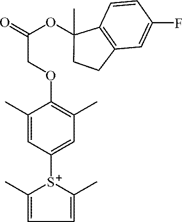

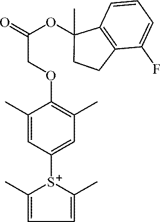

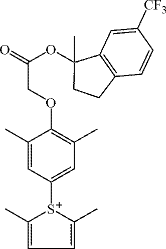

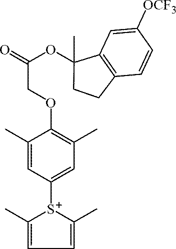

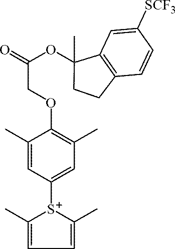

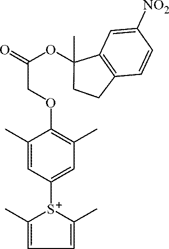

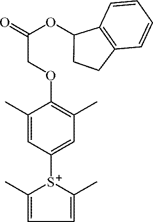

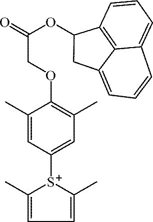

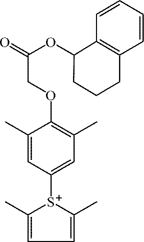

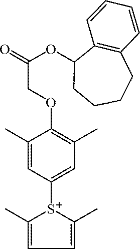

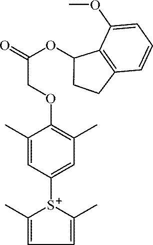

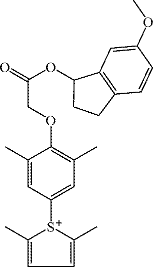

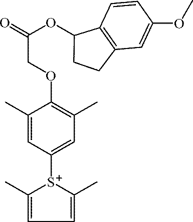

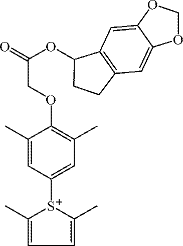

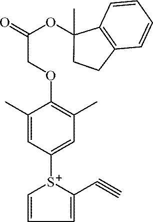

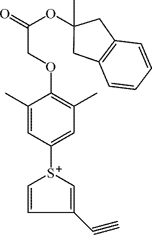

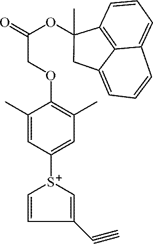

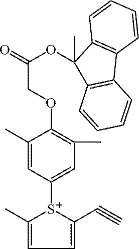

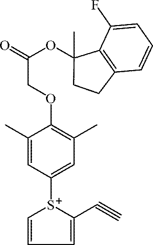

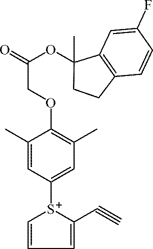

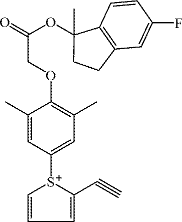

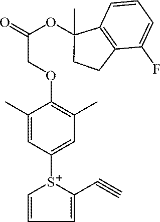

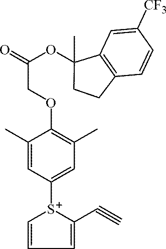

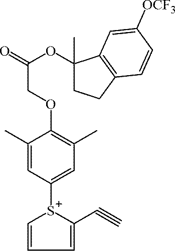

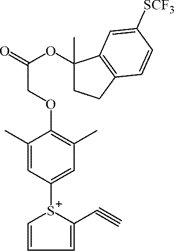

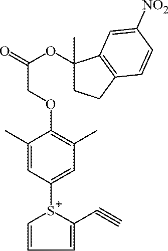

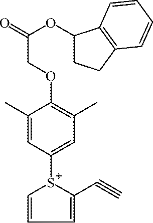

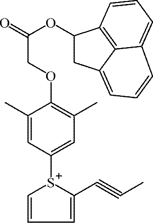

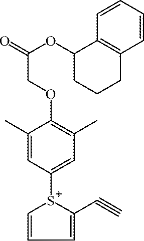

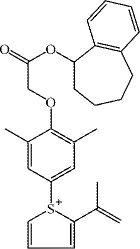

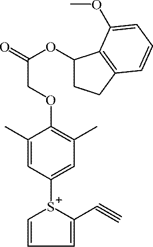

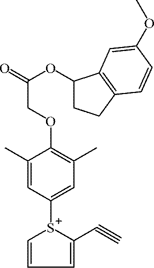

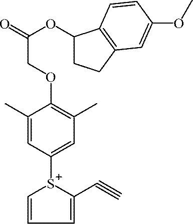

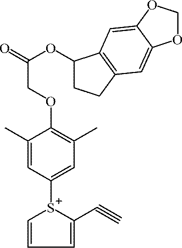

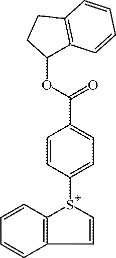

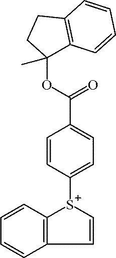

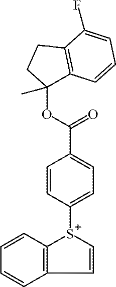

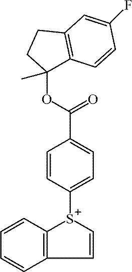

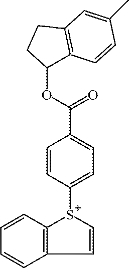

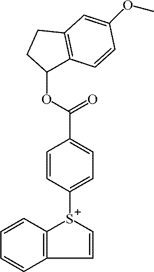

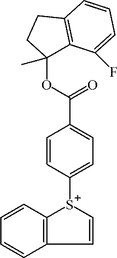

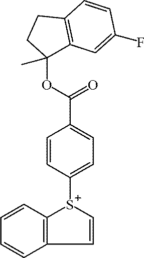

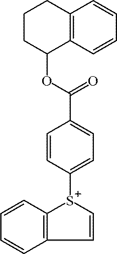

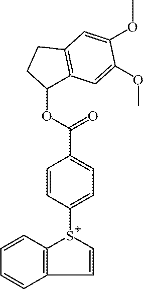

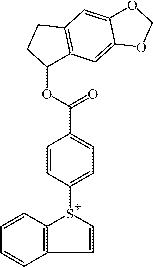

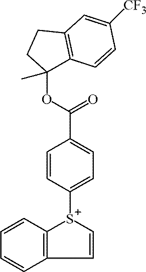

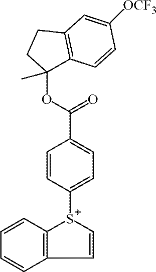

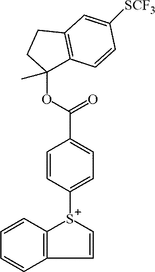

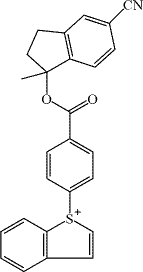

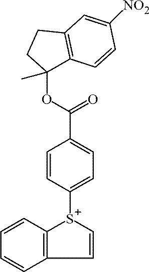

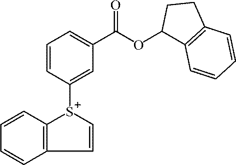

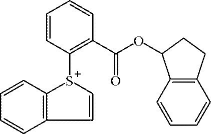

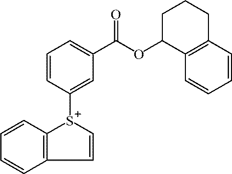

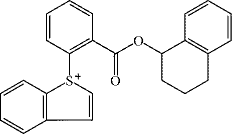

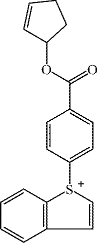

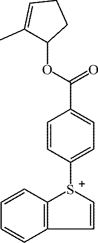

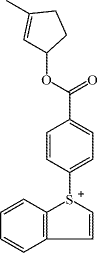

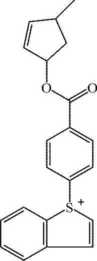

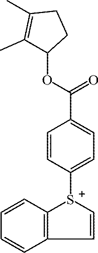

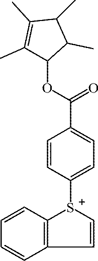

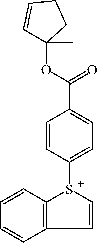

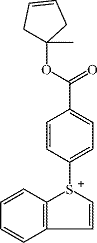

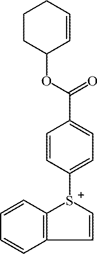

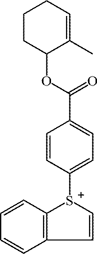

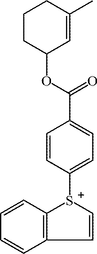

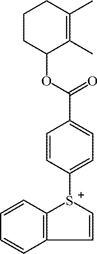

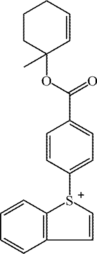

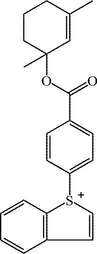

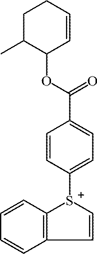

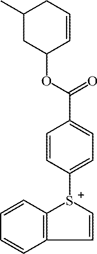

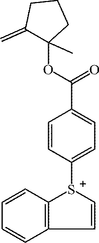

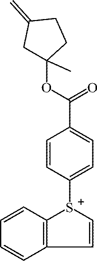

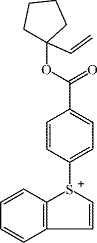

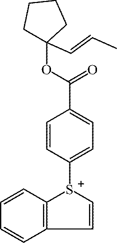

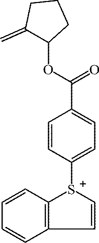

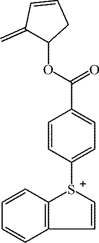

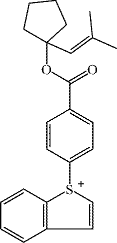

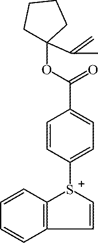

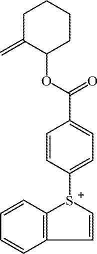

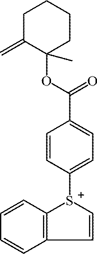

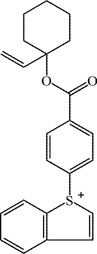

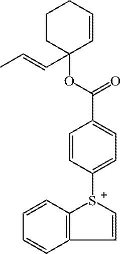

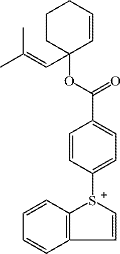

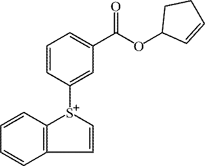

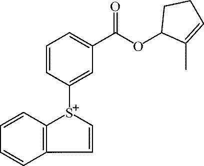

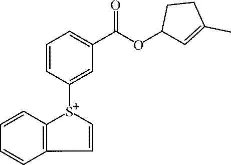

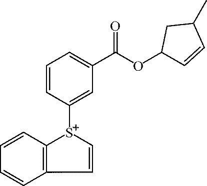

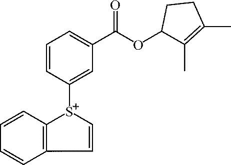

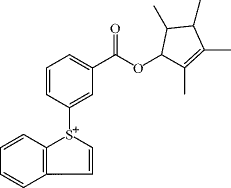

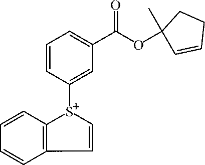

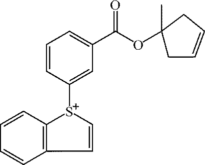

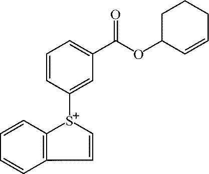

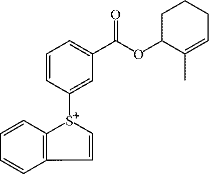

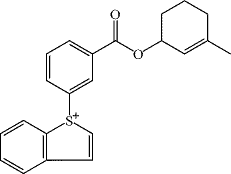

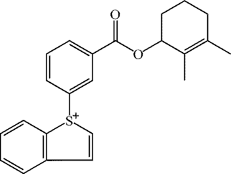

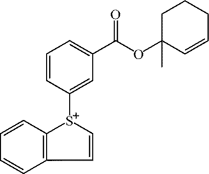

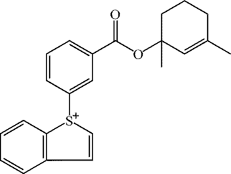

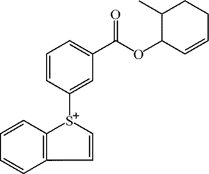

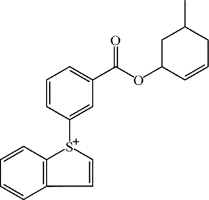

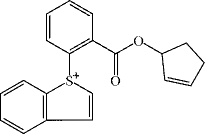

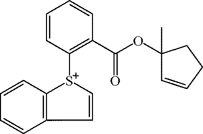

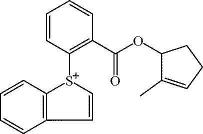

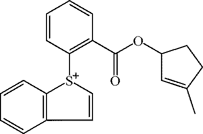

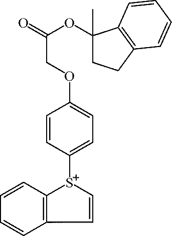

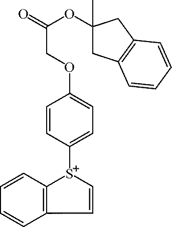

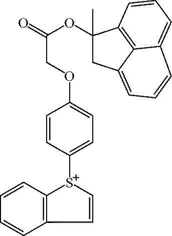

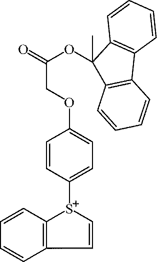

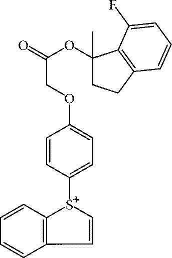

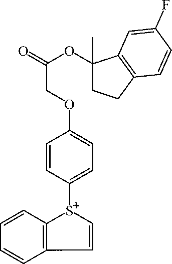

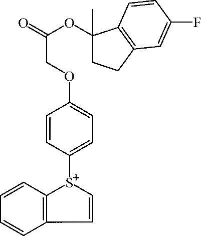

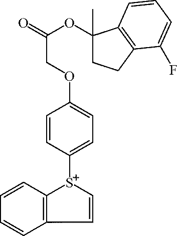

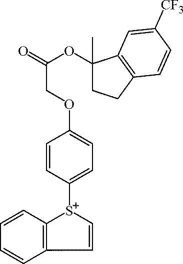

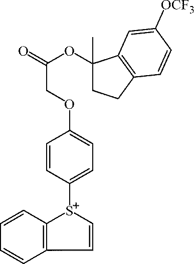

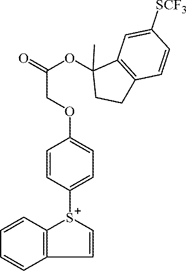

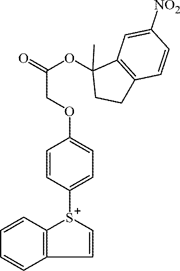

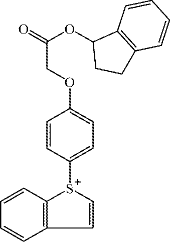

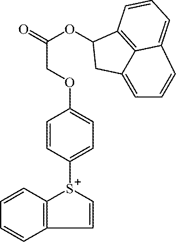

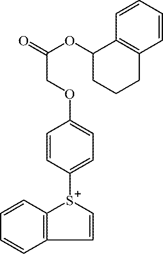

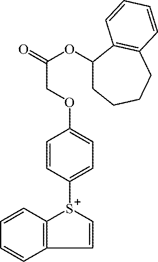

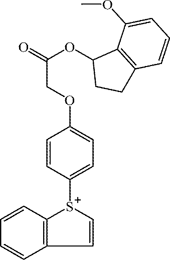

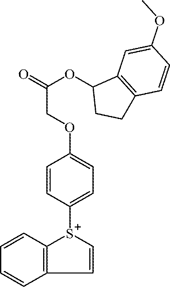

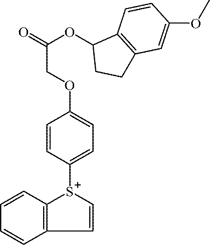

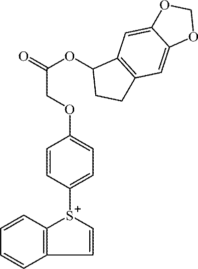

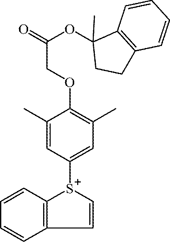

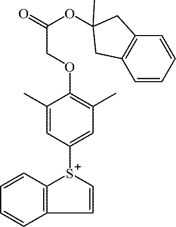

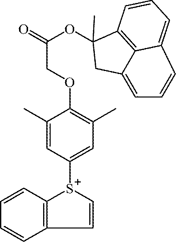

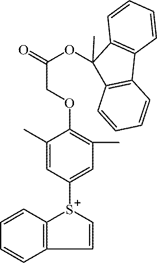

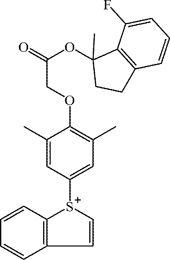

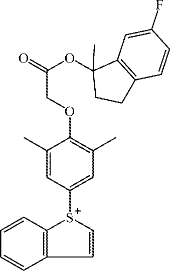

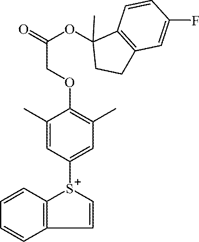

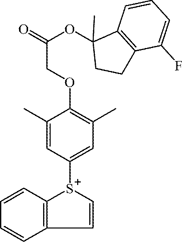

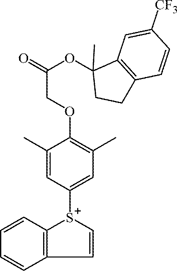

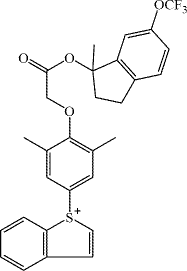

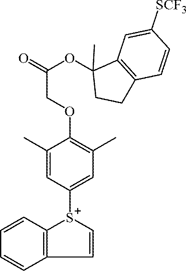

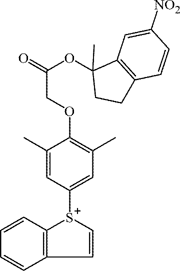

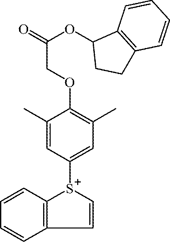

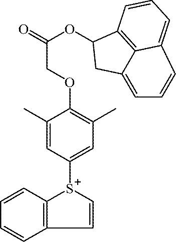

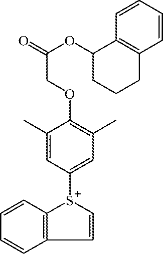

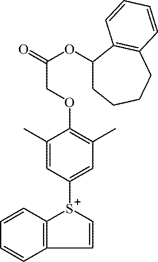

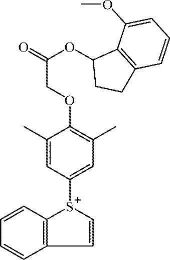

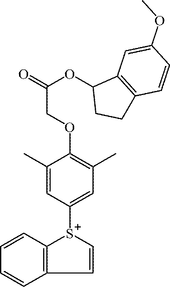

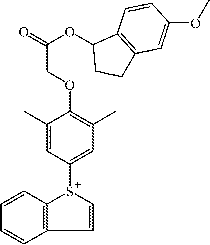

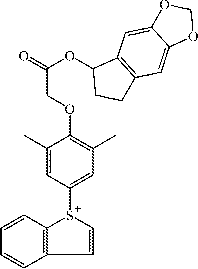

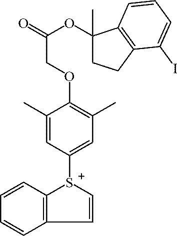

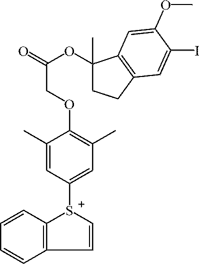

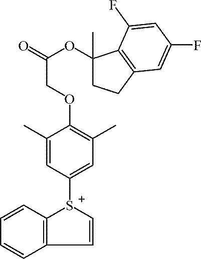

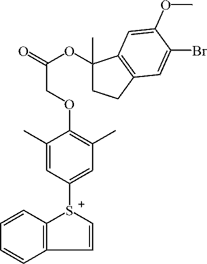

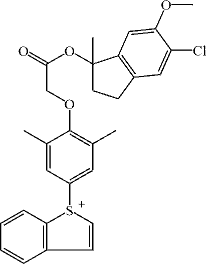

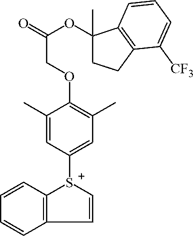

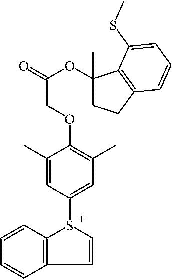

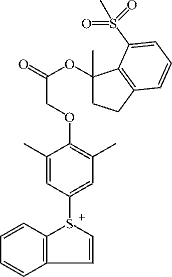

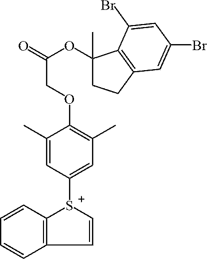

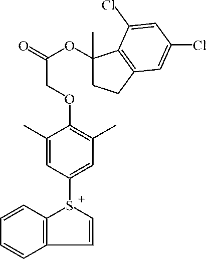

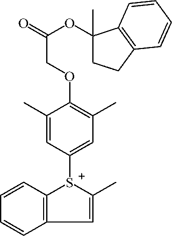

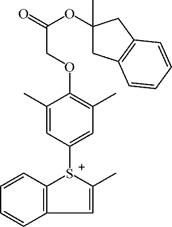

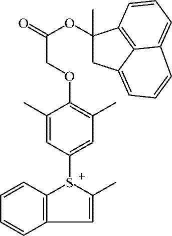

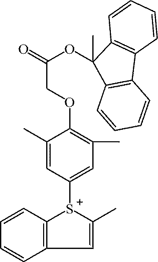

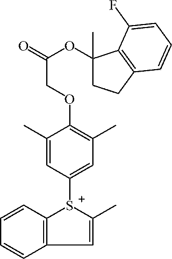

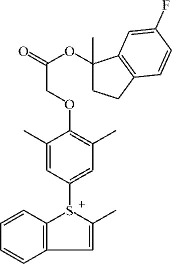

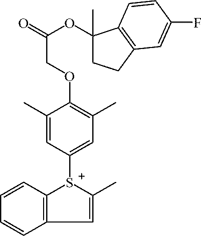

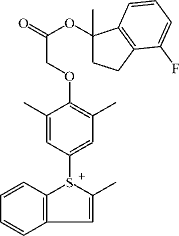

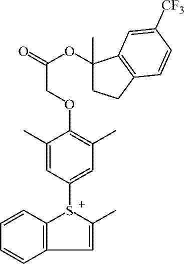

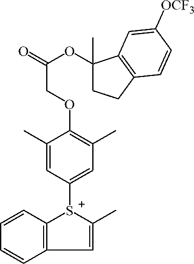

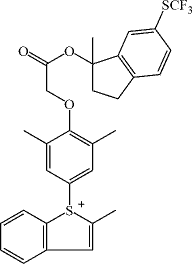

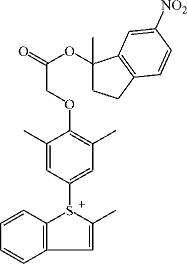

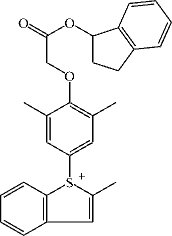

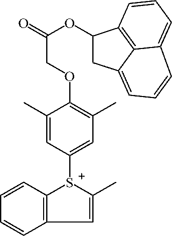

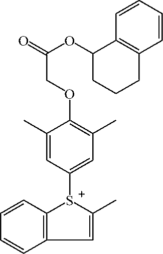

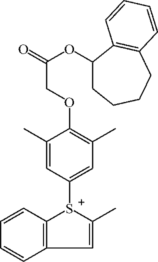

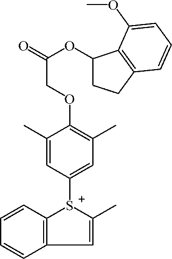

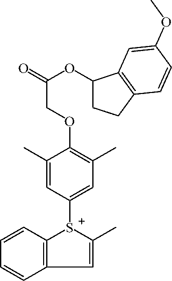

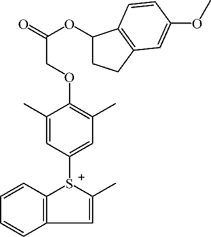

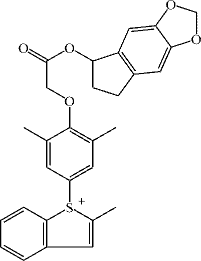

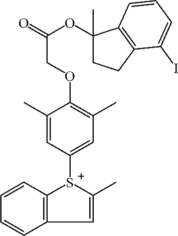

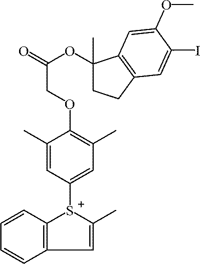

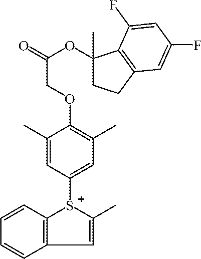

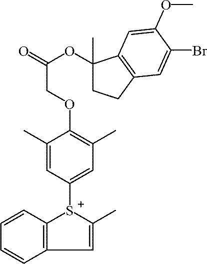

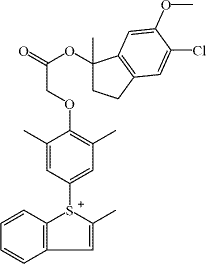

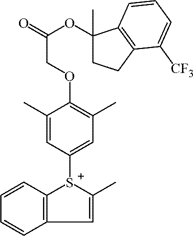

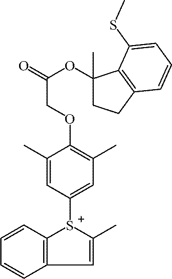

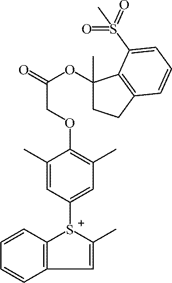

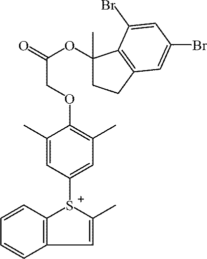

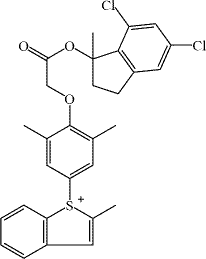

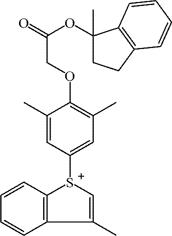

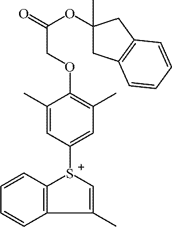

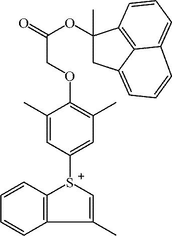

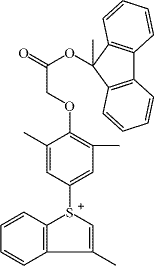

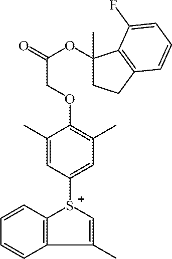

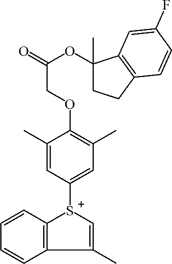

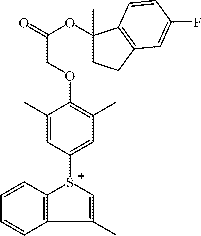

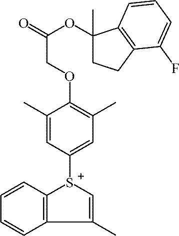

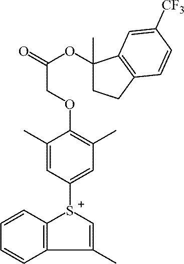

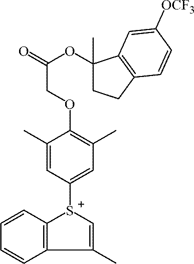

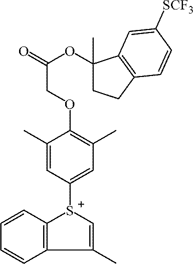

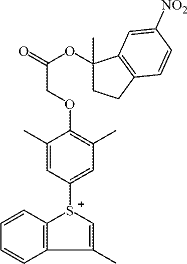

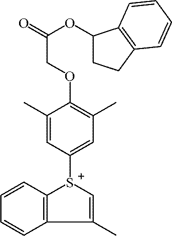

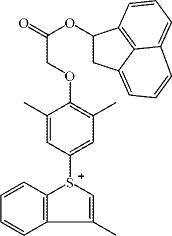

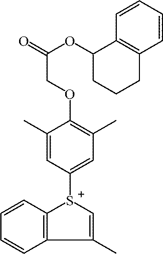

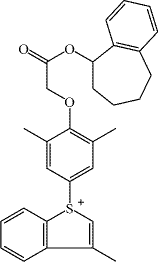

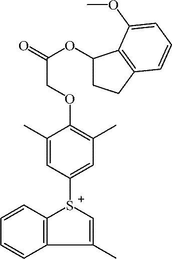

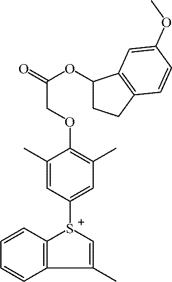

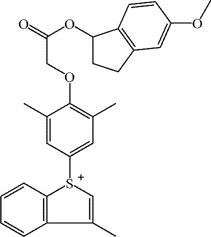

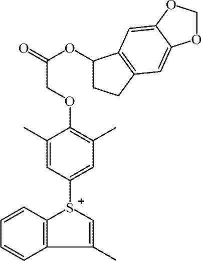

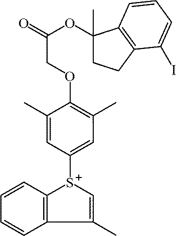

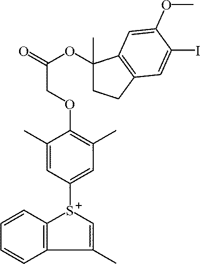

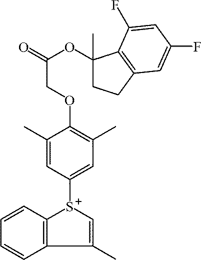

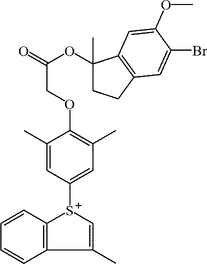

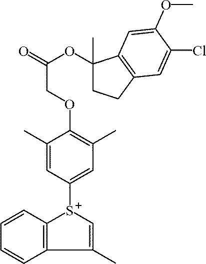

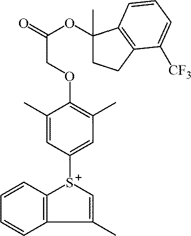

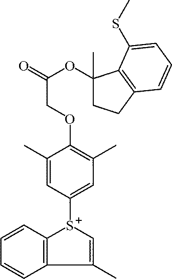

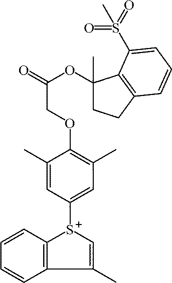

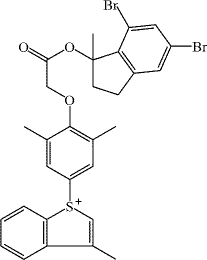

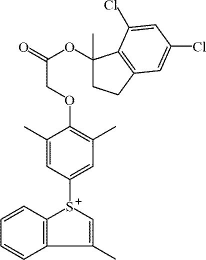

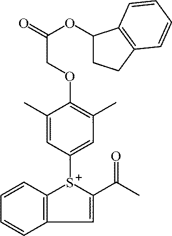

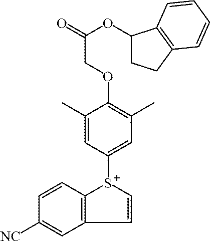

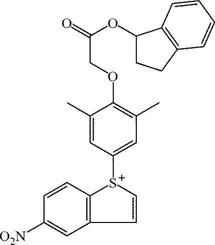

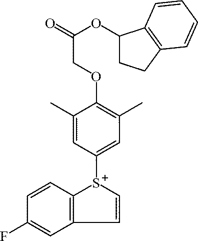

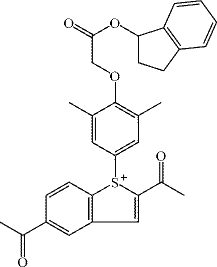

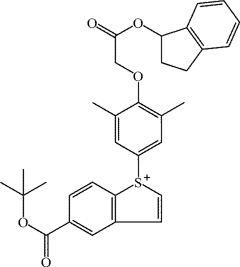

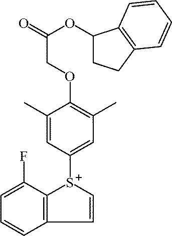

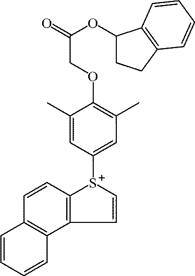

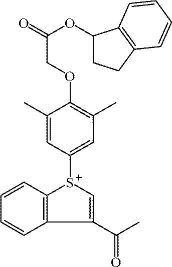

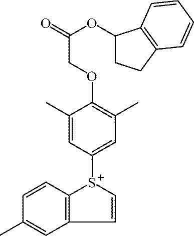

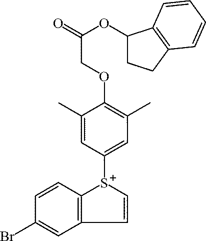

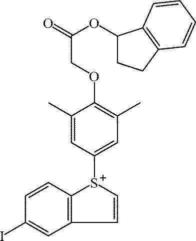

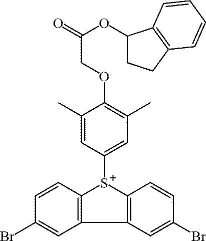

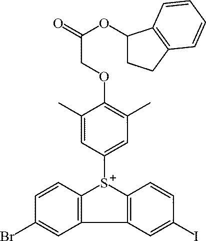

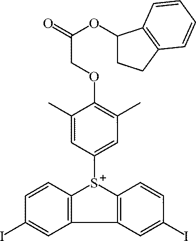

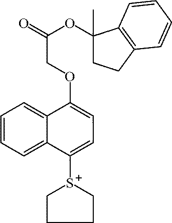

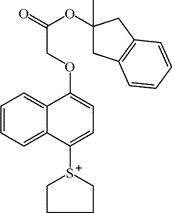

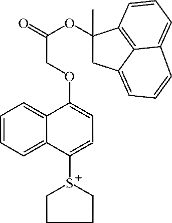

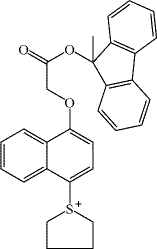

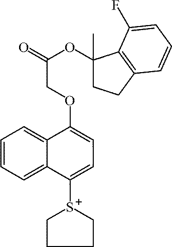

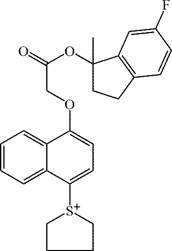

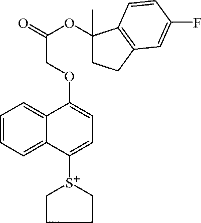

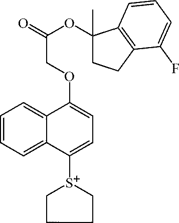

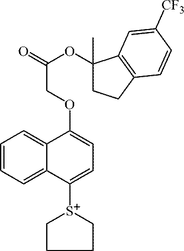

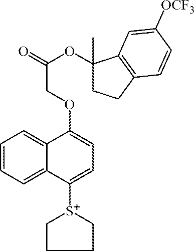

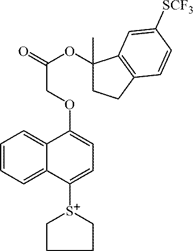

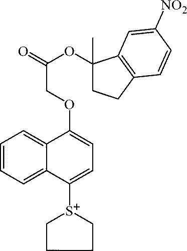

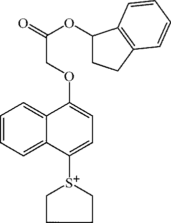

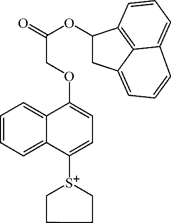

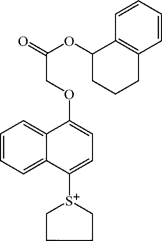

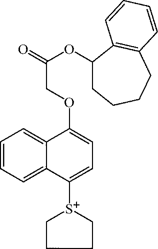

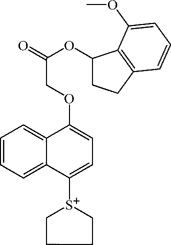

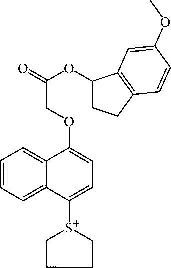

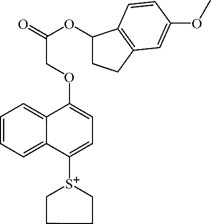

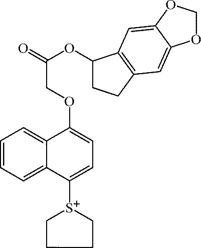

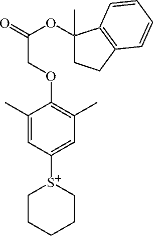

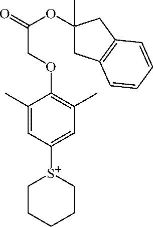

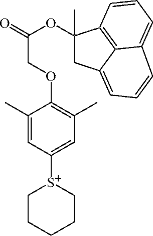

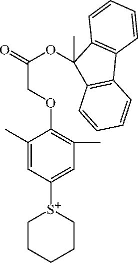

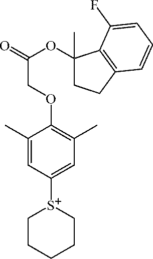

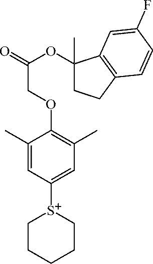

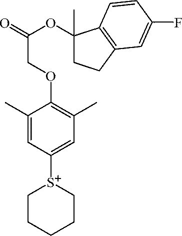

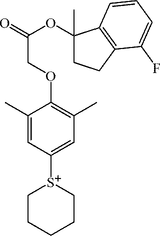

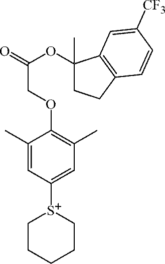

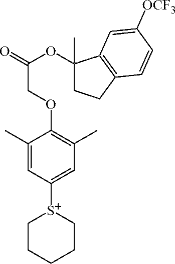

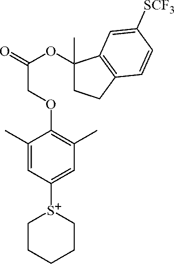

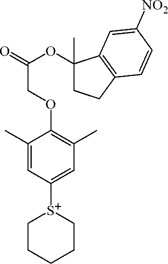

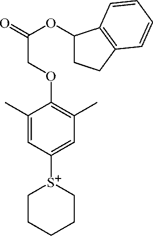

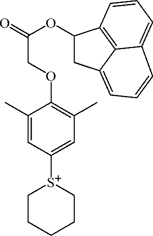

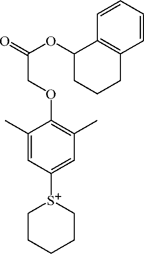

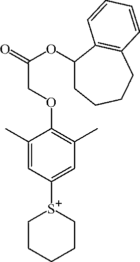

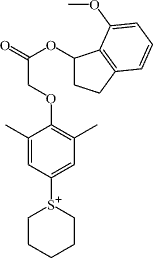

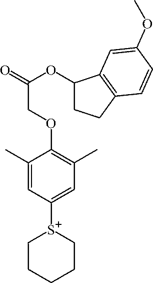

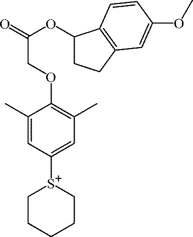

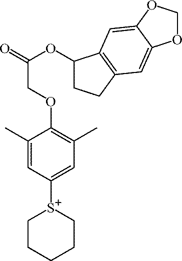

In formula (1), X⁻ is a non-nucleophilic counter ion. Examples of the non-nucleophilic counter ion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; methide ions such as tris(trifluoromethylsulfonyl)methide and tris(perfluoroethylsulfonyl)methide.

Anions having the following formulae (1A) to (1D) are also useful as the non-nucleophilic counter ion.

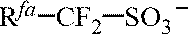

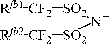

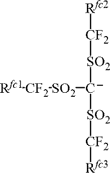

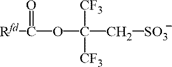

In formula (1A), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified below for the hydrocarbyl group R^{fa1} in formula (1A′).

Of the anions of formula (1A), an anion having the formula (1A′) is preferred.

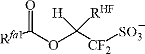

In formula (IA′), R^{HF} is hydrogen or trifluoromethyl, preferably trifluoromethyl.

R^{fa1} is a C₁-C₃₈ hydrocarbyl group which may contain a heteroatom. As the heteroatom, oxygen, nitrogen, sulfur and halogen atoms are preferred, with oxygen being most preferred. Of the hydrocarbyl groups, those groups of 6 to 30 carbon atoms are preferred from the aspect of achieving a high resolution in forming patterns of small feature size. The hydrocarbyl groups may be saturated or unsaturated and straight, branched or cyclic. Examples thereof include, but are not limited to, C₁-C₃₈ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecyl, tetracyclododecyl, tetracyclododecylmethyl, and dicyclohexylmethyl; C₂-C₃₈ unsaturated aliphatic hydrocarbyl groups such as allyl and 3-cyclohexenyl; C₆-C₃₈ aryl groups such as phenyl, 1-naphthyl, 2-naphthyl and 9-fluorenyl; and C₇-C₃₈ aralkyl groups such as benzyl and diphenylmethyl, and combinations thereof.

In the foregoing hydrocarbyl groups, some or all hydrogen may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonic ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

Examples of the anion having formula (1A) are shown below, but not limited thereto.

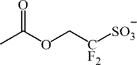

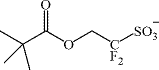

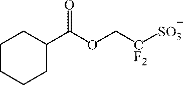

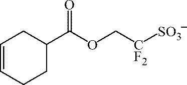

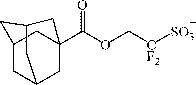

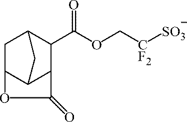

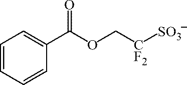

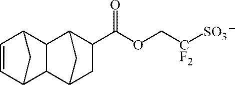

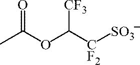

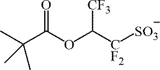

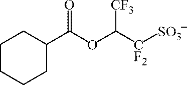

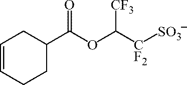

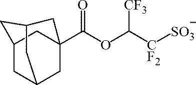

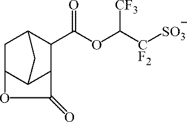

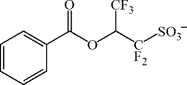

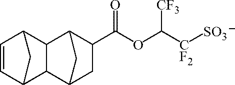

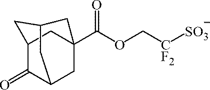

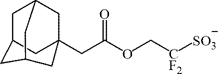

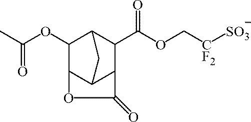

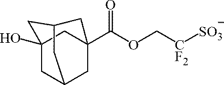

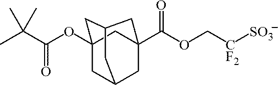

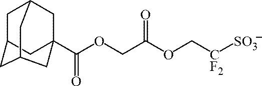

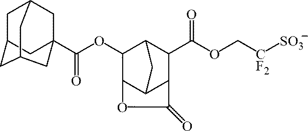

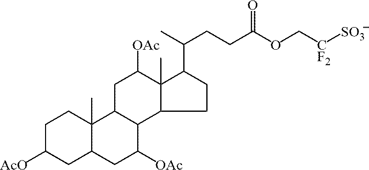

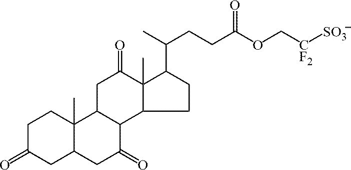

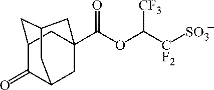

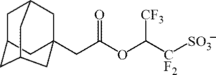

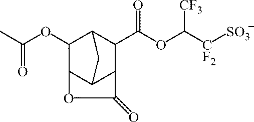

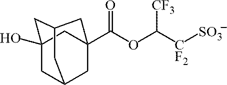

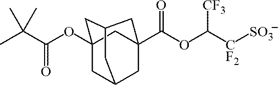

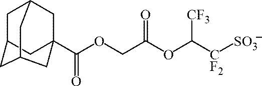

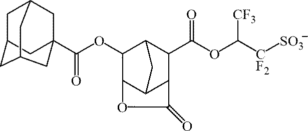

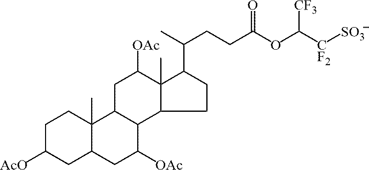

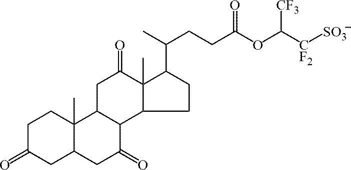

In formula (1B), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for R^{fa1} in formula (1A′). Preferably R^{fb1} and R^{fb2} are fluorine or C₁-C₄ straight fluorinated alkyl groups. Also, R^{fb1} and R^{fb2} may bond together to form a ring with the linkage: —CF₂—SO₂—N—SO₂—CF₂— to which they are attached. It is preferred that a combination of R^{fb1} and R^{fb2} be a fluorinated ethylene or fluorinated propylene group.

In formula (1C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified for R^{fa1} in formula (1A′). Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C⁻—SO₂—CF₂— to which they are attached. It is preferred that a combination of R^{fc1} and R^{fc2} be a fluorinated ethylene or fluorinated propylene group.

In formula (ID), R^{fd} is a C₁-C₄₀ hydrocarbyl group which may contain a heteroatom. The hydrocarbyl group may be saturated or unsaturated and straight, branched or cyclic. Examples thereof are as exemplified above for R^{fa1}.

Examples of the anion having formula (1D) are shown below, but not limited thereto.

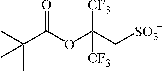

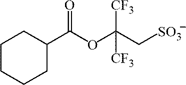

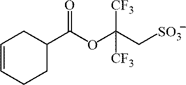

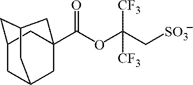

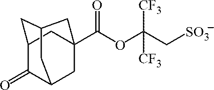

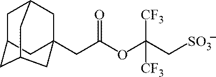

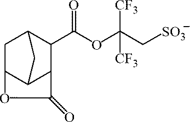

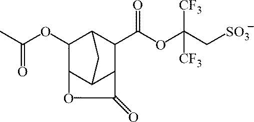

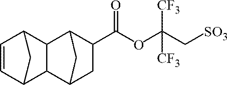

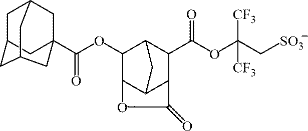

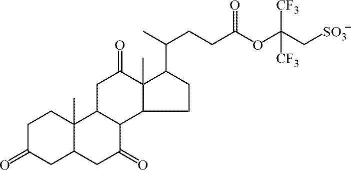

Anions having an iodized or brominated aromatic ring are also useful as the non-nucleophilic counter ion. These anions have the formula (1E).

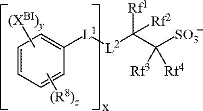

In formula (IE), x is an integer of 1 to 3, y is an integer of 1 to 5, z is an integer of 0 to 3, and 1 ≤ y+z ≤ 5; preferably, y is an integer of 1 to 3, more preferably 2 or 3, and z is an integer of 0 to 2.

X^{B1} is iodine or bromine, and may be identical or different when x and/or y is 2 or more.

L¹ is a single bond, ether bond, ester bond, or a C₁-C₆ saturated hydrocarbylene group which may contain an ether bond or ester bond. The saturated hydrocarbylene group may be straight, branched or cyclic.

L² is a single bond or a C₁-C₂₀ divalent linking group when x=1, or a C₁-C₂₀ (x+1)-valent linking group when x=2 or 3. The linking group may contain an oxygen, sulfur or nitrogen atom.

R⁸ is hydroxy, carboxy, fluorine, chlorine, bromine, amino group, or a C₁-C₂₀ hydrocarbyl, C₁-C₂₀ hydrocarbyloxy, C₂-C₂₀ hydrocarbylcarbonyl, C₂-C₁₀ hydrocarbyloxycarbonyl, C₂-C₂₀ hydrocarbylcarbonyloxy, or C₁-C₂₀ hydrocarbylsulfonyloxy group, which may contain fluorine, chlorine, bromine, hydroxy, amino or ether bond, or —N(R^{8A})(R^{8B}), —N(R^{8C})—C(═O)—R^{8D} or —N(R^{8C})—C(═O)—O—R^{8D}. R^{8A} and R^{8B} are each independently hydrogen or a C₁-C₆ saturated hydrocarbyl group. R^{8C} is hydrogen, or a C₁-C₆ saturated hydrocarbyl group which may contain halogen, hydroxy, C₁-C₆ saturated hydrocarbyloxy. C₂-C₆ saturated hydrocarbylcarbonyl or C₂-C₆ saturated hydrocarbylcarbonyloxy moiety. R^{8D} is a C₁-C₁₆ aliphatic hydrocarbyl group, C₆-C₁₂ aryl group or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarlsulfonyloxy groups may be straight, branched or cyclic. Groups R⁸ may be identical or different when x and/or z is 2 or more.

Of these, R⁸ is preferably hydroxy, —N(R^{8C})—C(═O)—R^{8D}, —N(R^{8C})—C(═O)—O—R^{8D}, fluorine, chlorine, bromine, methyl or methoxy.

Rf¹ to Rf⁴ are each independently hydrogen, fluorine or trifluoromethyl, at least one of Rf¹ to Rf⁴ is fluorine or trifluoromethyl, or Rf¹ and Rf², taken together, may form a carbonyl group. More preferably, both Rf³ and Rf⁴ are fluorine.

Examples of the anion having formula (1E) are shown below, but not limited thereto. X^{B1} is as defined above.

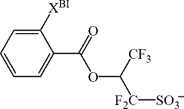

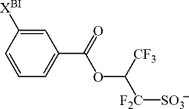

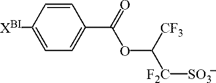

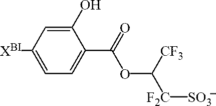

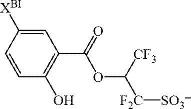

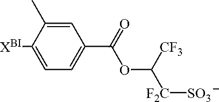

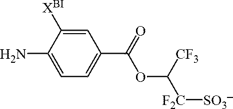

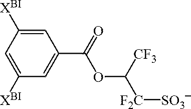

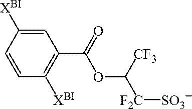

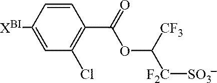

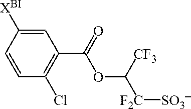

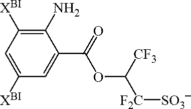

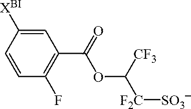

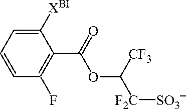

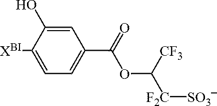

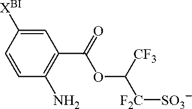

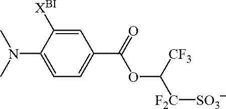

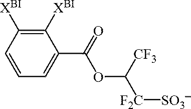

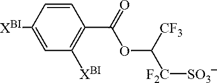

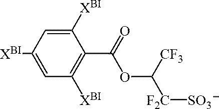

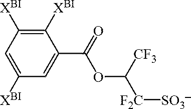

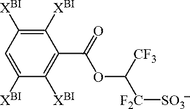

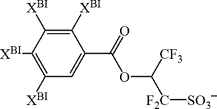

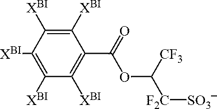

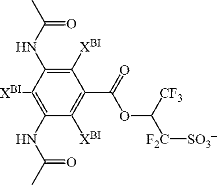

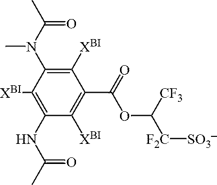

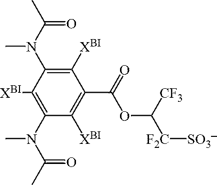

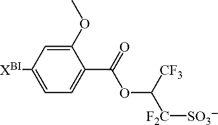

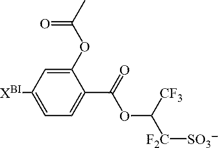

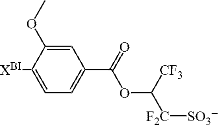

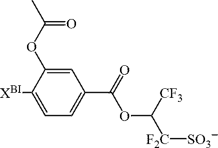

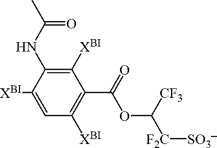

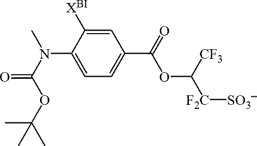

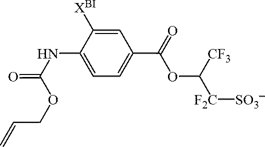

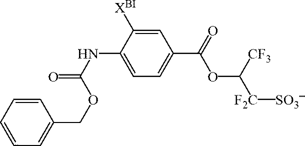

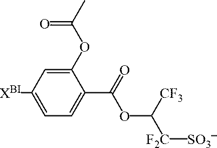

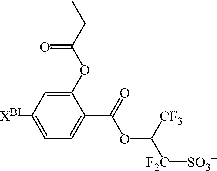

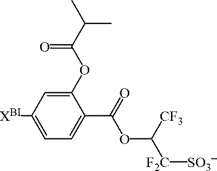

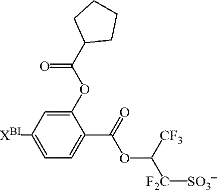

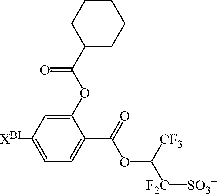

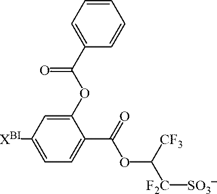

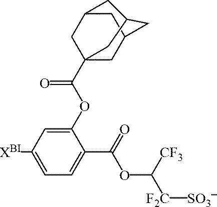

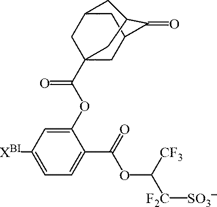

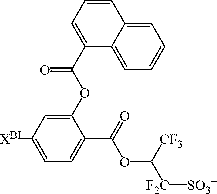

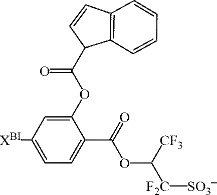

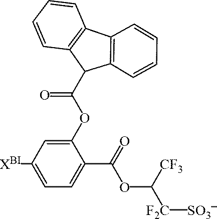

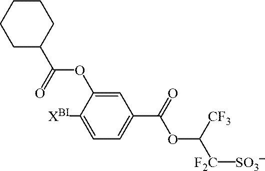

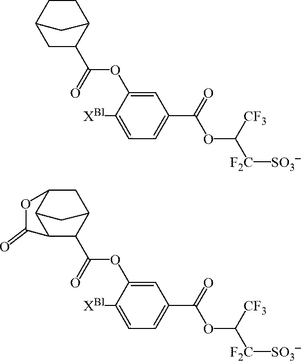

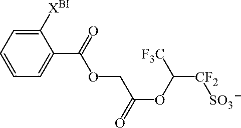

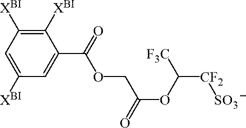

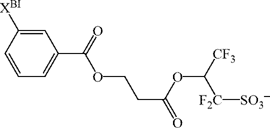

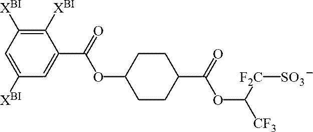

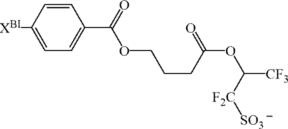

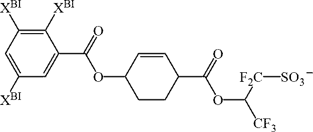

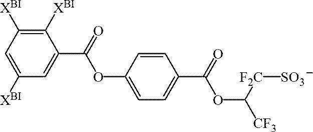

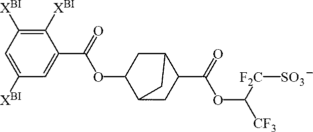

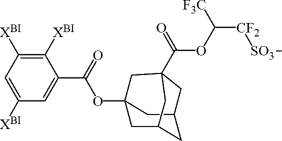

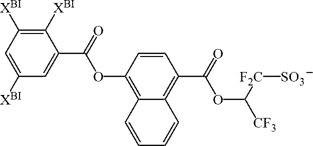

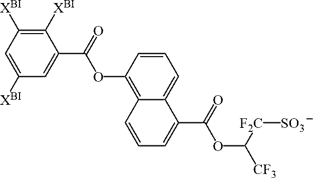

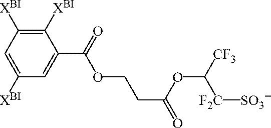

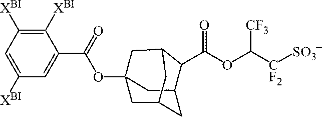

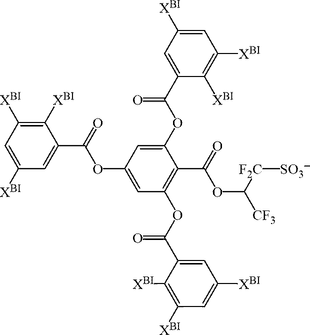

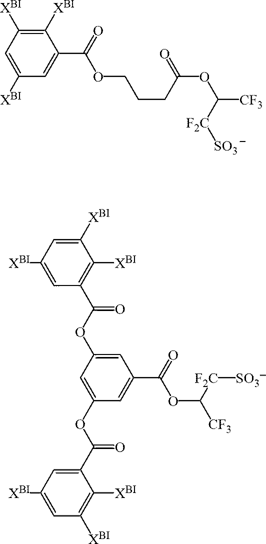

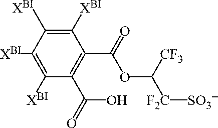

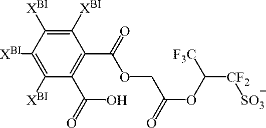

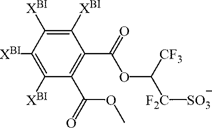

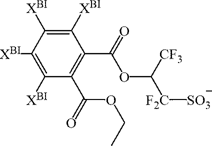

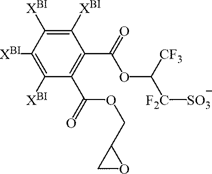

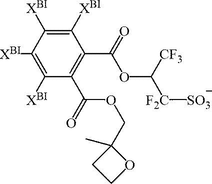

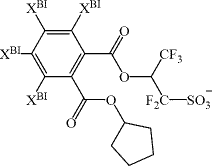

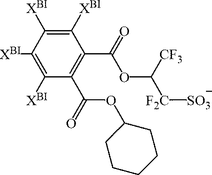

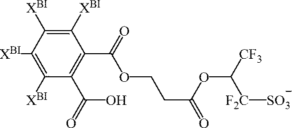

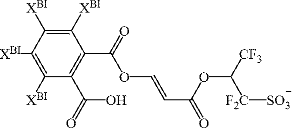

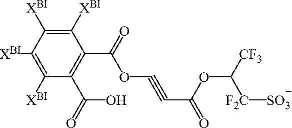

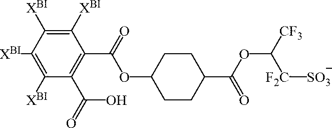

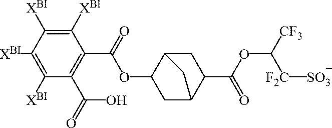

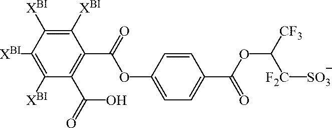

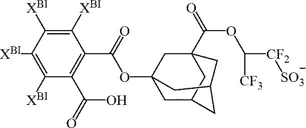

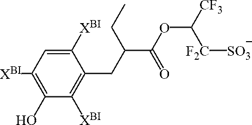

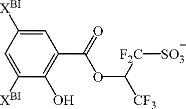

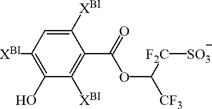

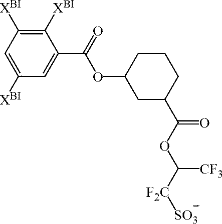

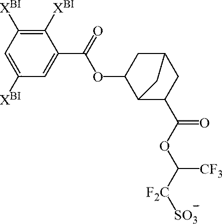

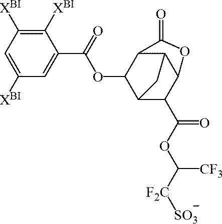

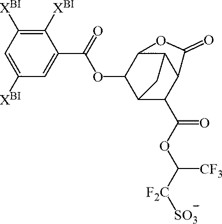

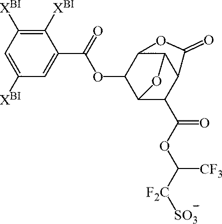

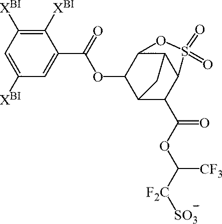

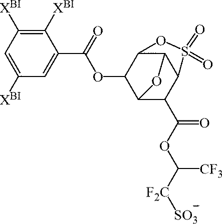

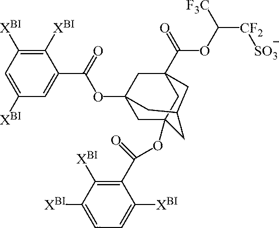

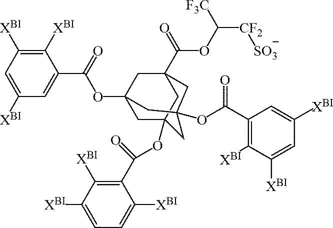

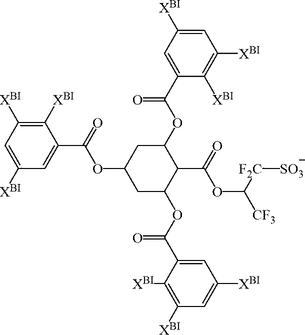

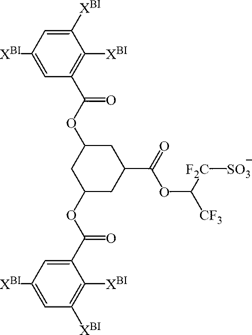

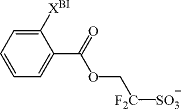

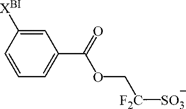

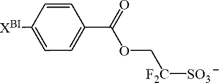

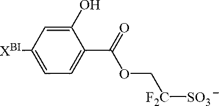

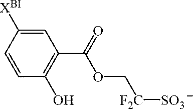

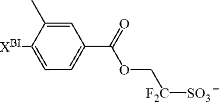

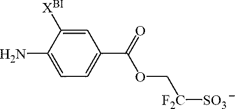

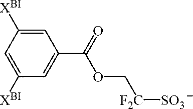

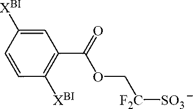

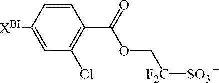

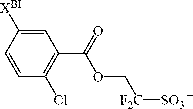

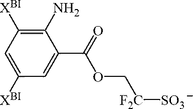

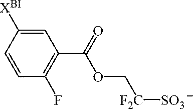

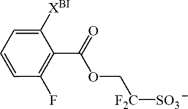

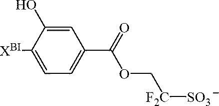

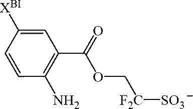

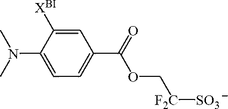

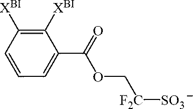

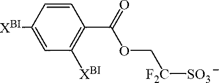

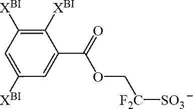

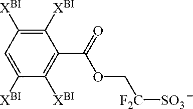

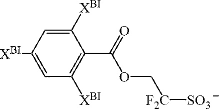

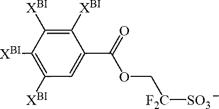

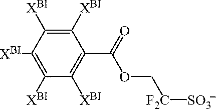

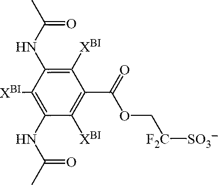

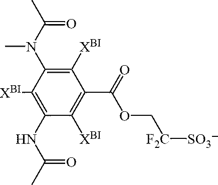

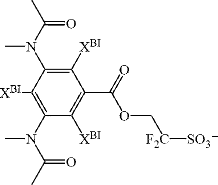

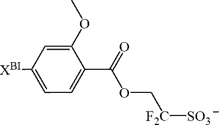

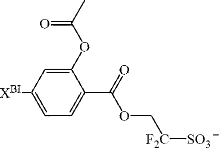

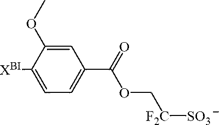

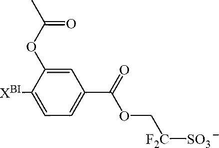

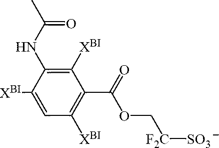

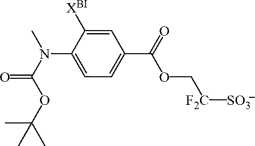

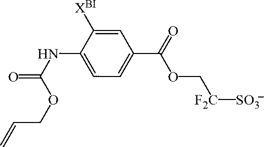

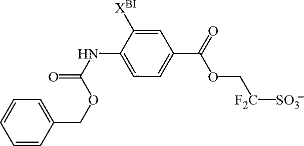

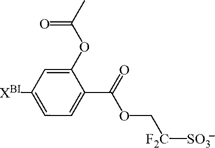

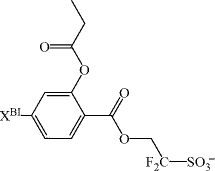

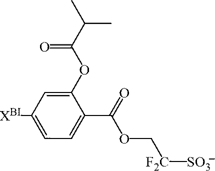

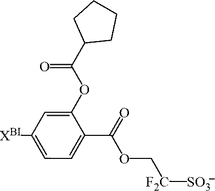

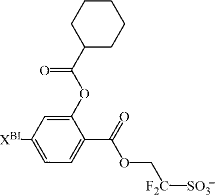

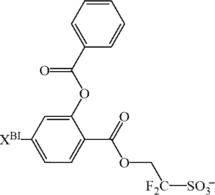

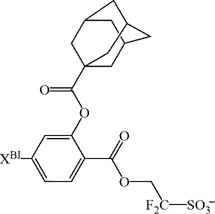

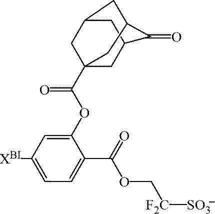

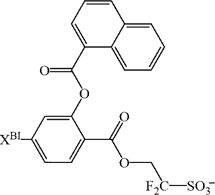

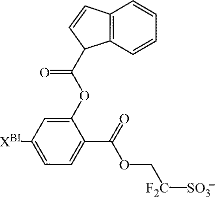

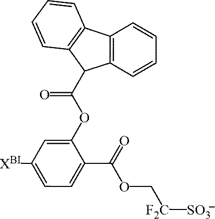

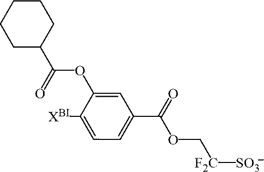

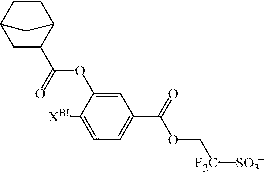

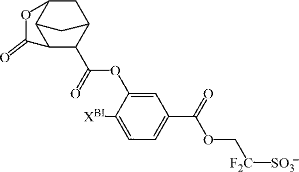

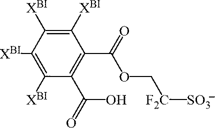

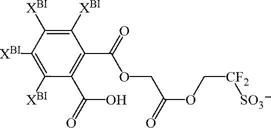

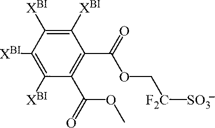

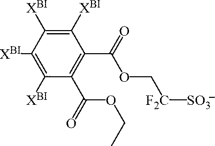

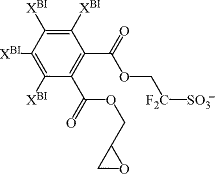

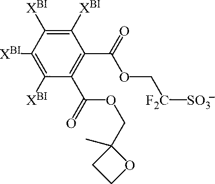

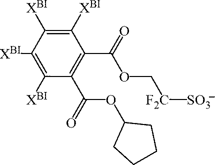

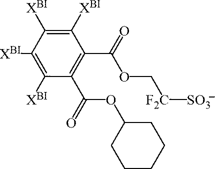

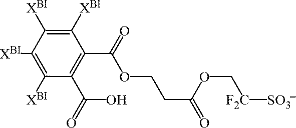

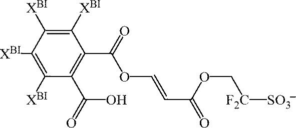

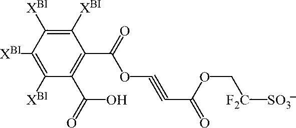

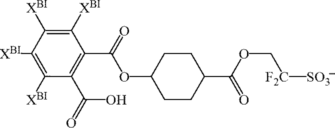

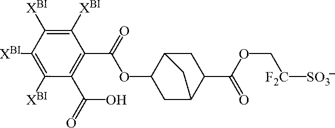

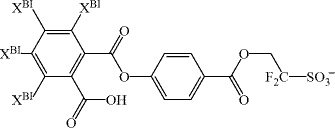

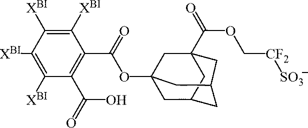

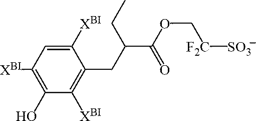

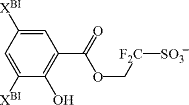

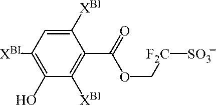

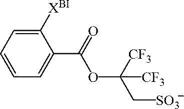

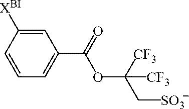

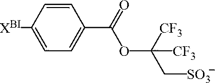

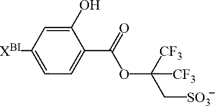

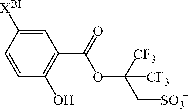

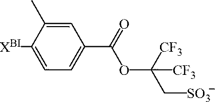

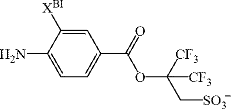

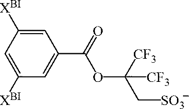

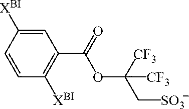

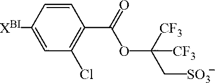

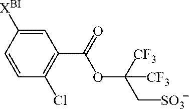

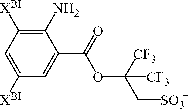

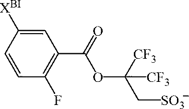

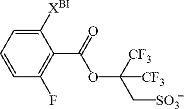

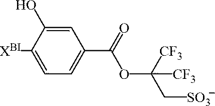

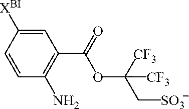

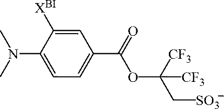

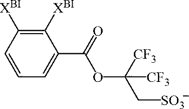

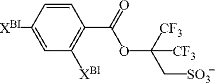

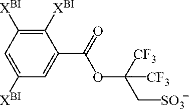

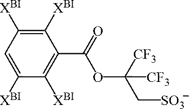

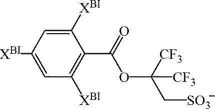

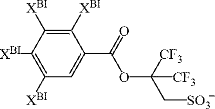

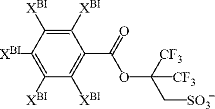

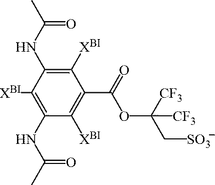

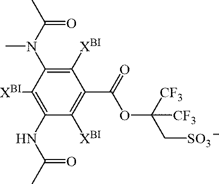

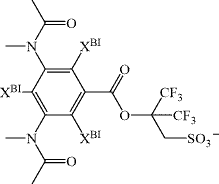

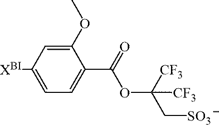

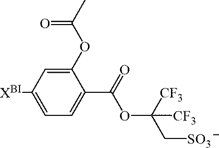

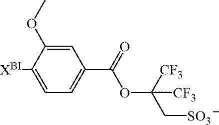

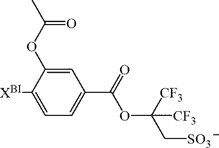

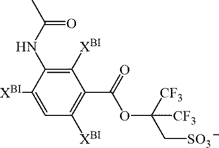

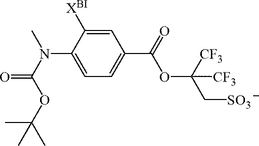

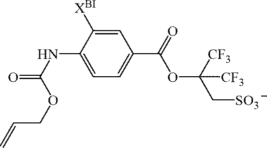

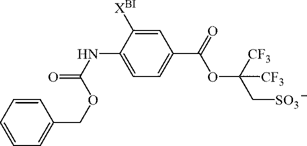

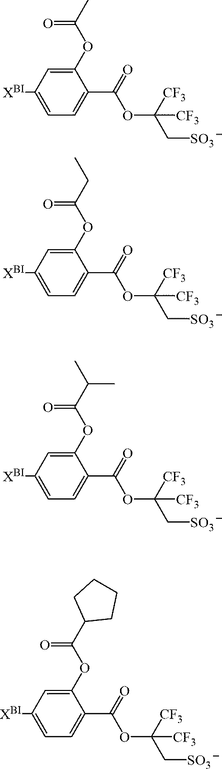

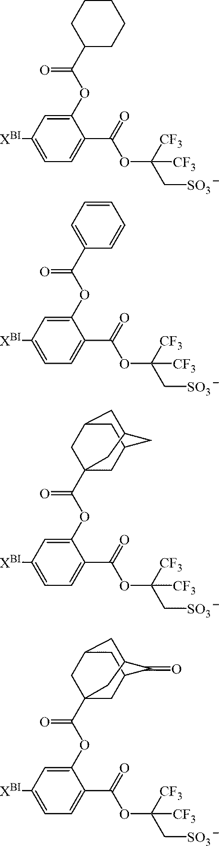

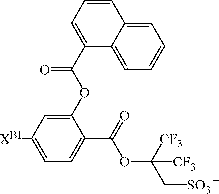

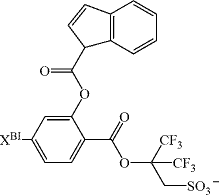

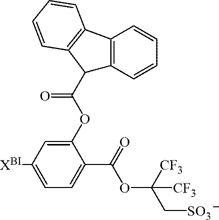

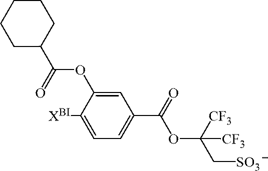

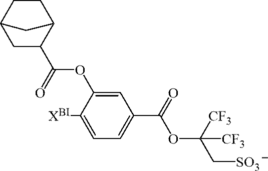

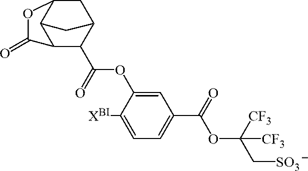

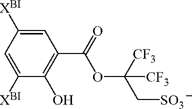

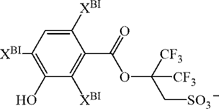

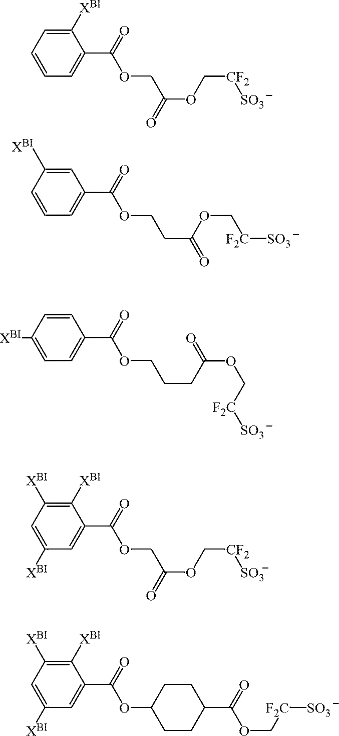

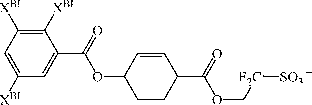

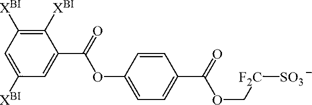

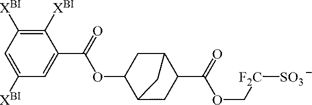

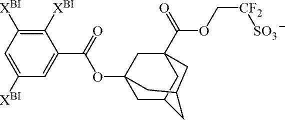

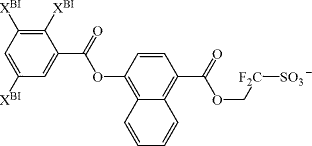

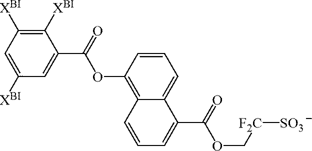

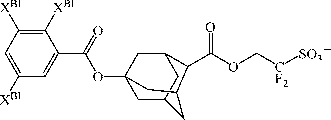

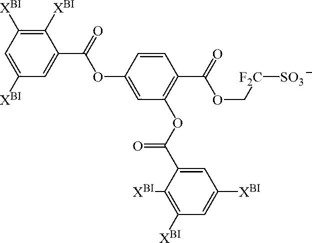

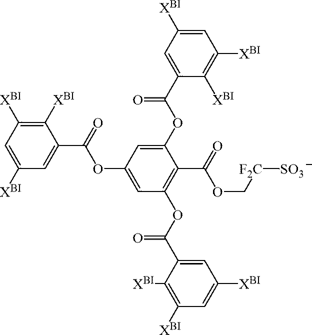

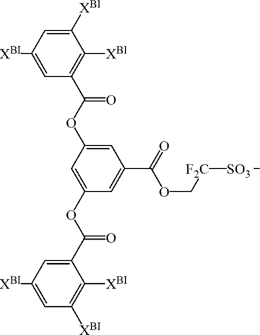

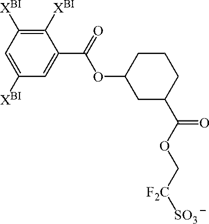

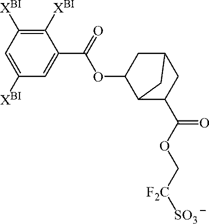

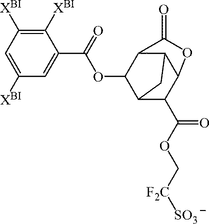

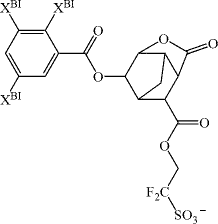

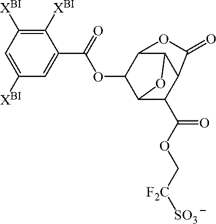

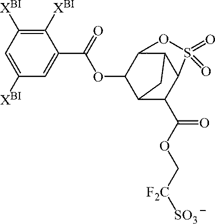

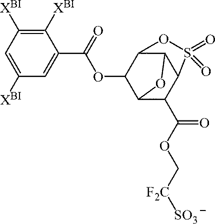

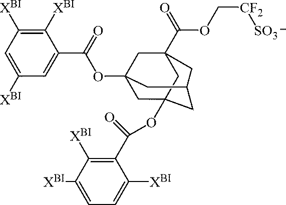

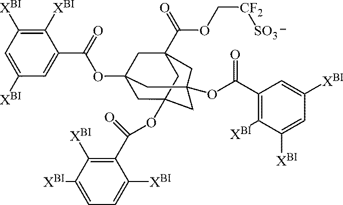

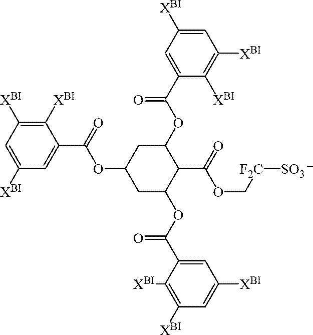

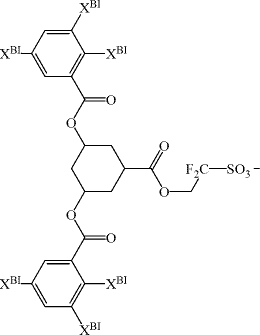

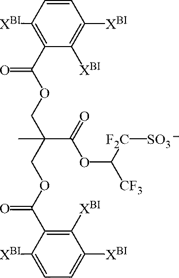

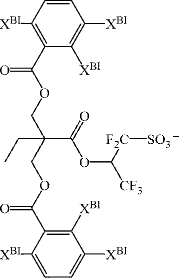

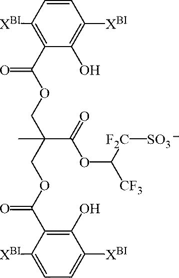

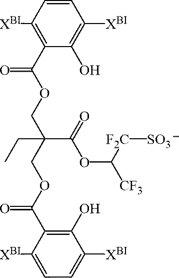

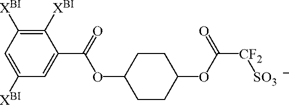

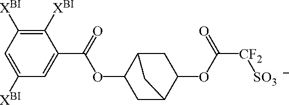

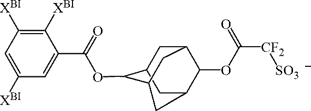

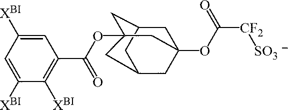

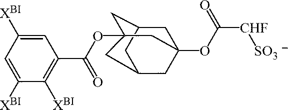

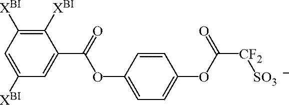

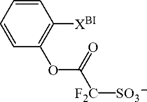

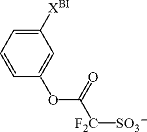

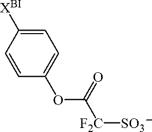

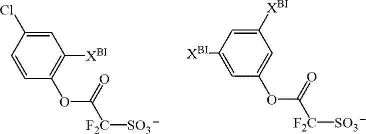

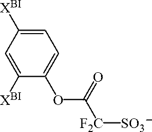

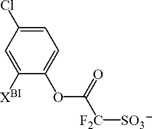

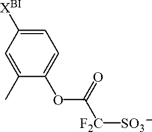

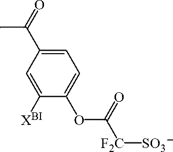

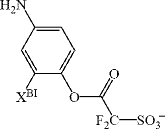

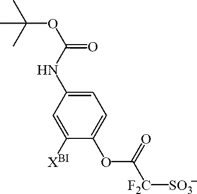

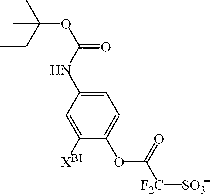

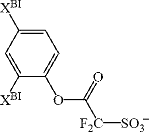

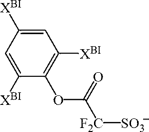

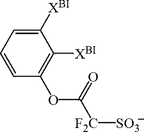

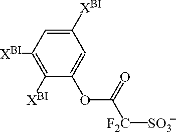

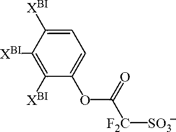

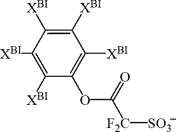

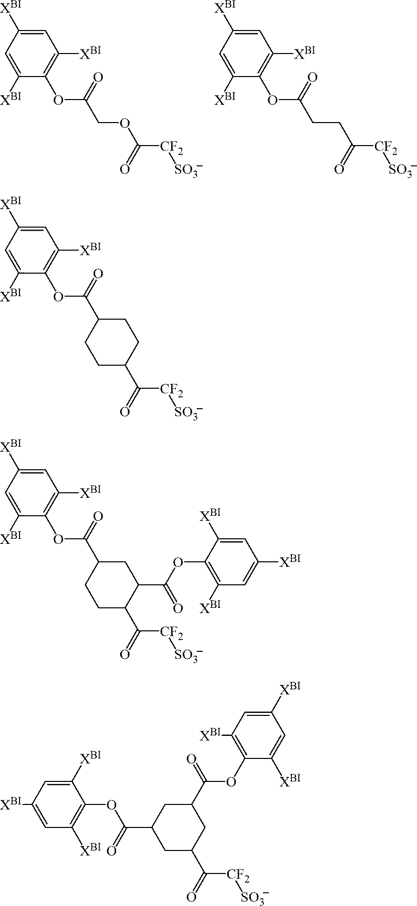

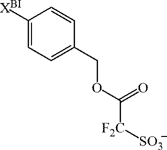

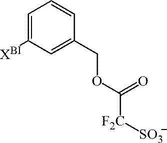

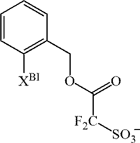

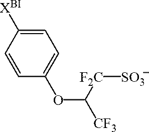

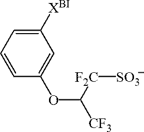

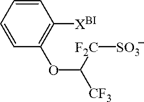

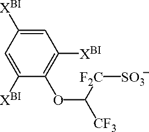

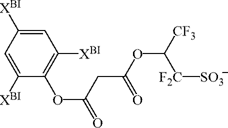

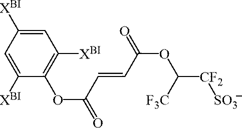

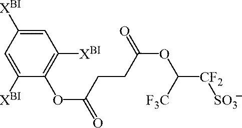

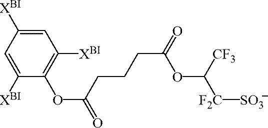

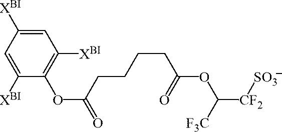

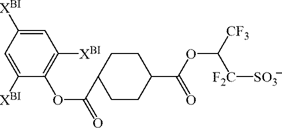

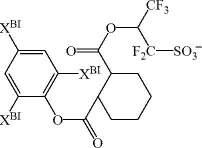

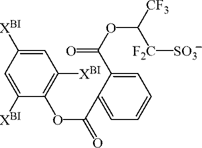

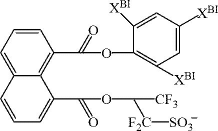

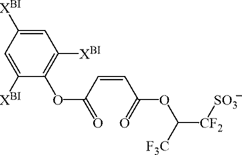

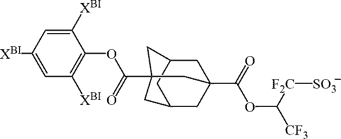

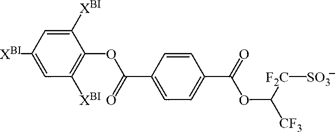

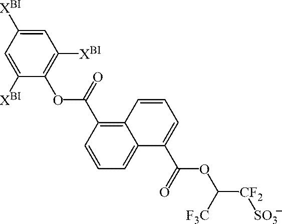

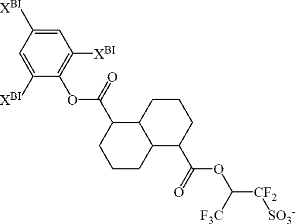

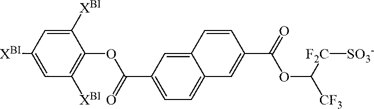

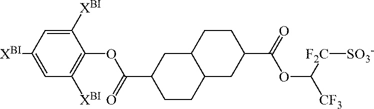

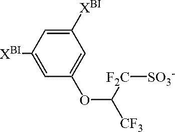

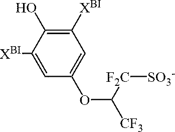

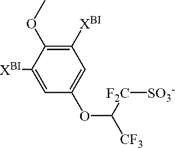

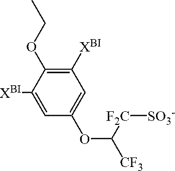

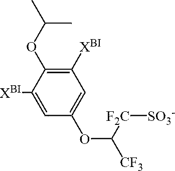

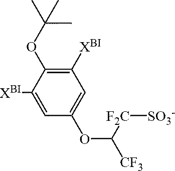

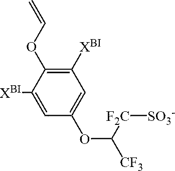

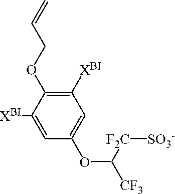

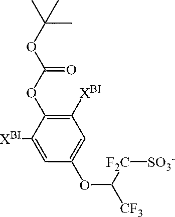

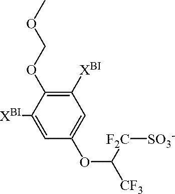

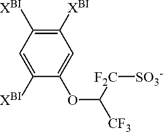

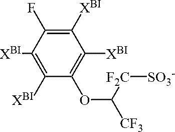

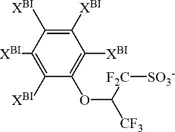

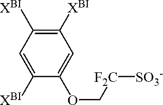

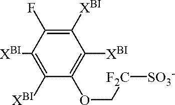

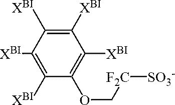

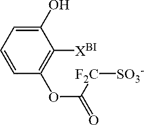

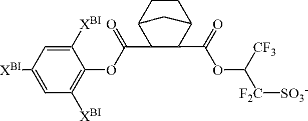

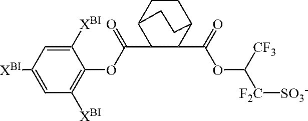

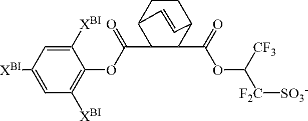

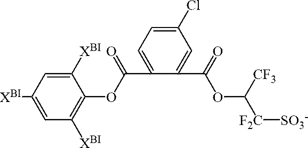

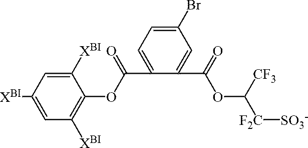

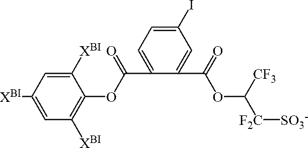

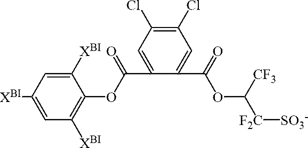

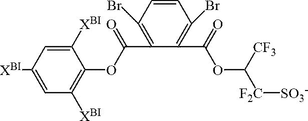

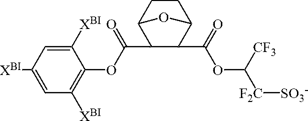

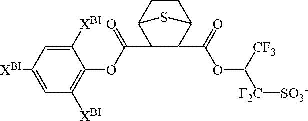

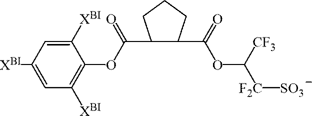

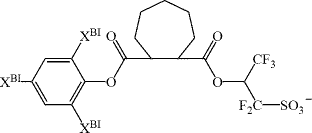

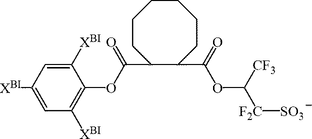

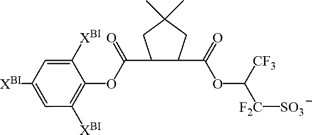

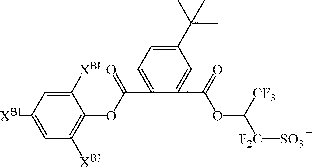

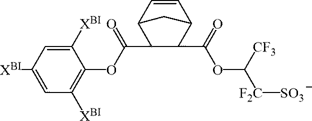

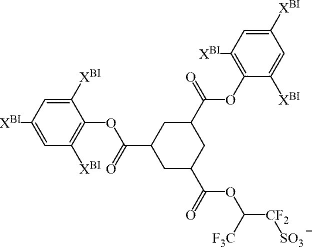

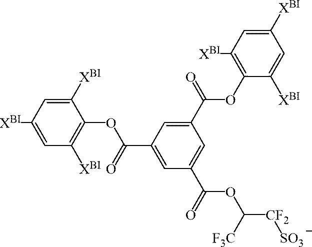

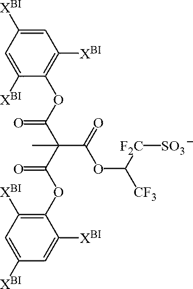

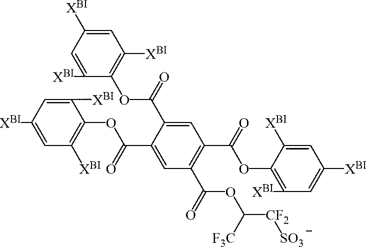

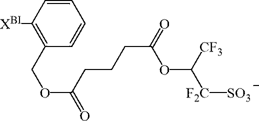

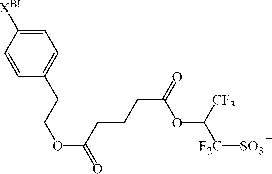

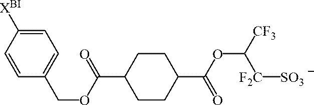

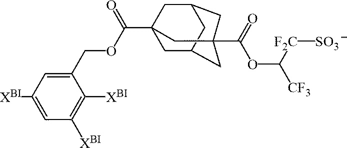

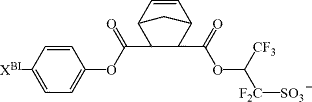

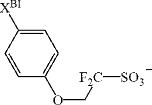

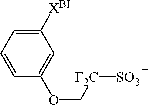

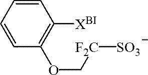

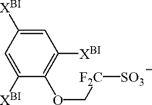

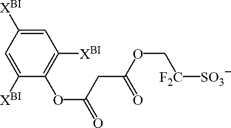

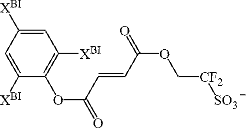

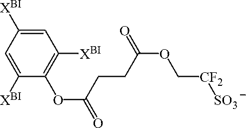

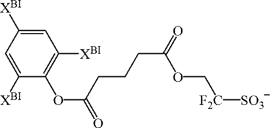

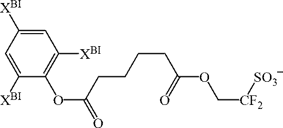

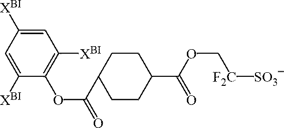

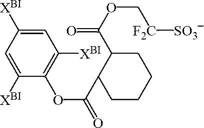

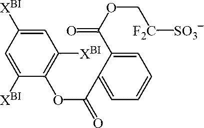

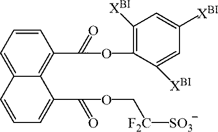

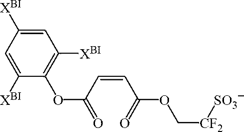

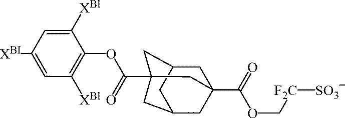

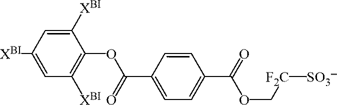

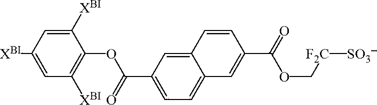

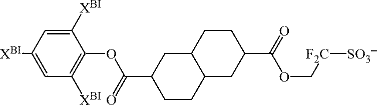

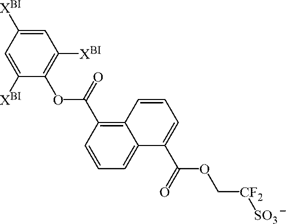

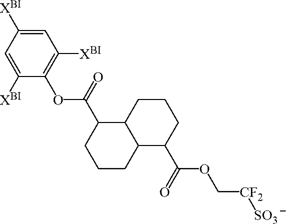

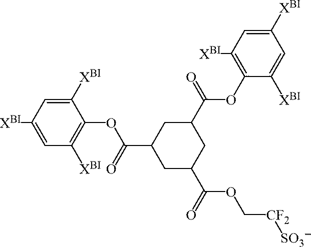

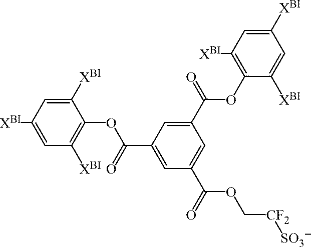

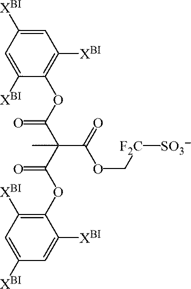

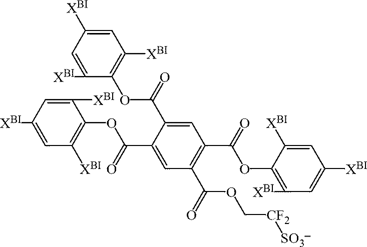

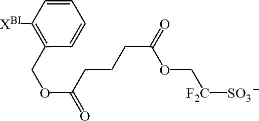

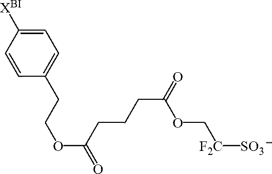

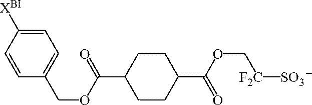

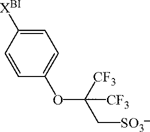

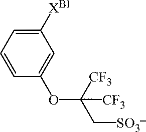

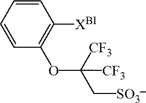

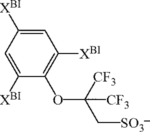

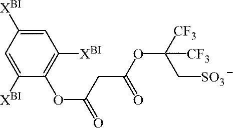

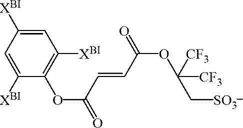

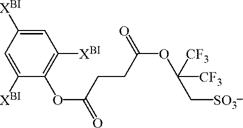

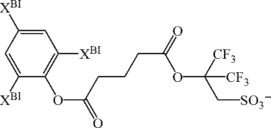

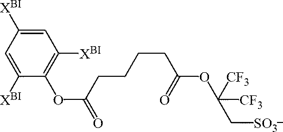

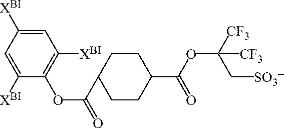

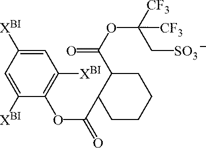

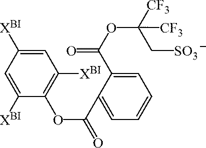

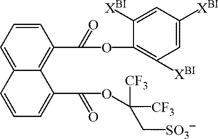

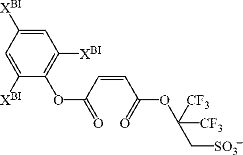

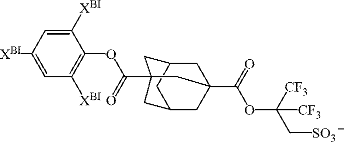

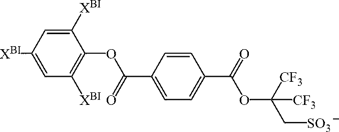

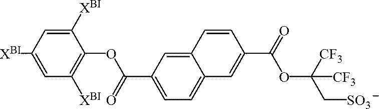

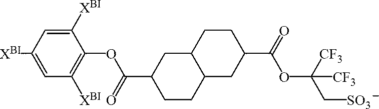

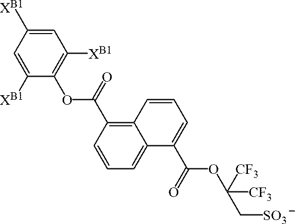

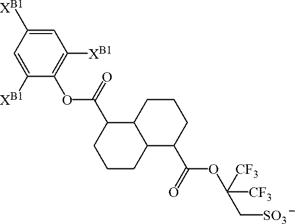

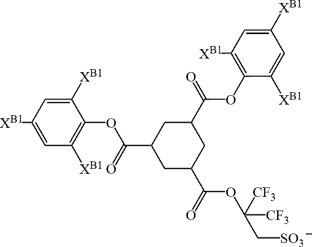

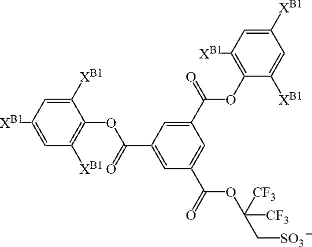

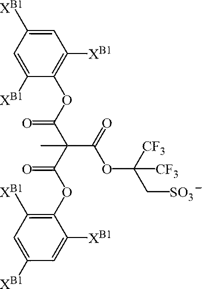

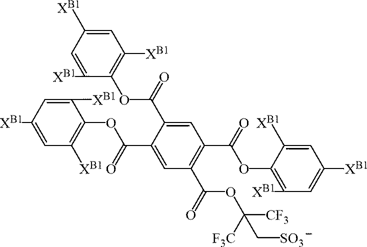

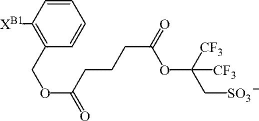

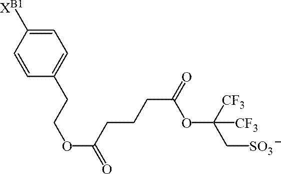

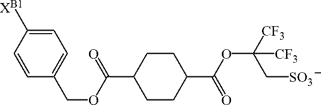

Other useful examples of the non-nucleophilic counter ion include fluorobenzenesulfonic acid anions having an iodized aromatic ring bonded thereto as described in JP 6648726, anions having an acid-catalyzed decomposition mechanism as described in WO 2021/200056 and JP-A 2021-070692, anions having a cyclic ether group as described in JP-A 2018-180525 and JP-A 2021-035935, and anions as described in JP-A 2018-092159.

Further useful examples of the non-nucleophilic counter ion include bulky fluorine-free benzenesulfonic acid anions as described in JP-A 2006-276759, JP-A 2015-117200, JP-A 2016-065016, and JP-A 2019-202974; fluorine-free benzenesulfonic acid or alkylsulfonic acid anions having an iodized aromatic group bonded thereto as described in JP 6645464.

Also useful are bissulfonic acid anions as described in JP-A 2015-206932, sulfonamide or sulfonimide anions having sulfonic acid side and different side as described in WO 2020/158366, and anions having a sulfonic acid side and a carboxylic acid side as described in JP-A 2015-024989.

The sulfonium salt having formula (1) may be synthesized, for example, by an ion exchange between a weak acid salt of the sulfonium cation and an ammonium salt having the non-nucleophilic counter ion.

In the resist composition, the sulfonium salt having formula (1) is preferably present in an amount of 0.01 to 1,000 parts by weight, more preferably 0.05 to 500 parts by weight per 100 parts by weight of the base polymer to be described below, in view of sensitivity and acid diffusion-suppressing effect.

### Base Polymer

In one preferred embodiment, the resist composition comprises a base polymer. When the resist composition is of positive tone, a base polymer comprising repeat units having an acid labile group is used. The repeat units having an acid labile group are preferably repeat units having the formula (a1) or repeat units having the formula (a2). These repeat units are also referred to as repeat units (a1) or (a2).

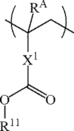

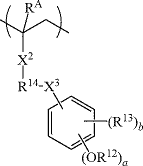

In formulae (a1) and (a2), R^{A} is each independently hydrogen or methyl. X¹ is a single bond, phenylene, naphthylene, or a C₁-C₁₂ linking group containing at least one moiety selected from an ester bond, ether bond and lactone ring. X² is a single bond or ester bond. X³ is a single bond, ether bond or ester bond. R¹¹ and R¹² are each independently an acid labile group. R¹³ is fluorine, trifluoromethyl, cyano, a C₁-C₆ saturated hydrocarbyl group, C₁-C₆ saturated hydrocarbyloxy group, C₂-C₇ saturated hydrocarbylcarbonyl group, C₂-C₇ saturated hydrocarbylcarbonyloxy group, or C₂-C₇ saturated hydrocarbyloxycarbonyl group. R¹⁴ is a single bond or a C₁-C₆ alkanediyl group in which some constituent —CH₂—may be replaced by an ether bond or ester bond. The subscript “a” is 1 or 2, “b” is an integer of 0 to 4, and a+b is from 1 to 5.

Examples of the monomer from which repeat units (a1) are derived are shown below, but not limited thereto. Herein R^{A} and R¹¹ are as defined above.

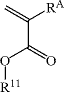

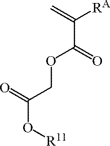

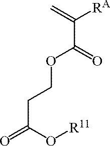

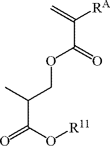

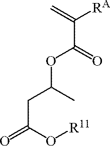

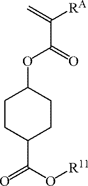

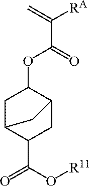

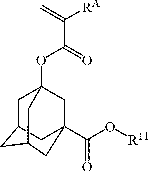

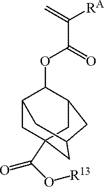

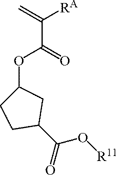

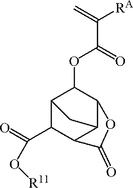

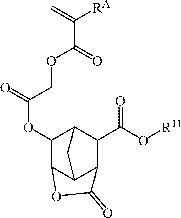

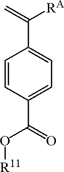

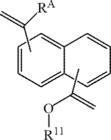

Examples of the monomer from which repeat units (a2) are derived are shown below, but not limited thereto. Herein R^{A} and R¹² are as defined above.

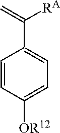

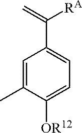

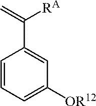

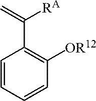

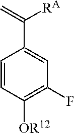

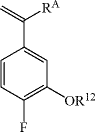

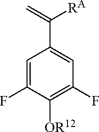

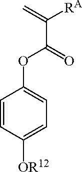

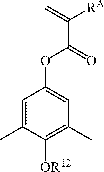

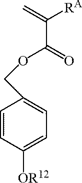

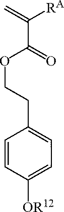

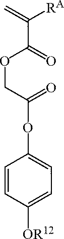

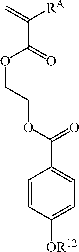

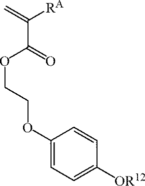

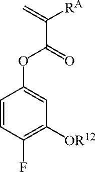

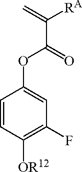

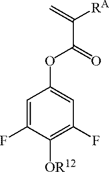

The acid labile groups represented by R¹¹ and R¹² in formulae (a1) and (a2) include those described in USP 8,574,817 (JP-A 2013-080033) and USP 8,846,303 (JP-A 2013-083821).

Typically, the acid labile groups are selected from groups having the following formulae (L-1) to (L-3).

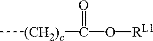

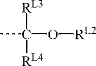

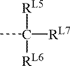

In formulae (L-1) and (L-2), R^{L1} and R^{L2} are each independently a C₁-C₄₀ hydrocarbyl group which may contain a heteroatom such as oxygen, sulfur, nitrogen or fluorine. The hydrocarbyl group may be saturated or unsaturated and straight, branched or cyclic. Preferred are C₁-C₄₀, especially C₁-C₂₀ saturated hydrocarbyl groups.

In formula (L-1), c is an integer of 0 to 10, preferably 1 to 5.

In formula (L-2), R^{L3} and R^{L4} are each independently hydrogen or a C₁-C₂₀ hydrocarbyl group which may contain a heteroatom such as oxygen, sulfur, nitrogen or fluorine. The hydrocarbyl group may be saturated or unsaturated and straight, branched or cyclic. Preferred are C₁-C₂₀ saturated hydrocarbyl groups. Any two of R^{L2}, R^{L3} and R^{L4} may bond together to form a ring, typically alicyclic, with the carbon atom or carbon and oxygen atoms to which they are attached, the ring containing 3 to 20 carbon atoms, preferably 4 to 16 carbon atoms.

In formula (L-3), R^{L5}, R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Preferred are C₁-C₂₀ saturated hydrocarbyl groups. Any two of R^{L5}, R^{L6} and R^{L7} may bond together to form a ring, typically alicyclic, with the carbon atom to which they are attached, the ring containing 3 to 20 carbon atoms, preferably 4 to 16 carbon atoms.

The base polymer may further comprise repeat units (b) having a phenolic hydroxy group as an adhesive group. Examples of suitable monomers from which repeat units (b) are derived are given below, but not limited thereto. Herein R^{A} is as defined above.

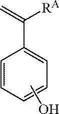

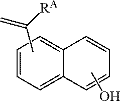

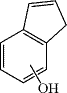

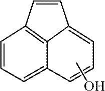

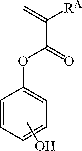

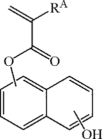

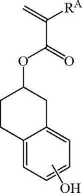

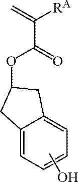

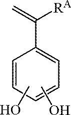

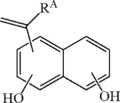

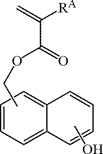

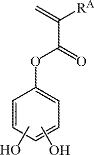

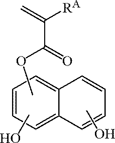

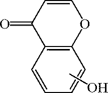

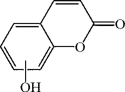

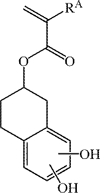

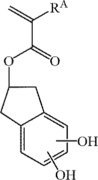

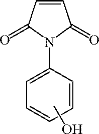

Further, repeat units (c) having another adhesive group selected from hydroxy (other than the foregoing phenolic hydroxy), lactone ring, sultone ring, ether bond, ester bond, sulfonic ester bond, carbonyl, sulfonyl, cyano and carboxy groups may also be incorporated in the base polymer. Examples of suitable monomers from which repeat units (c) are derived are given below, but not limited thereto. Herein R^{A} is as defined above.

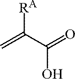

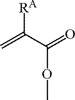

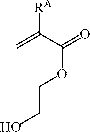

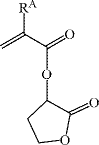

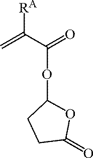

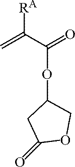

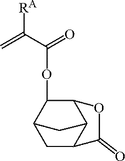

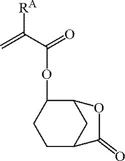

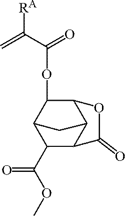

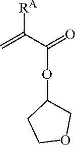

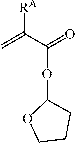

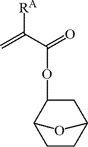

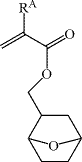

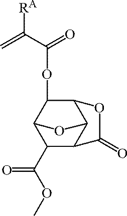

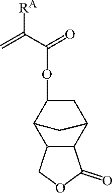

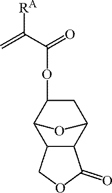

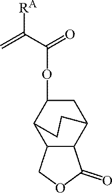

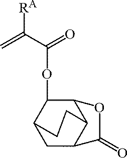

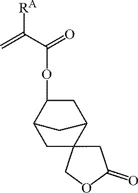

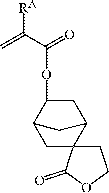

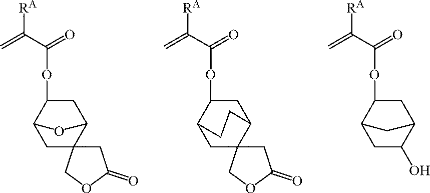

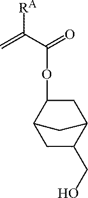

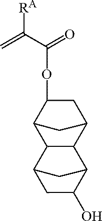

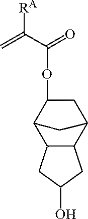

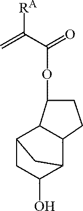

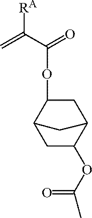

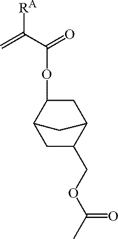

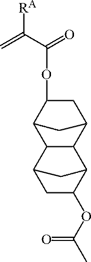

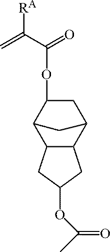

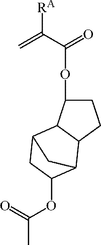

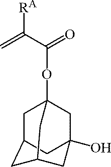

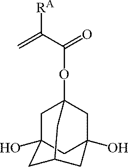

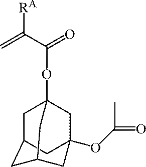

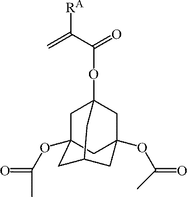

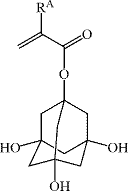

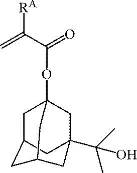

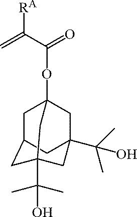

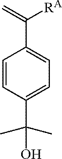

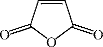

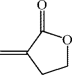

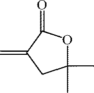

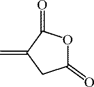

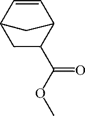

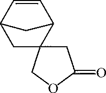

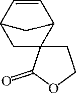

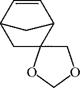

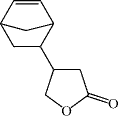

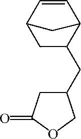

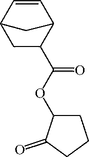

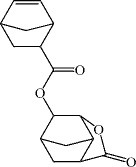

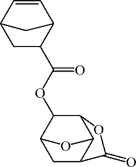

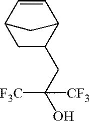

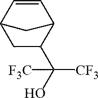

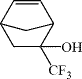

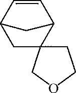

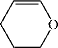

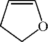

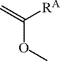

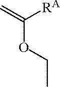

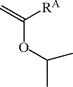

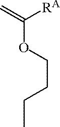

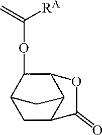

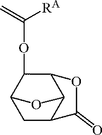

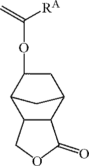

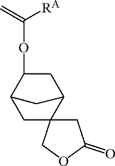

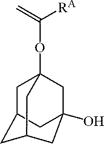

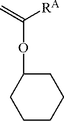

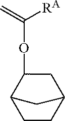

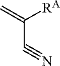

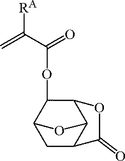

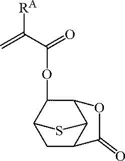

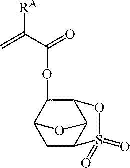

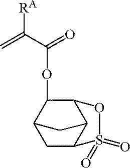

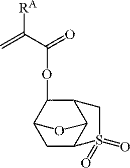

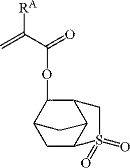

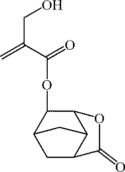

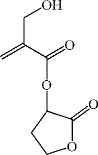

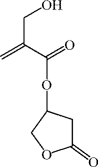

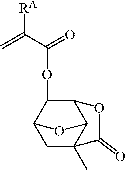

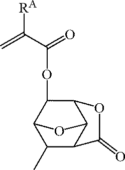

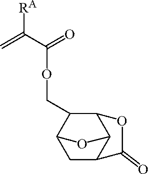

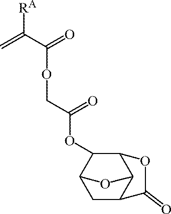

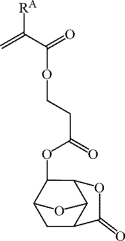

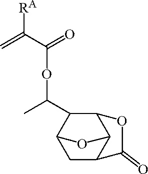

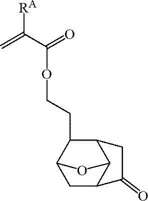

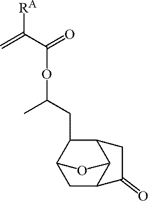

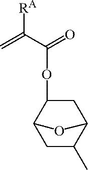

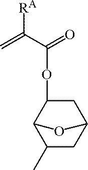

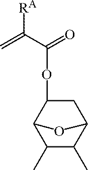

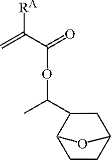

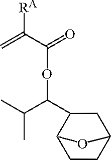

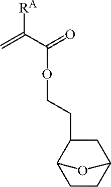

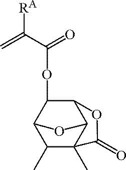

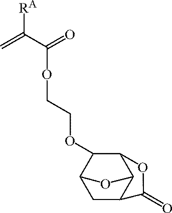

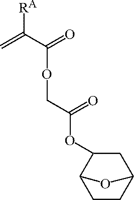

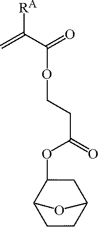

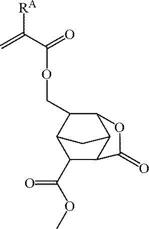

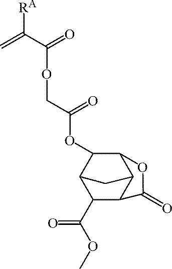

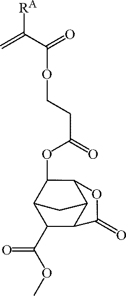

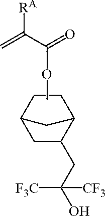

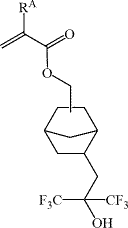

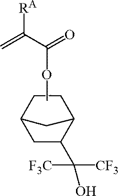

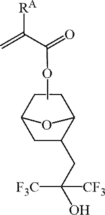

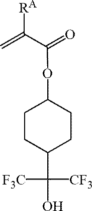

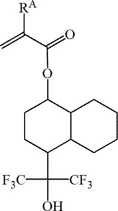

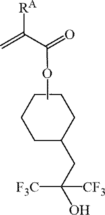

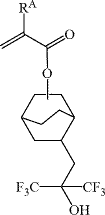

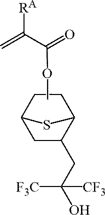

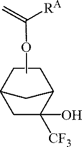

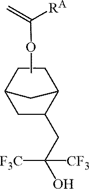

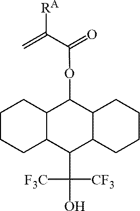

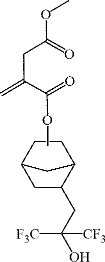

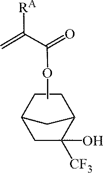

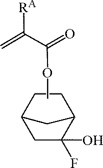

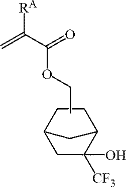

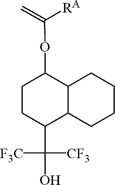

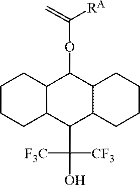

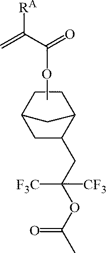

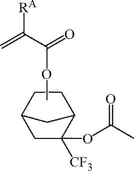

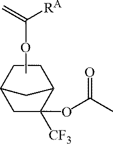

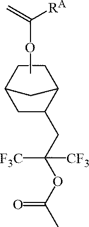

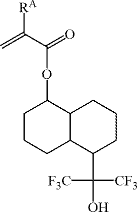

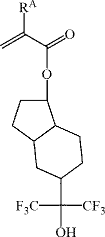

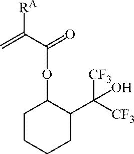

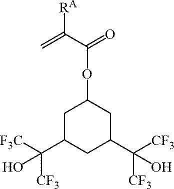

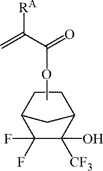

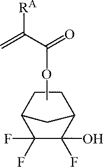

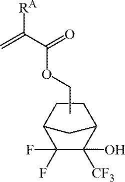

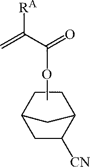

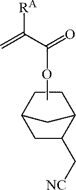

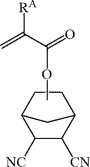

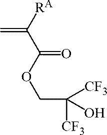

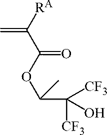

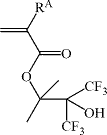

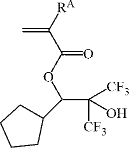

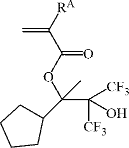

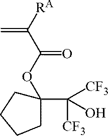

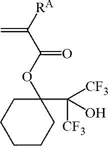

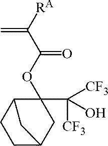

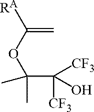

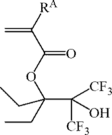

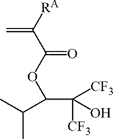

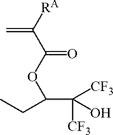

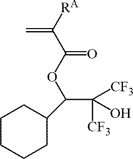

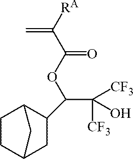

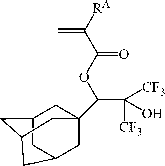

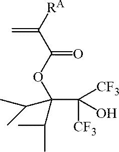

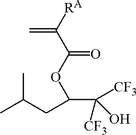

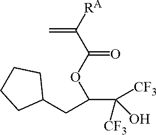

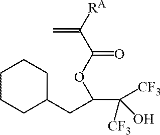

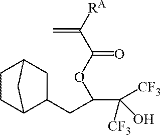

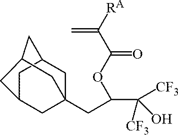

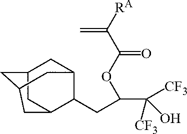

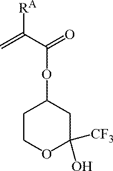

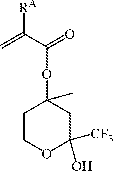

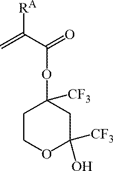

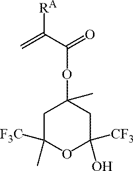

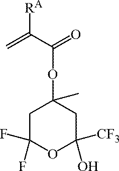

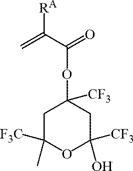

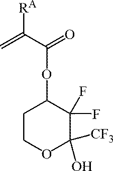

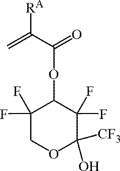

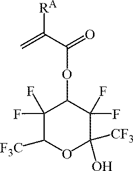

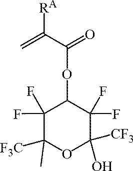

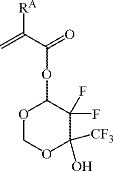

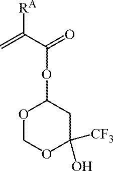

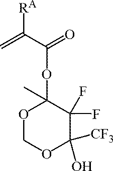

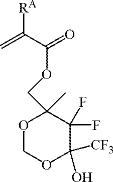

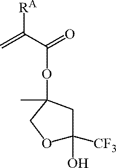

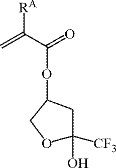

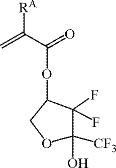

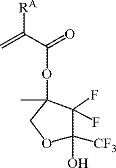

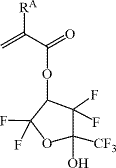

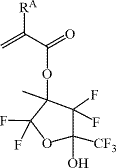

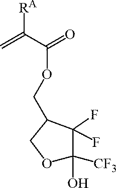

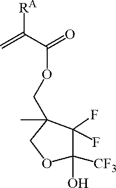

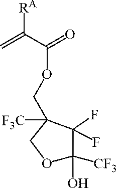

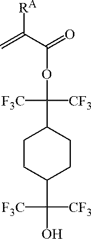

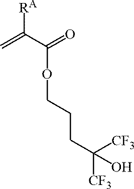

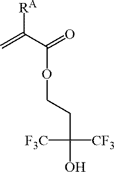

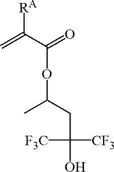

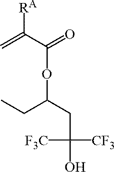

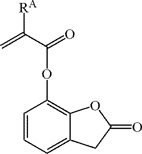

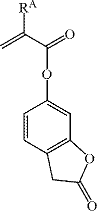

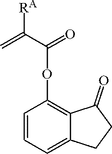

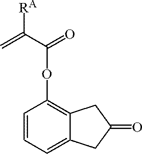

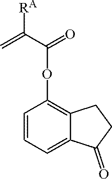

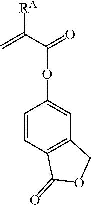

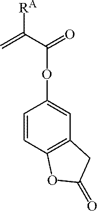

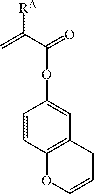

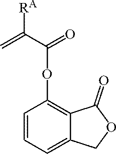

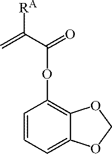

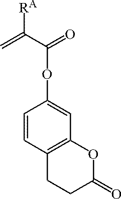

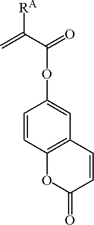

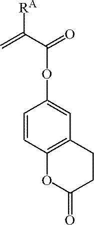

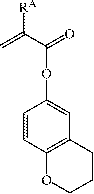

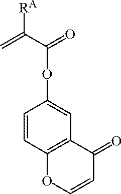

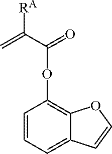

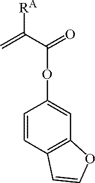

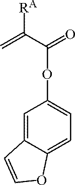

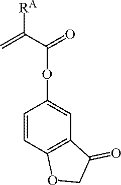

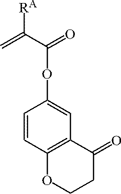

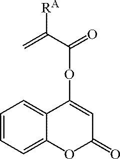

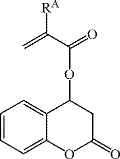

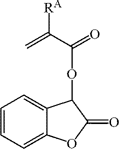

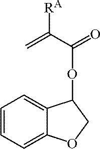

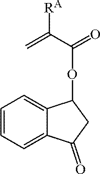

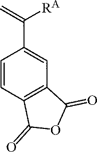

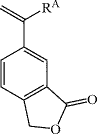

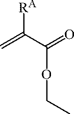

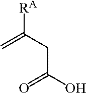

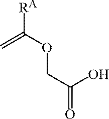

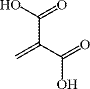

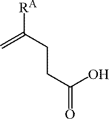

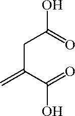

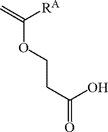

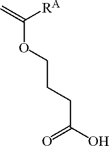

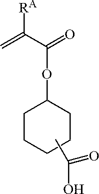

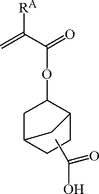

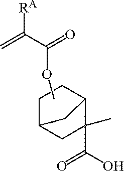

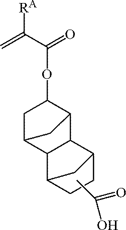

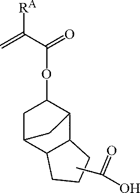

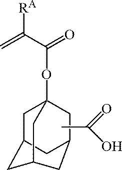

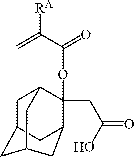

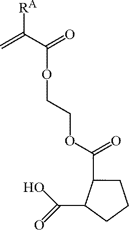

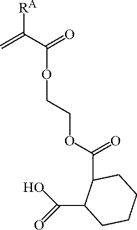

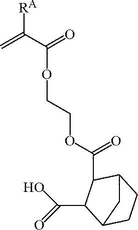

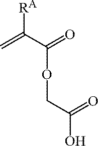

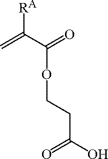

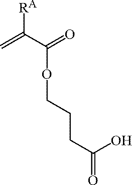

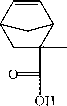

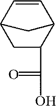

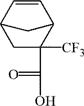

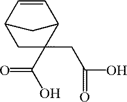

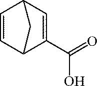

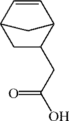

In another preferred embodiment, the base polymer may further comprise repeat units (d) derived from indene, benzofuran, benzothiophene, acenaphthylene, chromone, coumarin, and norbomadiene, or derivatives thereof. Examples of suitable monomers from which repeat units (d) are derived are given below, but not limited thereto.

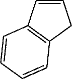

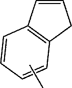

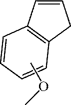

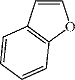

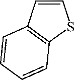

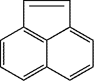

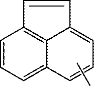

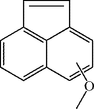

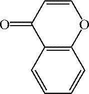

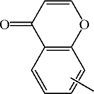

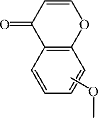

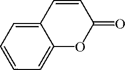

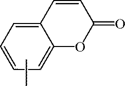

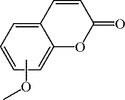

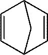

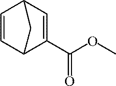

The base polymer may further include repeat units (e) which are derived from styrene, vinylnaphthalene, vinylanthracene, vinylpyrene, methyleneindene, vinylpyridine, vinylcarbazole, or derivatives thereof.

In a further embodiment, the base polymer may further comprise repeat units (f) derived from an onium salt having a polymerizable unsaturated bond. The preferred repeat units (f) include repeat units having formula (f1), repeat units having formula (f2), and repeat units having formula (f3). These units are simply referred to as repeat units (f1), (f2) and (f3), which may be used alone or in combination of two or more types.

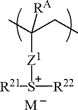

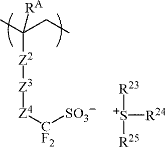

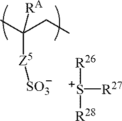

In formulae (fl) to (f3), R^{A} is each independently hydrogen or methyl. Z¹ is a single bond, a C₁-C₆ aliphatic hydrocarbylene group, phenylene, naphthylene or a C₇-C₁₈ group obtained by combining the foregoing, or —O—Z¹¹—, —C(═O)—O—Z¹¹— or —C(═O)—NH—Z¹¹—, wherein Z¹¹ is a C₁-C₆ aliphatic hydrocarbylene group, phenylene, naphthylene or a C₇-C₁₈ group obtained by combining the foregoing, which may contain a carbonyl moiety, ester bond, ether bond or hydroxy moiety. Z² is a single bond or ester bond. Z³ is a single bond, —Z³¹—C(═O)—O—, —Z³¹—O— or —Z³¹—O—C(═O)—, wherein Z³¹ is a C₁-C₁₂ hydrocarbylene group, phenylene or a C₇-C₁₈ group obtained by combining the foregoing, which may contain a carbonyl moiety, ester bond, ether bond, iodine or bromine. Z⁴ is methylene, 2,2,2-trifluoro-1,1-ethanediyl or carbonyl. Z⁵ is a single bond, methylene, ethylene, phenylene, fluorinated phenylene, trifluoromethyl-substituted phenylene, —O—Z⁵¹—, —C(═O)—O—Z⁵¹—, or —C(═O)—NH—Z⁵¹—, wherein Z⁵¹ is a C₁-C₆ aliphatic hydrocarbylene group, phenylene, fluorinated phenylene, or trifluoromethyl-substituted phenylene group, which may contain a carbonyl moiety, ester bond, ether bond, halogen or hydroxy moiety.

In formulae (f1) to (f3), R²¹ to R²⁸ are each independently halogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl group R⁴ in formula (1). In the hydrocarbyl group, some or all hydrogen atoms may be substituted by a moiety containing a heteroatom such as oxygen, sulfur, nitrogen or halogen and some constituent —CH₂— may be replaced by a moiety containing a heteroatom such as oxygen, sulfur or nitrogen, so that the group may contain hydroxy, fluorine, chlorine, bromine, iodine, cyano, nitro, carbonyl, ether bond, ester bond, sulfonic ester bond, carbonate bond, lactone ring, sultone ring, carboxylic anhydride (—C(═O)—O—C(═O)—), or haloalkyl moiety. A pair of R²³ and R²⁴, or R²⁶ and R²⁷ may bond together to form a ring with the sulfur atom to which they are attached. Examples of the ring are as exemplified for the ring that two groups R⁴ in formula (1), taken together, form with the sulfur atom to which they are attached.

In formula (f1), M⁻ is a non-nucleophilic counter ion. Examples thereof include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; and methide ions such as tris(trifluoromethylsulfonyl)methide and tris(perfluoroethylsulfonyl)methide.

As the non-nucleophilic counter ion M⁻, an anion having any one of formulae (1A) to (1E) is also applicable.

Examples of the cation in the monomer from which repeat unit (f1) is derived are shown below, but not limited thereto. R^{A} is as defined above.

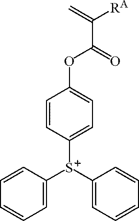

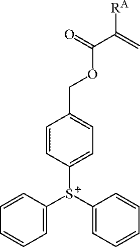

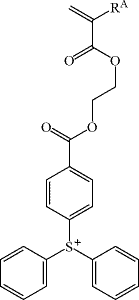

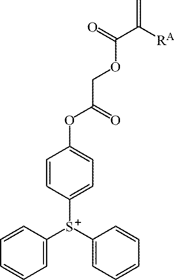

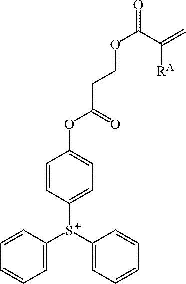

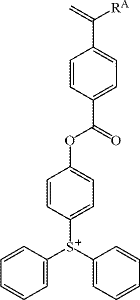

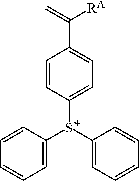

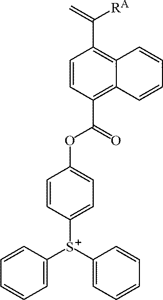

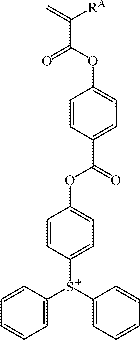

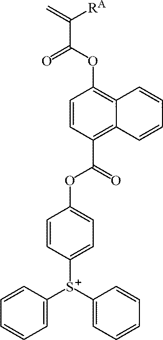

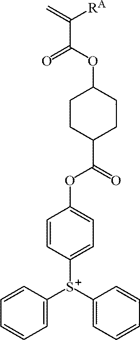

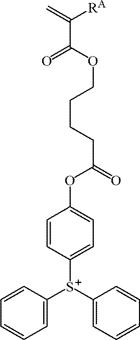

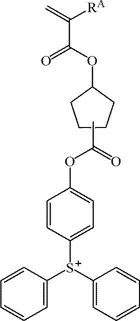

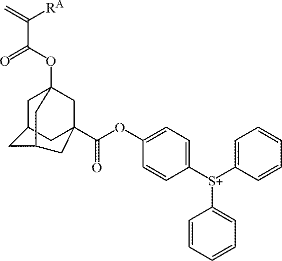

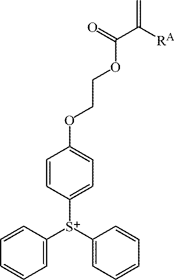

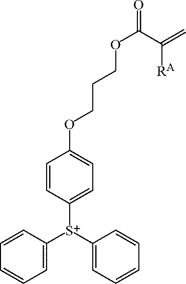

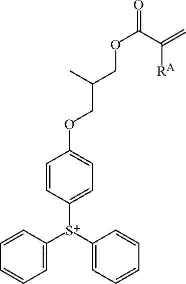

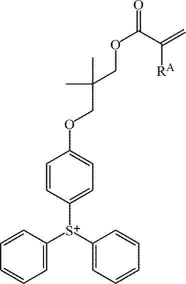

Examples of the cation in the monomer from which repeat unit (f2) or (f3) is derived include the sulfonium cations described in JP-A 2017-219836.

Examples of the anion in the monomer from which repeat unit (f2) is derived are shown below, but not limited thereto. R^{A} is as defined above.

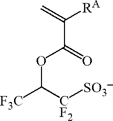

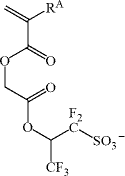

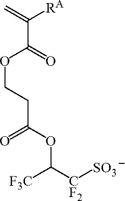

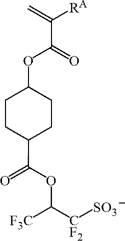

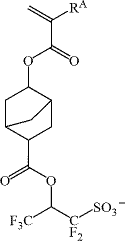

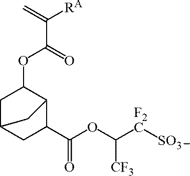

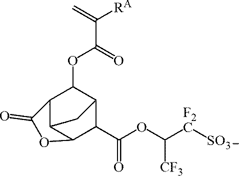

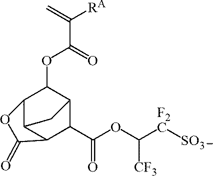

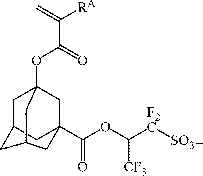

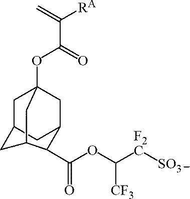

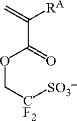

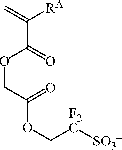

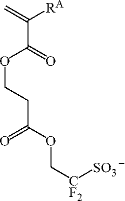

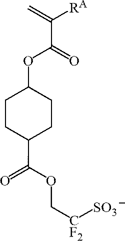

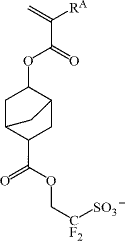

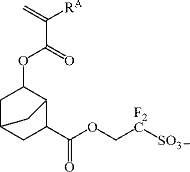

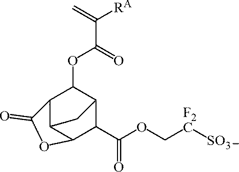

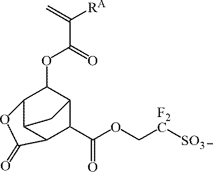

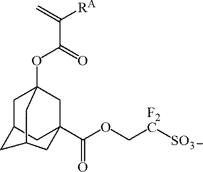

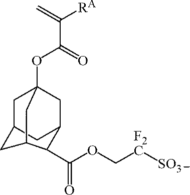

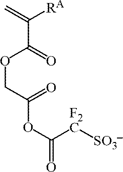

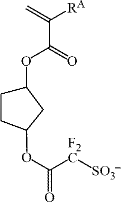

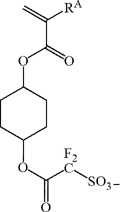

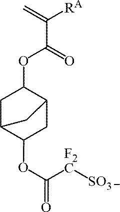

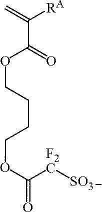

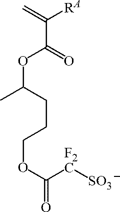

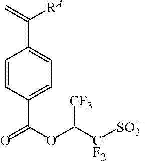

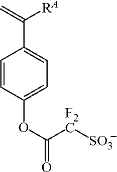

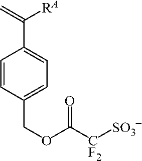

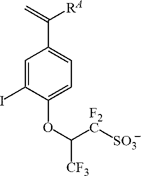

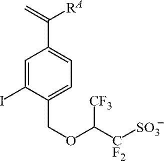

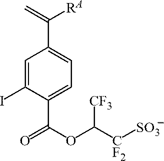

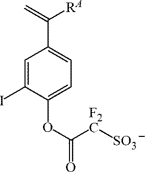

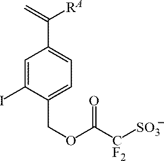

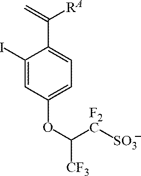

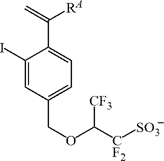

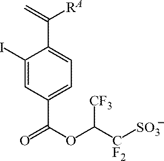

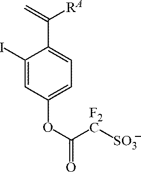

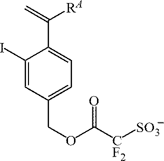

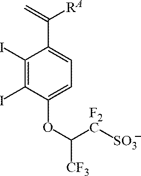

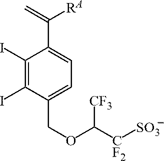

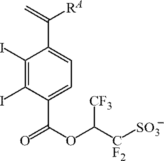

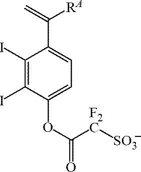

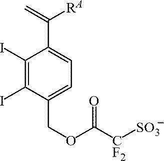

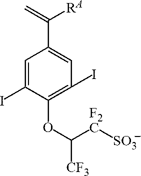

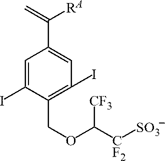

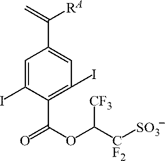

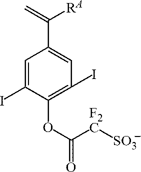

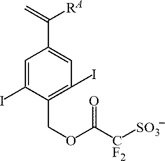

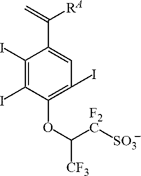

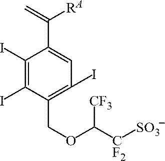

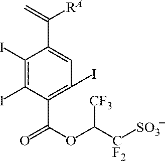

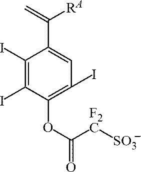

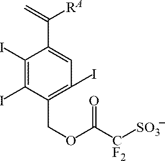

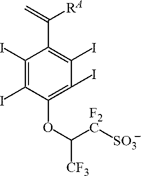

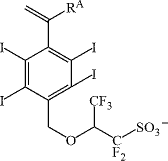

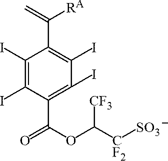

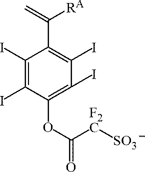

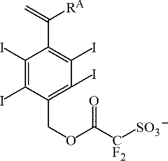

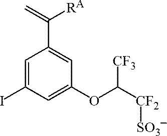

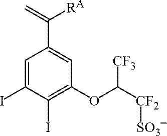

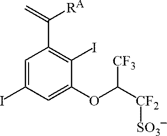

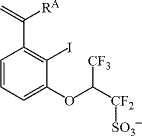

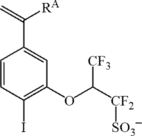

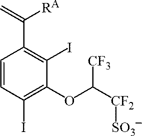

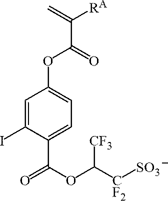

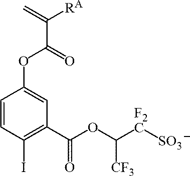

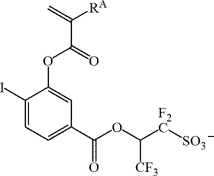

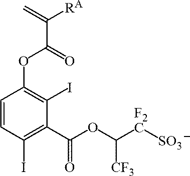

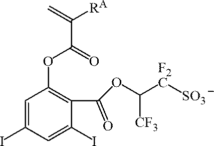

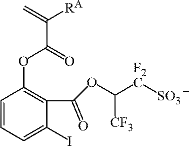

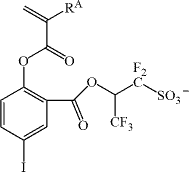

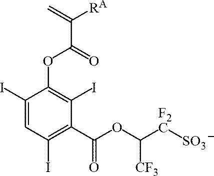

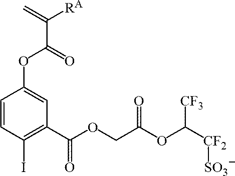

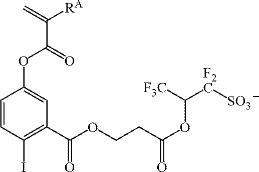

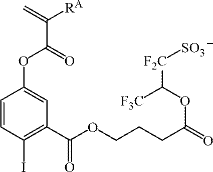

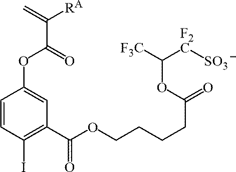

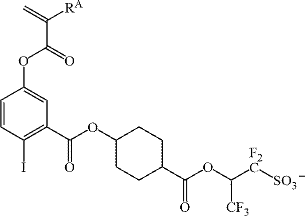

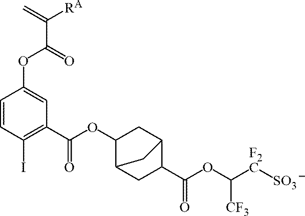

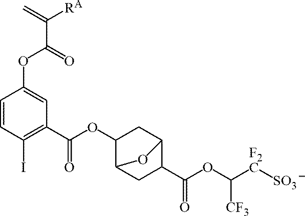

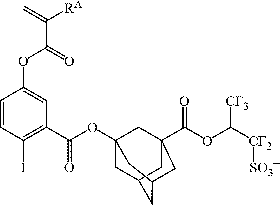

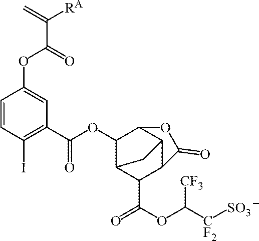

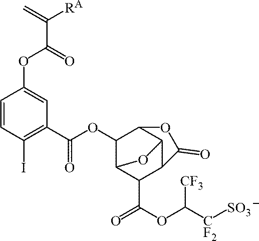

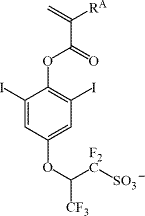

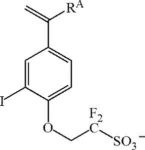

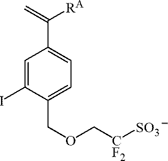

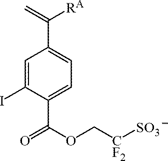

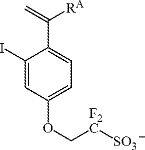

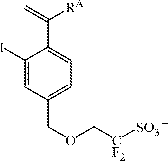

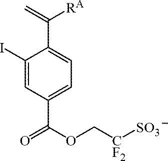

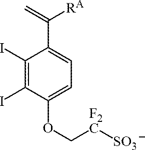

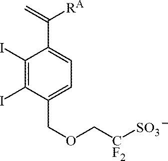

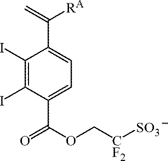

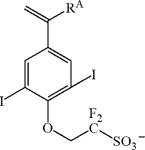

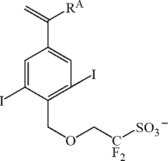

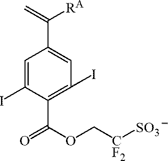

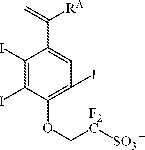

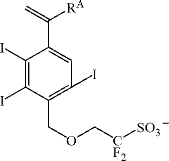

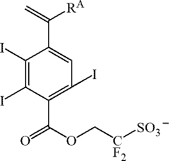

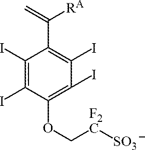

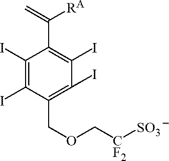

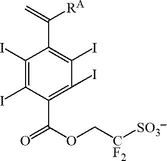

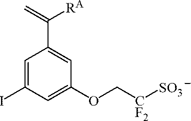

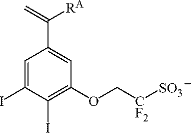

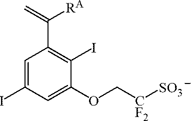

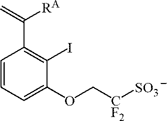

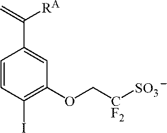

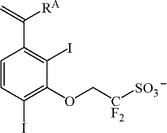

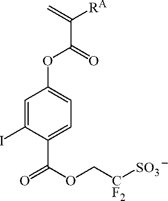

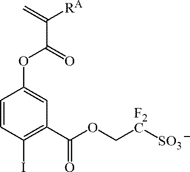

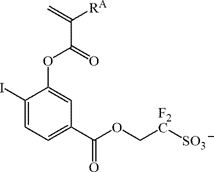

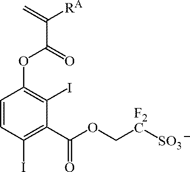

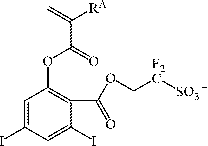

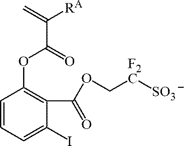

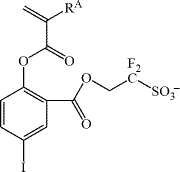

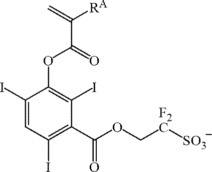

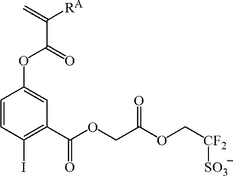

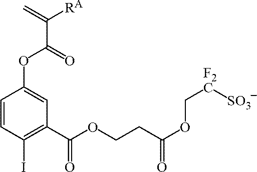

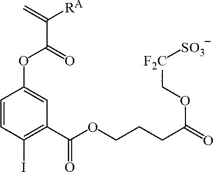

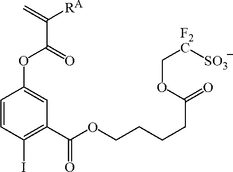

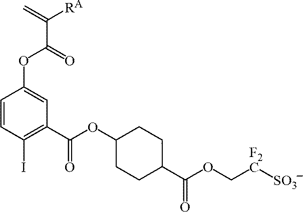

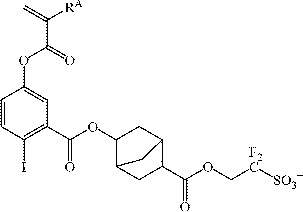

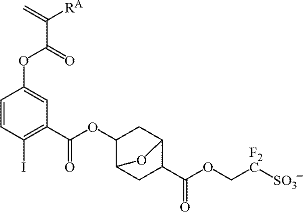

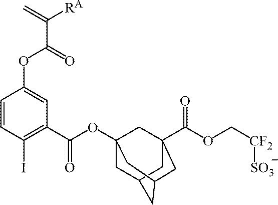

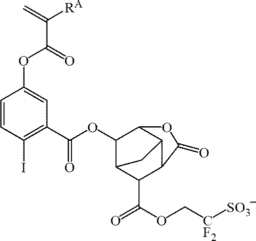

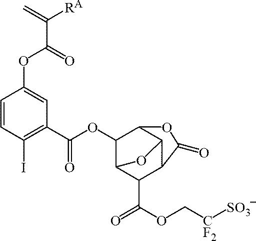

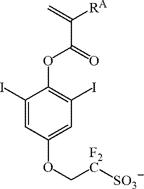

Examples of the anion in the monomer from which repeat unit (f3) is derived are shown below, but not limited thereto. R^{A} is as defined above.

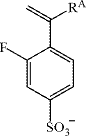

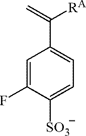

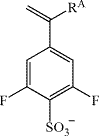

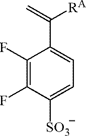

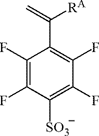

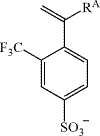

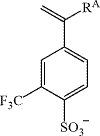

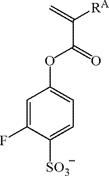

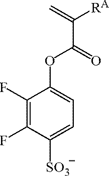

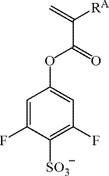

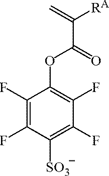

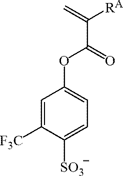

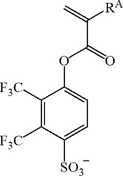

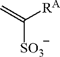

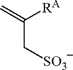

The attachment of an acid generator to the polymer main chain is effective in restraining acid diffusion, thereby preventing a reduction of resolution due to blur by acid diffusion. Also LWR or CDU is improved since the acid generator is uniformly distributed.

The base polymer for formulating the positive resist composition comprises repeat units (a1) or (a2) having an acid labile group as essential component and additional repeat units (b), (c), (d), (e), and (f) as optional components. A fraction of units (a1), (a2), (b), (c), (d), (e), and (f) is: preferably 0 ≤ a1 < 1.0, 0 ≤ a2 < 1.0, 0 < a1+a2 < 1.0, 0 ≤ b ≤ 0.9, 0 ≤ c ≤ 0.9,0 ≤ d ≤ 0.8, 0 ≤ e ≤ 0.8, and 0 ≤ f ≤ 0.5; more preferably 0 ≤ a1 ≤ 0.9, 0 ≤ a2 ≤ 0.9, 0.1 ≤ a1+a2 ≤ 0.9, 0 ≤ b ≤ 0.8,0 ≤ c ≤ 0.8, 0 ≤ d ≤ 0.7, 0 ≤ e ≤ 0.7, and 0 ≤ f ≤ 0.4; and even more preferably 0 ≤ a1 ≤ 0.8, 0 ≤ a2 ≤ 0.8, 0.1 ≤ a1+a2 ≤ 0.8, 0 ≤ b ≤ 0.75, 0 ≤ c ≤ 0.75, 0 ≤ d ≤ 0.6, 0 ≤ e ≤ 0.6, and 0 ≤ f ≤ 0.3. Notably, f = f1+f2+f3, meaning that unit (f) is at least one of units (f1) to (f3), and a1+a2-rb+c+d+e+f = 1.0.

For the base polymer for formulating the negative resist composition, an acid labile group is not necessarily essential. The base polymer comprises repeat units (b), and optionally repeat units (c), (d), (e), and/or (f). A fraction of these units is: preferably 0 ≤ b ≤ 1.0, 0 ≤ c ≤ 0.9, 0 ≤ d ≤ 0.8, 0 ≤ e ≤ 0.8, and 0 ≤ f ≤ 0.5; more preferably 0.2 ≤ b ≤ 1.0, 0 ≤ c ≤ 0.8, 0 ≤ d ≤ 0.7.0 ≤ e ≤ 0.7, and 0 ≤ f ≤ 0.4; and even more preferably 0.3 ≤ b ≤ 1.0, 0 ≤ c ≤ 0.75, 0 ≤ d ≤ 0.6, 0 ≤ e ≤ 0.6, and 0 ≤ f ≤ 0.3. Notably, f = f1+f2+f3, meaning that unit (f) is at least one of units (f1) to (f3), and b+c+d+e+f = 1.0.

The base polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran, diethyl ether, and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the polymerization temperature is 50 to 80° C., and the reaction time is 2 to 100 hours, more preferably 5 to 20 hours.

When a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinyinaphthalene, and after polymerization, the acetoxy group is deprotected by alkaline hydrolysis, for thereby converting the polymer product to hydroxystyrene or hydroxyvinyinaphthalene. For alkaline hydrolysis, a base such as aqueous ammonia or triethylamine may be used. Preferably the reaction temperature is -20° C. to 100° C., more preferably 0° C. to 60° C., and the reaction time is 0.2 to 100 hours, more preferably 0.5 to 20 hours.

The base polymer should preferably have a weight average molecular weight (Mw) in the range of 1,000 to 500,000, and more preferably 2,000 to 30,000, as measured by GPC versus polystyrene standards using tetrahydrofirran (THF) solvent. A Mw in the range ensures that the resist film has heat resistance and high solubility in alkaline developer.

If a base polymer has a wide molecular weight distribution or dispersity (Mw/Mn), which indicates the presence of lower and higher molecular weight polymer fractions. there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

It is understood that a blend of two or more polymers which differ in compositional ratio. Mw or Mw/Mn is acceptable.

### Organic Solvent

An organic solvent may be added to the resist composition. The organic solvent used herein is not particularly limited as long as the foregoing and other components are soluble therein. Examples of the organic solvent are described in JP-A 2008-111103, paragraphs [0144]-[0145] (USP 7,537,880). Exemplary solvents include ketones such as cyclohexanone, cyclopentanone, methyl-2-n-pentyl ketone and 2-heptanone; alcohols such as 3-methoxybutmol, 3-methyl-3-methoxybrrtanol, l-methoxy-2-propanol, 1-ethoxy-2-propanol and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, methyl 2-hydroxyisobutyrate, ethyl 2-hydroxyisobutyrate, propyl 2-hydroxyisobutyrate, and butyl 2-hydroxyisobutyrate; and lactones such as γ-butyrolactone, which may be used alone or in admixture.

The organic solvent is preferably added in an amount of 100 to 10,000 parts, and more preferably 200 to 8,000 parts by weight per 100 parts by weight of the base polymer.

### Quencher

The resist composition may further comprise a quencher. As used herein, the “quencher” refers to a compound capable of trapping the acid generated from the acid generator for thereby preventing the acid from diffusing to the unexposed region.

The quencher is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy, ether bond, ester bond, lactone ring, cyano, or sulfonic ester bond as described in JP-A 2008-111103, paragraphs [0146]-[0164], and compounds having a carbamate group as described in JP 3790649. Addition of a basic compound may be effective for further suppressing the diffusion rate of acid in the resist film or correcting the pattern profile.

Suitable quenchers also include onium salts such as sulfonium salts, iodonium salts and ammonium salts of sulfonic acids which are not fluorinated at a-position, carboxylic acids or fluorinated alkoxides, as described in JP-A 2008-158339. While an α-fluorinated sulfonic acid, imide acid, and methide acid are necessary to deprotect the acid labile group of carboxylic acid ester, an α-non-fluorinated sulfonic acid, carboxylic acid or fluorinated alcohol is released by salt exchange with an α-non-fluorinated onium salt. The α-non-fluorinated sulfonic acid, carboxylic acid and fluorinated alcohol function as a quencher because they do not induce deprotection reaction.

Exemplary such quenchers include a compound (onium salt of α-non-fluorinated sulfonic acid) having the formula (2), a compound (onium salt of carboxylic acid) having the formula (3), and a compound (onium salt of alkoxide) having the formula (4).

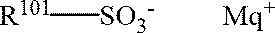

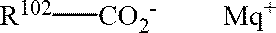

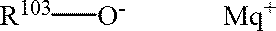

In formula (2), R¹⁰¹ is hydrogen or a C₁-C₄₀ hydrocarbyl group which may contain a heteroatom, exclusive of the hydrocarbyl group in which the hydrogen bonded to the carbon atom at α-position of the sulfo group is substituted by fluorine or fluoroalkyl moiety.

The C₁-C₄₀ hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, n-decyl; C₃-C₄₀ cyclic saturated hydrocarbyl groups such as cyclopentyl, cyclohexyl. cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl; C₂-C₄₀ alkenyl groups such as vinyl, allyl, propenyl. butenyl and hexenyl, C₃-C4₀ cyclic unsaturated aliphatic hydrocarbyl groups such as cyclohexenyl; C₆-C₄₀ aryl groups such as phenyl, naphthyl, alkylphenyl groups (e.g., 2-methylphenyl, 3-methylphenyl, 4-methylphenyl, 4-ethylphenyl, 4-tert-butylphenyl, 4-n-butylphenyl), dialkylphenyl groups (e.g., 2,4-dimethylphenyl and 2,4,6-triisopropylphenyl), alkylnaphthyl groups (e.g., methylnaphthyl and ethylnaphthyl), dialkylnaphthyl groups (e.g., dimethylnaphthyl and diethylnaphthyl); and C₇-C₄₀ aralkyl groups such as benzyl, 1-phenylethyl and 2-phenylethyl.

In the hydrocarbyl group, some or all of the hydrogen atoms may be substituted by a moiety containing a heteroatom such as oxygen, sidfitr, nitrogen or halogen, and some constituent —CH₂— may be replaced by a moiety containing a heteroatom such as oxygen, sulfur or nitrogen, so that the group may contain a hydroxy moiety, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Suitable heteroatom-containing hydrocarbyl groups include heteroaryl groups such as thienyl, 4-hydioxyphenyl, alkoxyphenyl groups such as 4-methoxyphenyl, 3-methoxyphenyl, 2-methoxyphenyl, 4-ethoxyphenyl, 4-tert-butoxyphenyl. 3-tert-butoxyphenyl: alkoxynaphthyl groups such as methoxyuaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl and 2-(2-naphthyl)-2-oxoethyl.

In formula (3), R¹⁰² is a C₁-C₄₀ hydrocarbyl group which may contain a heteroatom. Examples of the hydrocarbyl group R¹⁰² are as exemplified above for the hydrocarbyl group R¹⁰¹. Also included are fluorinated alkyl groups such as trifluoromethyl, trifluoroethyl, 2,2,2-trifluoro-1-methyl-1-hydroxyethyl, 2,2,2-trifluoro-1-(trifluoromethyl)-1-hydroxyethyl, and fluorinated aryl groups such as pentafluorophenyl and 4-trifluoromethylphenyl.

In formula (4), R¹⁰³ is a C₁-C₈ saturated hydrocarbyl group containing at least 3 fluorine atoms or a C₆-C₁₀ aryl group containing at least 3 fluorine atoms, the hydrocarbyl and aryl groups optionally containing a nitro moiety.

In formulae (2), (3) and (4), Mq⁺ is an onium cation. The onium cation is preferably a sulfonium, iodonium or ammonium cation, with the sulfonium cation being more preferred. Suitable sulfonium cations are as exemplified in USP 10,295,904 (JP-A 2017-219836).

A sulfonium salt of iodized benzene ring-containing carboxylic acid having the formula (5) is also useful as the quencher.

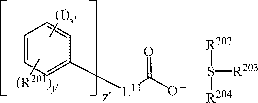

In formula (5), R²⁰¹ is hydroxy, fluorine, chlorine, bromine, amino, nitro, cyano, or a C₁-C₆ saturated hydrocarbyl, C₁-C₆ saturated hydrocarbyloxy, C₂-C₆ saturated hydrocarbylcarbonyloxy, or C₁-C₄ saturated hydrocarbylsulfonyloxy group, in which some or all hydrogen may be substituted by halogen, or —N(R^{201A})—C(═O)—R^{201B}, or —N(R^{201A})—C(═O)—O—R^{201B}, wherein R^{201A} is hydrogen or a C₁-C₆ saturated hydrocarbyl group and R^{201B} is a C₁-C₆ saturated hydrocarbyl or C₂-C₈ unsaturated aliphatic hydrocarbyl group.

In formula (5), x′ is an integer of 1 to 5, y′ is an integer of 0 to 3, and z′ is an integer of 1 to 3. L¹¹ is a single bond, or a C₁-C₂₀ (z′+1)-valent linking group which may contain an ether bond, carbonyl, ester bond, amide bond, sultone ring, lactam ring, carbonate bond, halogen, hydroxy or carboxy moiety or a mixture thereof. The saturated hydrocarbyl, saturated hydrocarbyloxy, saturated hydrocarbylcarbonyloxy and saturated hydrocarbylsulfonyloxy groups may be straight, branched or cyclic. Groups R²⁰¹ may be identical or different when y′ and/or z′ is 2 or 3.

In formula (5), R²⁰², R²⁰³ and R²⁰⁴ are each independently halogen or a C₁-C₂₀ hydrocarbyl group which may contain a heteroatom. The hydrocarbyl group may be saturated or unsaturated and straight, branched or cyclic. Examples thereof are as exemplified for the hydrocarbyl group R⁴ in formula (1). In these hydrocarbyl groups, some or all hydrogen may be substituted by hydroxy, carboxy, halogen, oxo, cyano, nitro, sultone ring, sulfo, or sulfonium salt-containing moiety, or some constituent —CH₂— may be replaced by an ether bond, ester bond, carbonyl, amide bond, carbonate bond or sulfonic ester bond A pair of R²⁰² and R²⁰³ may bond together to form a ring with the sulfur atom to which they are attached.

Examples of the compound having formula (5) include those described in USP 10,295,904 (JP-A 2017-219836) and US 20210188770 (JP-A 2021-091666).

Also useful are quenchers of polymer type as described in USP 7,598,016 (JP-A 2008-239918). The polymeric quencher segregates at the resist film surface and thus enhances the rectangularity of resist pattern. When a protective film is applied as is often the case in the immersion lithography, the polymeric quencher is also effective for preventing a film thickness loss of resist pattern or rounding of pattern top.

Other usefid quenchers include sulfonium salts of betaine structure as described in JP 6848776 and JP-A 2020-037544, fluorine-free methide acids as described in JP-A 2020-055797, sulfonium salts of sulfonamide as described in JP 5807552, and sulfonium salts of iodized sulfonamide as described in JP-A 2019-211751.

The quencher is preferably added in an amount of 0 to 5 parts, more preferably 0 to 4 parts by weight per 100 parts by weight of the base polymer. The quencher may be used alone or in admixture.

### Other Components

In addition to the foregoing components, the resist composition may contain other components such as an acid generator other than the sulfonium salt having formula (1), surfactant, dissolution inhibitor, crosslinker, water repellency improver and acetylene alcohol. Each of the other components may be used alone or in admixture.

The other acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imide acid (imidic acid) or methide acid are preferred. Suitable PAGs include sulfonium salts, iodonium salts, sulfonyldiazomethane, N-sulfonyloxyimide, and oxime-O-sulfonate acid generators. Exemplary PAGs are described in JP-A 2008-111103, paragraphs [0122]-[0142] (USP 7,537,880), JP-A 2018-005224, and JP-A 2018-025789. The other acid generator is preferably used in an amount of 0 to 200 parts, more preferably 0.1 to 100 parts by weight per 100 parts by weight of the base polymer.

Exemplary surfactants are described in JP-A 2008-111103, paragraphs [0165]-[0166]. Inclusion of a surfactant may improve or control the coating characteristics of the resist composition. The surfactant is preferably added in an amount of 0.0001 to 10 parts by weight per 100 parts by weight of the base polymer.

In the embodiment wherein the resist composition is of positive tone, the inclusion of a dissolution inhibitor may lead to an increased difference in dissolution rate between exposed and unexposed areas and a further improvement in resolution. The dissolution inhibitor is typically a compound having at least two phenolic hydroxy groups on the molecule, in which an average of from 0 to 100 mol% of all the hydrogen atoms on the phenolic hydroxy groups are replaced by acid labile groups or a compound having at least one carboxy group on the molecule, in which an average of 50 to 100 mol% of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in USP 7,771,914 (JP-A 2008-122932, paragraphs [0155]-[0178]).

The dissolution inhibitor is preferably added in an amount of 0 to 50 parts, more preferably 5 to 40 parts by weight per 100 parts by weight of the base polymer.

In the case of negative resist compositions, a negative pattern may be formed by adding a crosslinker to reduce the dissolution rate of exposed area. Suitable crosslinkers which can be used herein include epoxy compounds, melamine compounds, guanamine compounds, glycoluril compounds and urea compounds having substituted thereon at least one group selected from among methylol, alkoxymethyl and acyloxymethyl groups, isocyanate compounds, azide compounds, and compounds having a double bond such as an alkenyloxy group. These compounds may be used as an additive or introduced into a polymer side chain as a pendant. Hydroxy-containing compounds may also be used as the crosslinker.

Suitable epoxy compounds include tris(2,3-epoxypropyl) isocyanurate, trimethylohnethane triglycidyl ether, trimethydolpropane triglycidyl ether, and triethylolethane triglycidyl ether. Examples of the melamine compound include hexamethylol melamine, hexamethoxymethyl melamine, hexamethylol melamine compounds having 1 to 6 methylol groups methoxymethylated and mixtures thereof hexamethoxyethyl melamine, hexaacyloxymethyl melamine, hexamethylol melamine compounds having 1 to 6 methylol groups acyloxymethylated and mixtures thereof. Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, tetramethylol guanamine compounds having 1 to 4 methylol groups acyloxymethylated and mixtures thereof. Examples of the glycoluril compound include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Suitable isocyanate compounds include tolylene diisocyanate, diphenylmethane diisocyanate, hexamethylene diisocyanate and cyclohexane diisocyanate. Suitable azide compounds include 1,1′-biphenyl-4,4′-bisazide, 4,4′-methylidenebisazide, and 4,4′-oxybic;azide. Examples of the alkenyloxy group-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

In the negative resist composition, the crosslinker is preferably added in an amount of 0.1 to 50 parts, more preferably 1 to 40 parts by weight per 100 parts by weight of the base polymer.

To the resist composition, a water repellency improver may also be added for improving the water repellency on surface of a resist film. The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer having an amino group or amine salt copolymerized as repeat units may serve as the water repellent additive and is effective for preventing evaporation of acid during PEB, thus preventing any hole pattern opening failure after development. An appropriate amount of the water repellency improver is 0 to 20 parts, preferably 0.5 to 10 parts by weight per 100 parts by weight of the base polymer.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer.

The resist composition of the invention may be prepared by intimately mixing the selected components to form a solution, adjusting so as to meet a predetermined range of sensitivity and film thickness, and filtering the solution. The filtering step is important for reducing the number of defects in a resist pattern after development. The membrane for filtration or filter has a pore size of preferably up to 1 µm, more preferably up to 10 nm, even more preferably up to 5 nm. As the filter pore size is smaller, the number of defects in a small size pattern is reduced. The membrane is typically made of such materials as tetrafluoroethylene, polyethylene, polypropylene, nylon, polyurethane, polycarbonate, polyimide, polyamide-imide, and polysulfone. Membranes of tetrafluoroethylene. polyethylene and polypropylene which have been surface-modified so as to increase an adsorption ability are also useful. Unlike the membranes of nylon, polyurethane, polycarbonate and polyimide possessing an ability to adsorb gel and metal ions due to their polarity, membranes of tetrafluoroethylene, polyethylene and polypropylene which are non-polar do not possess the gel/metal ion adsorption ability in themselves, but can be endowed with the adsorption ability by surface modification with a functional group having polarity. In particular, filters obtained from surface modification of membranes of polyethylene and polypropylene in which pores of a smaller size can be perforated are effective for removing not only submicron particles, but also polar particles and metal ions. A laminate of membranes of different materials or a laminate of membranes having different pore sizes is also useful.

A membrane having an ion exchange ability may also be used as the filter. For example, an ion-exchange membrane capable of adsorbing cations acts to adsorb metal ions for thereby reducing metal impurities.

In the practice of filtration, a plurality of filters may be connected through serial or parallel pipes. The type and pore size of membranes in the plural filters may be the same or different. The filter may be disposed in a conduit between vessels. Alternatively, the filter is disposed in a conduit between inlet and outlet ports of a single vessel so that the solution is filtered while it is circulated.

### Process

The resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

Specifically, the resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, CrN, MoSi₂, SiO₂, MoSi₂ multilayer film, Ta, TaN, TaCN, Ru, Nb, Mo, Mn, Co, Ni or alloys thereof) by a suitable coating technique such as spin coating, roll coating, flow coating, dipping, spraying or doctor coating. The coating is prebaked on a hotplate preferably at a temperature of 60 to 154° C. for 10 seconds to 30 minutes, more preferably at 80 to 120° C. for 30 seconds to 20 minutes. The resulting resist film is generally 0.01 to 2 µm thick.

The resist film is then exposed to a desired pattern of high-energy radiation such as UV, deep-UV, EB, EUV of wavelength 3 to 15 nm, x-ray, soft x-ray, excimer laser light, γ-ray or synchrotron radiation. When UV, deep-UV, EUV, x-ray, soft x-ray, excimer laser light, γ-ray or synchrotron radiation is used as the high-energy radiation, the resist film is exposed thereto through a mask having a desired pattern in a dose of preferably about 1 to 200 mJ/cm², more preferably about 10 to 100 mJ/cm². When EB is used as the high-energy radiation, the resist film is exposed thereto directly or through a mask having a desired pattern in a dose of preferably about 0.1 to 300 µC/cm², more preferably about 0.5 to 200 µC/cm². It is appreciated that the inventive resist composition is suited in micropatteming using KrF excimer laser, ArF excimer laser, EB, EUV, x-ray, soft x-ray, γ-ray or synchrotron radiation, especially in micropatteming using EB or EUV.

After the exposure, the resist film may be baked (PEB) on a hotplate or in an oven preferably at 30 to 150° C. for 10 seconds to 30 minutes, more preferably at 50 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is a 0.1 to 10 wt%, preferably 2 to 5 wt% aqueous solution of tetramethylammoniuin hydroxide (TMAH), tetraethylammonium hydroxide (TEAH), tetrapropylammonium hydroxide (TPAH), or tetrabutylammonium hydroxide (TBAH). In the case of positive tone, the resist film in the exposed area is dissolved in the developer whereas the resist film in the unexposed area is not dissolved. In this way, the desired positive pattern is formed on the substrate. In the case of negative tone, inversely the resist film in the exposed area is insohibilized whereas the resist film in the unexposed area is dissolved away.

In an alternative embodiment, a negative pattern can be obtained from the positive resist composition comprising a base polymer containing acid labile groups by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol. 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyme, heptyne, and octyne. Suitable aromatic solvents include toluene, xylene, ethylbenzene, isopropylbenzene, t-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. All parts are by weight (pbw). THF stands for tetrahydrofuran.

Acid generators PAG-1 to PAG-40 in the form of sulfonium salts used in resist compositions have the structure shown below. PAG-1 to PAG-40 were synthesized by ion exchange between an ammonium salt of fluorinated sulfonic acid providing the anion shown below and a sulfonium chloride providing the cation shown below.

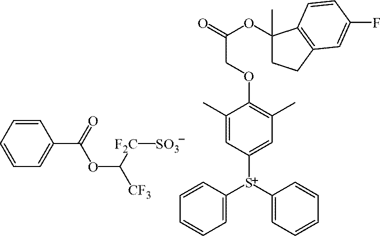

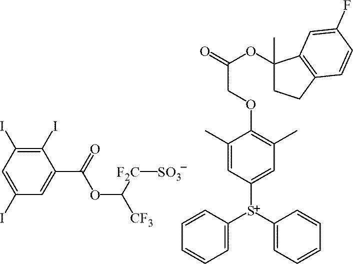

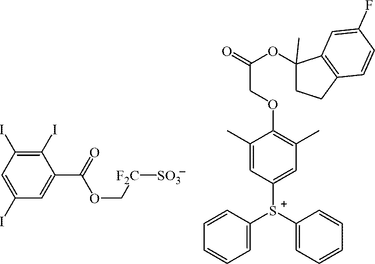

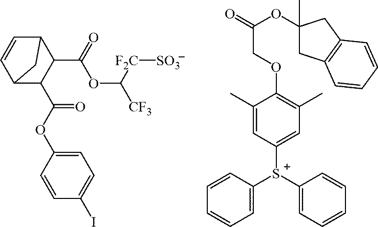

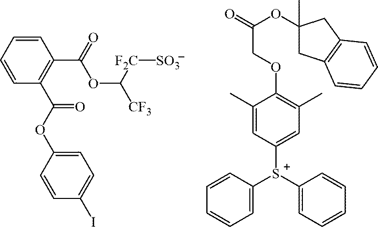

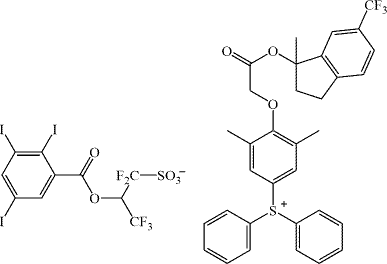

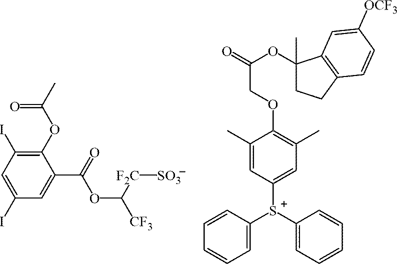

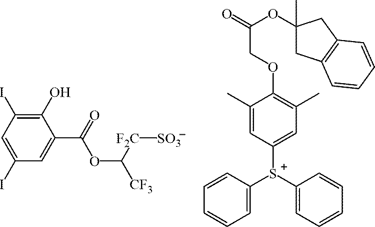

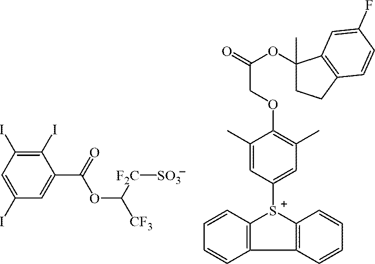

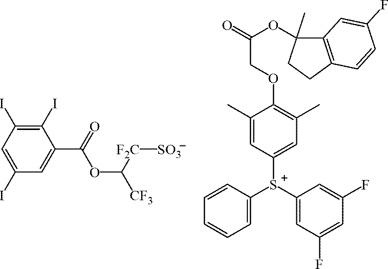

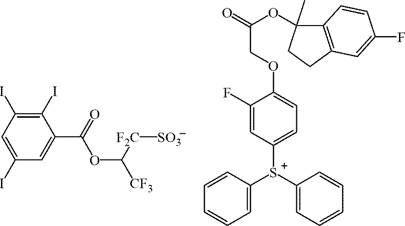

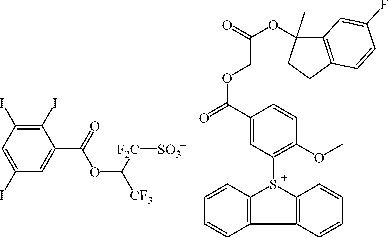

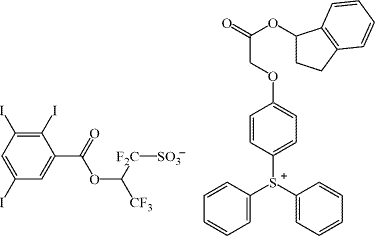

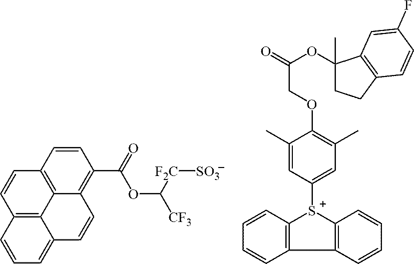

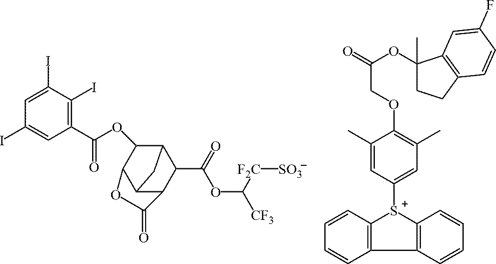

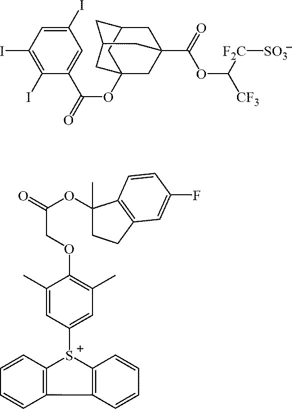

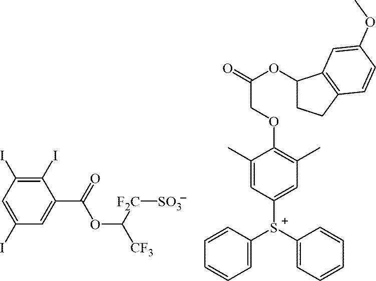

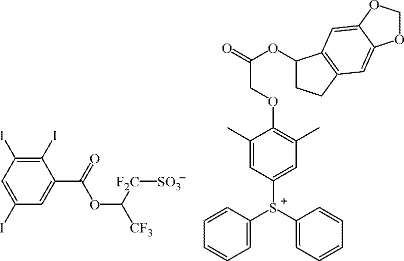

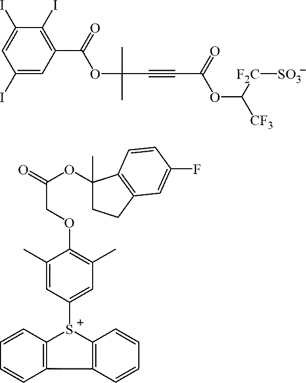

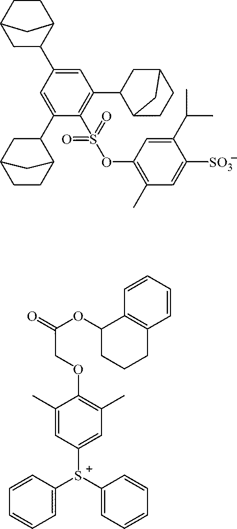

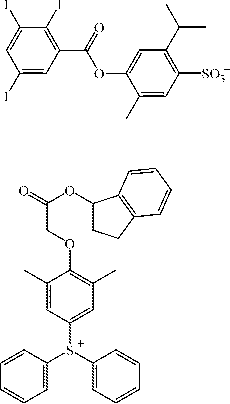

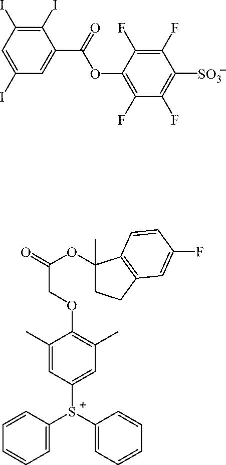

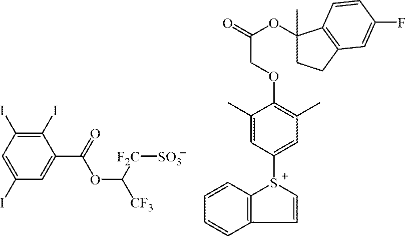

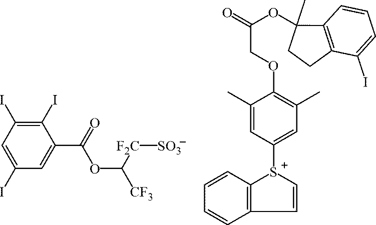

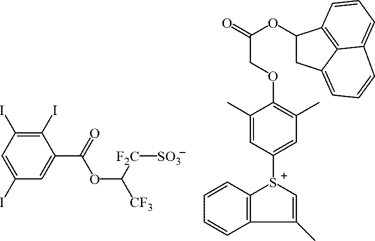

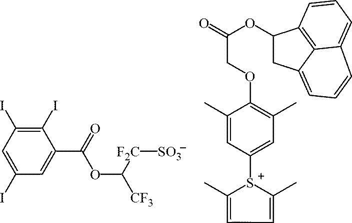

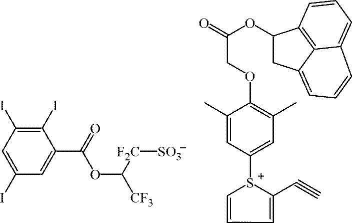

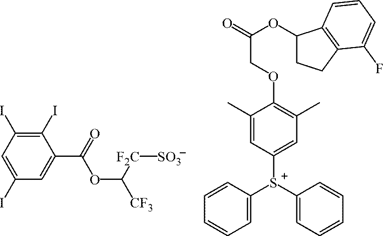

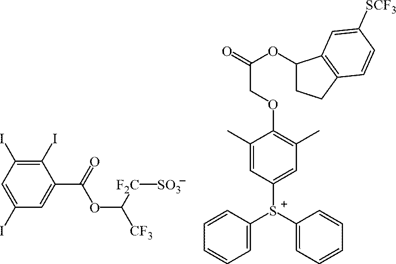

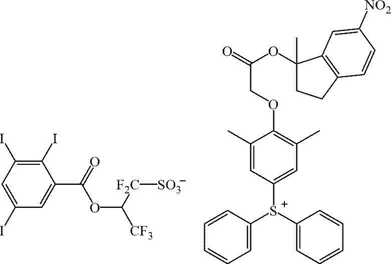

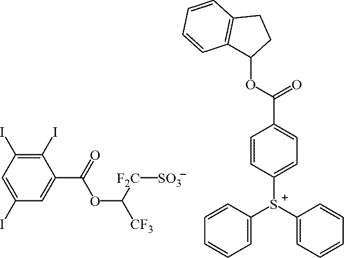

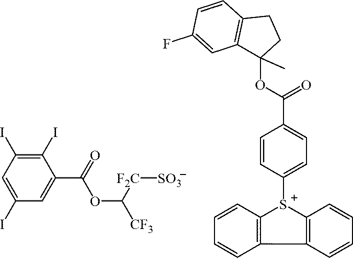

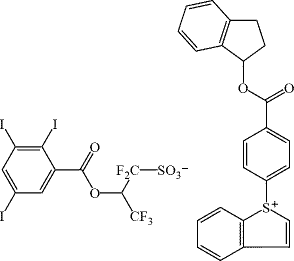

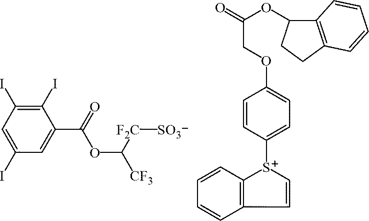

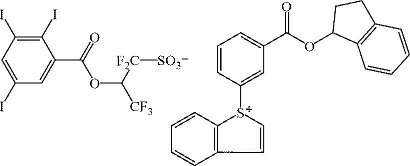

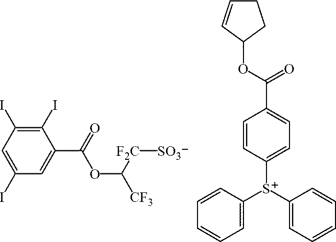

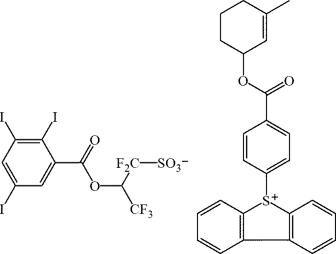

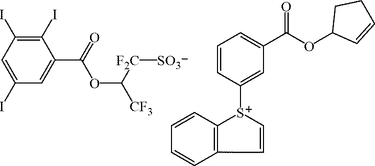

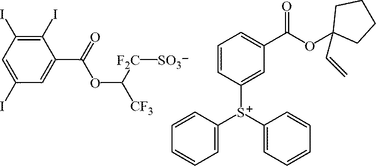

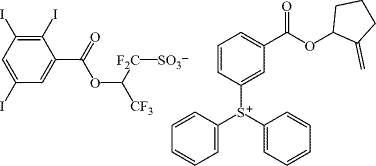

### Synthesis Example

### Synthesis of Base Polymers (Polymers P-1 to P-5)

Base polymers (Polymers P-1 to P-5) of the structure shown below were synthesized by combining selected monomers, effecting copolymerization reaction in THF solvent, pouring the reaction solution into methanol, washing the solid precipitate with hexane, isolating, and drying. The base polymers were analyzed for composition by ¹H-NMR spectroscopy and for Mw and Mw/Mn by GPC versus polystyrene standards using THF solvent.

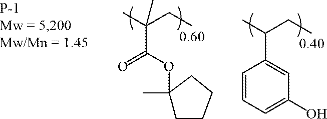

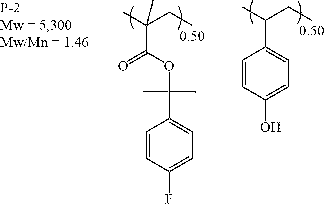

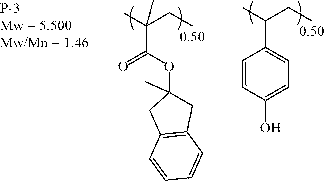

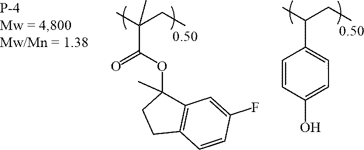

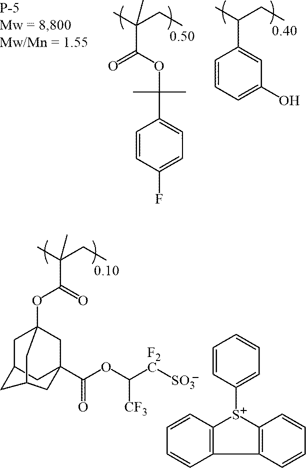

### Examples 1 to 46 and Comparative Examples 1 to 4

### Preparation and Evaluation of Resist Compositions

### Preparation of Resist Compositions

Resist compositions were prepared by dissolving components in a solvent in accordance with the recipe shown in Tables 1 to 4, and filtering the solution through a filter having a pore size of 0.2 µm. The solvent contained 100 ppm of surfactant Polyfox PF-636 (Onmova Solutions, Inc.).

The components in Tables 1 to 4 are identified below.

Organic solvents:
PGMEA (propylene glycol monomethyl ether acetate)
EL (ethyl lactate)
DAA (diacetone alcohol)

Blending acid generators: bPAG-1 and bPAG-2

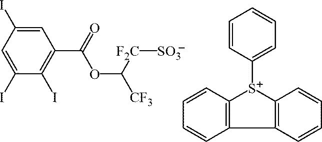

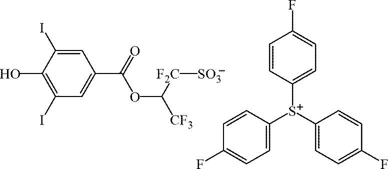

Comparative acid generators: cPAG-1 to cPAG-4

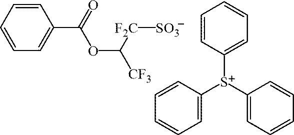

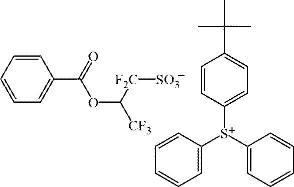

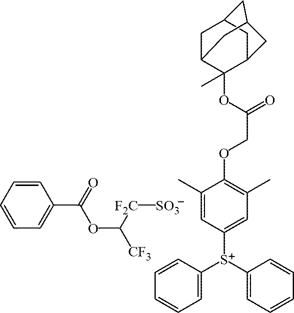

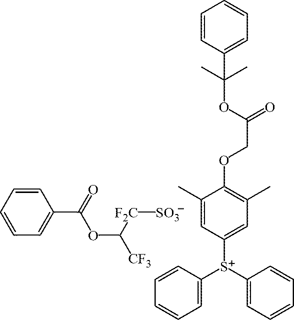

Quenchers: Q-1 and Q-2

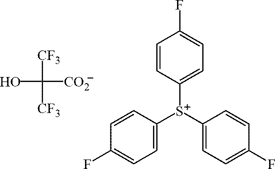

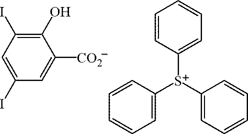

### EUV Lithography Test

Each of the resist compositions in Tables 1 to 4 was spin coated on a silicon substrate having a 20-nm coating of silicon-containing spin-on hard mask SHB-A940 (Shin-Etsu Chemical Co., Ltd., Si content 43 wt%) and prebaked on a hotplate at 105° C. for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern at a pitch 40 nm (on-wafer size) and +20% bias. The resist film was baked (PEB) on a hotplate at the temperature shown in Tables 1 to 4 for 60 seconds and developed in a 2.38 wt% TMAH aqueous solution for 30 seconds to form a hole pattern having a size of 20 nm.

The resist pattern was observed under CD-SEM (CG6300, Hitachi High-Technologies Corp.). The exposure dose that provides a hole pattern having a size of 20 nm is reported as sensitivity. The size of 50 holes printed at that dose was measured, from which a 3-fold value (3σ) of the standard deviation (σ) was computed and reported as CDU.

The resist compositions are shown in Tables 1 to 4 together with the sensitivity and CDU of EUV lithography.

TABLE 1

| | | Polymer (pbw) | Acid generator (pbw) | Quencher (pbw) | Organic solvent (pbw) | PEB temp. (°C) | Sensitivity (mJ/cm²) | CDU (nm) |
|---|---|---|---|---|---|---|---|---|
| Example | 1 | P-1 (100) | PAG-1 (21.2) | Q-1 (5.28) | PGMEA (500) EL (2,000) | 80 | 34 | 3.0 |
| | 2 | P-1 (100) | PAG-2 (30.6) | Q-1 (5.28) | PGMEA (500) EL (2,000) | 80 | 27 | 3.2 |
| | 3 | P-1 (100) | PAG-3 (28.9) | Q-1 (5.28) | PGMEA (500) EL (2,000) | 80 | 32 | 2.8 |
| | 4 | P-1 (100) | PAG-4 (27.3) | Q-1 (5.28) | PGMEA (2,000) DAA (500) | 80 | 34 | 3.2 |
| | 5 | P-1 (100) | PAG-5 (26.9) | Q-1 (5.28) | PGMEA (2,000) DAA (500) | 80 | 33 | 3.0 |
| | 6 | P-1 (100) | PAG-6 (31.9) | Q-1 (5.28) | PGMEA (2,000) DAA (500) | 80 | 32 | 3.0 |
| | 1 | P-1 (100) | PAG-7 (30.6) | Q-1 (5.28) | PGMEA (2,000) DAA (500) | 80 | 33 | 2.9 |
| | 8 | P-1 (100) | PAG-8 (27.4) | Q-1 (5.28) | PGMEA (2,000) DAA (500) | 80 | 32 | 3.0 |
| | 9 | P-1 (100) | PAG-9 (30 6) | Q-1 (5.28) | PGMEA (2,000) DAA (500) | 80 | 34 | 3.1 |
| | 10 | P-1 (100) | PAG-10 (31.5) | Q-1 (5.28) | PGMEA (2,000) DAA (500) | 80 | 30 | 3.3 |
| | 11 | P-1 (100) | PAG-11 (30.4) | Q-1 (5.28) | PGMEA (2,000) DAA (500) | 80 | 32 | 3.2 |
| | 12 | P-1 (100) | PAG-12 (31.3) | Q-1 (5.28) | PGMEA (2,000) DAA (500) | 80 | 29 | 3.2 |
| | 13 | P-2 (100) | PAG-12 (31.6) | Q-1 (5.28) | PGMEA (2,000) DAA (500) | 80 | 28 | 3.1 |
| | 14 | P-3 (100) | PAG-12 (31.3) | Q-1 (5.28) | PGMEA (2,000) DAA (500) | 80 | 27 | 3.0 |
| | 15 | P-4 (100) | PAG-12 (31.3) | Q-1 (5.28) | PGMEA (2,000) DAA (500) | 80 | 30 | 3.1 |
| | 16 | P-5 (100) | PAG-12 (12.3) | Q-2 (6.52) | PGMEA (2,000) DAA (500) | 80 | 26 | 3.3 |
| | 17 | P-2 (100) | PAG-13 (29.1) | Q-1 (5.28) | PGMEA (2,000) DAA (500) | 80 | 32 | 3.1 |
| | 18 | P-2 (100) | PAG-14 (24.2) | Q-1 (5.28) | PGMEA (2,000) DAA (500) | 80 | 33 | 3.0 |
| | 19 | P-2 (100) | PAG-15 (35.1) | Q-1 (5.28) | PGMEA (2,000) DAA (500) | 80 | 30 | 3.2 |
| | 20 | P-2 (100) | PAG-16 (35.0) | Q-1 (5.28) | PGMEA (2,000) DAA (500) | 80 | 29 | 3.1 |

TABLE 2

| | | Polymer (pbw) | Acid generator (pbw) | Quencher (pbw) | Organic solvent (pbw) | PEB temp. (°C) | Sensitivity (mJ/cm²) | CDU (nm) |
|---|---|---|---|---|---|---|---|---|
| Example | 21 | P-2 (100) | PAG-17 (30 5) | Q-1 (5.28) | PGMEA (2,000) DAA (500) | 80 | 31 | 3.2 |
| | 22 | P-2 (100) | PAG-18 (309) | Q-1 (5.28) | PGMEA (2,000) DAA (500) | 80 | 30 | 3.2 |
| | 23 | P-2 (100) | PAG-19 (33.3) | Q-1 (5.28) | PGMEA (2,000) DAA (500) | 80 | 26 | 3.0 |
| | 24 | P-2 (100) | PAG-18 (24 7) PAG-20 (5.8) | Q-1 (5.28) | PGMEA (2,000) DAA (500) | 85 | 31 | 3.0 |
| | 25 | P-2 (100) | PAG-18 (24.7) PAG-21 (6.1) | Q-1 (5.28) | PGMEA (2,000) DAA (500) | 85 | 29 | 3.0 |
| | 26 | P-2 (100) | PAG-22 (31.0) | Q-1 (5.28) | PGMEA (2,000) DAA (500) | 85 | 28 | 3.1 |
| | 27 | P-2 (100) | PAG-23 (29.3) | Q-1 (5.28) | PGMEA (2,000) DAA (500) | 80 | 26 | 3.0 |
| | 28 | P-2 (100) | PAG-24 (32.0) | Q-1 (5.28) | PGMEA (2,000) DAA (500) | 80 | 24 | 3.0 |
| | 29 | P-2 (100) | PAG-25 (29.4) | Q-1 (5.28) | PGMEA (2,000) DAA (500) | 80 | 28 | 2.8 |
| | 30 | P-2 (100) | PAG-13 (17.5) PAG-26 (113) | Q-1 (5.28) | PGMEA (2,000) DAA (500) | 80 | 27 | 2.9 |
| | 31 | P-2 (100) | PAG-13 (17.5) PAG-27 (11.5) | Q-1 (5.28) | PGMEA (2,000) DAA (500) | 80 | 28 | 3.0 |
| | 32 | P-2 (100) | PAG-28 (30.2) | Q-1 (5.28) | PGMEA (2,000) DAA (500) | 80 | 29 | 2.8 |
| | 33 | P-1 (100) | PAG-2 (12.2) bPAG-1 (18.9) | Q-1 (5.28) | PGMEA (2,000) DAA (500) | 80 | 27 | 2.8 |
| | 34 | P-1 (100) | PAG-2 (122) bPAG-2 (18.4) | Q-1 (5.28) | PGMEA (2,000) DAA (500) | 80 | 27 | 2.7 |
| | 35 | P-2 (100) | PAG-29 (32 6) | Q-1 (5.28) | PGMEA (2,000) DAA (500) | 80 | 28 | 2.8 |
| | 36 | P-2 (100) | PAG-30 (31.3) | Q-1 (5.28) | PGMEA (2,000) DAA (500) | 80 | 27 | 2.8 |
| | 37 | P-2 (100) | PAG-31 (28.4) | Q-1 (5.28) | PGMEA (2,000) DAA (500) | 80 | 27 | 2.6 |
| | 38 | P-2 (100) | PAG-32 (29.1) | Q-1 (5.28) | PGMEA (2,000) DAA (500) | 80 | 26 | 2.8 |
| | 39 | P-2 (100) | PAG-33 (27.1) | Q-1 (5.28) | PGMEA (2,000) DAA (500) | 80 | 26 | 2.9 |
| | 40 | P-2 (100) | PAG-34 (27 8) | Q-1 (5.28) | PGMEA (2,000) DAA (500) | 80 | 28 | 2.9 |

TABLE 3

| | | Polymer (pbw) | Acid generator (pbw) | Quencher (pbw) | Organic solvent (pbw) | PEB temp. (°C) | Sensitivity (mJ/cm²) | CDU (nm) |
|---|---|---|---|---|---|---|---|---|
| Example | 41 | P-2 (100) | PAG-35 (27.1) | Q-1 (5.28) | PGMEA (2.000) DAA (500) | 80 | 26 | 2.8 |
| | 42 | P-2 (100) | PAG-36 (27.1) | Q-1 (5.28) | PGMEA (2.000) DAA (500) | 80 | 27 | 2.9 |
| | 43 | P-2 (100) | PAG-37 (27.8) | Q-1 (5.28) | PGMEA (2.000) DAA (500) | 80 | 28 | 2.8 |
| | 44 | P-2 (100) | PAG-38 (25.8) | Q-1 (5.28) | PGMEA (2,000) DAA (500) | 80 | 26 | 3.0 |
| | 45 | P-2 (100) | PAG-39 (27.8) | Q-1 (5.28) | PGMEA (2.000) DAA (500) | 80 | 28 | 2.7 |
| | 46 | P-2 (100) | PAG-40 (27.5) | Q-1 (5.28) | PGMEA (2.000) DAA (500) | 80 | 28 | 2.8 |

TABLE 4

| | | Polymer (pbw) | Acid generator (pbw) | Quencher (pbw) | Organic solvent (pbw) | PEB temp. (°C) | Sensitivity (mJ/cm²) | CDU (nm) |
|---|---|---|---|---|---|---|---|---|
| Comparative Example | 1 | P-1 (100) | cPAG-1 (14.9) | Q-1 (5.28) | PGMEA (2.000) DAA (500) | 80 | 35 | 4.1 |
| | 2 | P-1 (100) | cPAG-2 (16.3) | Q-1 (5.28) | PGMEA (2.000) DAA (500) | 80 | 38 | 4.3 |
| | 3 | P-1 (100) | cPAG-3 (21.15) | Q-1 (5.28) | PGMEA (2.000) DAA (500) | 80 | 40 | 4.2 |
| | 4 | P-1 (100) | cPAG-4 (20.4) | Q-1 (5.28) | PGMEA (2,000) DAA (500) | 80 | 38 | 3.8 |

It is demonstrated in Tables 1 to 4 that resist compositions comprising a sulfonium salt having formula (1) as the acid generator offer a high sensitivity and excellent CDU.

Japanese Patent Application Nos. 2022-010588 and 2022-1 66325 are incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising an acid generator containing a sulfonium salt having the formula (1): 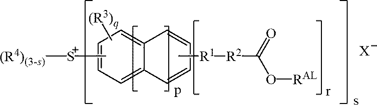
wherein p is 0 or 1, q is an integer of 0 to 4, r is 1 or 2, s is an integer of 1 to 3,
R¹ is a single bond, ether bond, thioether bond or ester bond,
R² is a single bond or a C₁-C₂₀ alkanediyl group which may contain fluorine or hydroxy,
R³ is hydroxy, carboxy, nitro, cyano, fluorine, chlorine, bromine, iodine, amino, or a C₁-C₂₀ saturated hydrocarbyl group, C₁-C₂₀ saturated hydrocarbyloxy group. C₂-C₂₀ saturated hydrocarbylcarbonyloxy group. C₂-C₂₀ saturated hydrocarbyloxycarbonyl group, or C₁-C₄ saturated hydrocarbylsulfonyloxy group, which may contain at least one moiety selected from fluorine, chlorine, bromine, iodine, hydroxy, amino and ether bond,
R⁴ is a C₁-C₂₀ hydrocarbyl group which may contain a heteroatom, in case of s=1, two groups R⁴ may be the same or different and may bond together to form a ring with the sulfur atom to which they are attached,
X⁻ is a non-nucleophilic counter ion.
R^{AL} is an acid labile group having any one of the formulae (AL-1) to (AL-4): 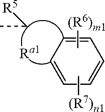 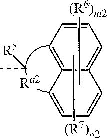 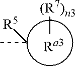 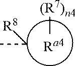
wherein m1 is an integer of 0 to 4, n1 is an integer of 0 to 3, m1+n1 is from 0 to 4, m2 is an integer of 0 to 6, n2 is an integer of 0 to 3, m2+n2 is from 0 to 6, n3 is an integer of 0 to 4, n4 is an integer of 0 to 4,
R⁵ is hydrogen, or a C₁-C₁₂ saturated hydrocarbyl group, C₂₋C₈ alkenyl group. C₂₋C₈ alkynyl group, or C₆-C₁₀ aryl group, which may contain oxygen or sulfur,
R⁶ is fluorine, iodine, an optionally fluorinated C₁-C₄ alkyl group, optionally fluorinated C₁-C₄ alkoxy group, or optionally fluorinated C₁-C₄ alkylthio group,
R⁷ is hydroxy, nitro, cyano, chlorine, bromine, amino, phenyl, a C₂₋C₈ alkoxycarbonyl group, or C₁-C₄ alkylsulfonyl group, in case of n2=2 or 3, two groups R⁷ may bond together to form a ring with the carbon atoms to which they are attached,
R⁸ is a C₂-C₆ alkenyl group,
the arc R^{a1} is a C₂-C₁₀ tetravalent saturated hydrocarbon group which may contain oxygen, sulfur, nitrogen or a C₆-C₁₀ aromatic moiety in a carbon-carbon bond,
the arc R^{a2} is a C₂-C₁₀ tetravalent saturated hydrocarbon group which may contain oxygen, sulfur or nitrogen in a carbon-carbon bond,
the circle R^{a3} is a C₃-C₁₀ (n3+2)-valent alicyclic hydrocarbon group having a double bond in the ring and/or an alkylidene moiety bonded to a carbon atom in the ring,
the circle R^{a4} is a C₃-C₁₀ (n4+2)-valent cyclic saturated hydrocarbon group, and
the broken line designates a valence bond.

2. The resist composition of claim 1 wherein the non-nucleophilic counter ion is a sulfonate, imide or methide anion.

3. The resist composition of claim 1 wherein m1 is an integer of 1 to 4 and m2 is an integer of 1 to 6.

4. The resist composition of claim 1, further comprising an organic solvent.

5. The resist composition of claim 1, further comprising a base polymer.

6. The resist composition of claim 5 wherein the base polymer comprises repeat units having the formula (a1) or repeat units having the formula (a2): 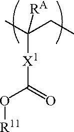 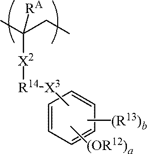
wherein R^{A} is each independently hydrogen or methyl,
X¹ is a single bond, phenylene, naphthylene, or a C₁₋C₁₂ linking group containing at least one moiety selected from an ester bond, ether bond and lactone ring,
X² is a single bond or ester bond,
X³ is a single bond, ether bond or ester bond,
R¹¹ and R¹² are each independently an acid labile group,
R¹³ is fluorine, trifluoromethyl, cyano, a C₁-C₆ saturated hydrocarbyl group, C₁-C₆ saturated hydrocarbyloxy group, C₂-C₇ saturated hydrocarbylcarbonyl group.
C₂-C₇ saturated hydrocarbylcarbonyloxy group, or C₂-C₇ saturated hydrocarbyloxycarbonyl group,
R¹⁴ is a single bond or a C₁-C₆ alkanediyl group in which some constituent —CH₂—may be replaced by an ether bond or ester bond,
a is 1 or 2, b is an integer of 0 to 4, and a+b is from 1 to 5.

7. The resist composition of claim 6 which is a chemically amplified positive resist composition.

8. The resist composition of claim 5 wherein the base polymer comprises repeat units of at least one type selected from repeat units having the formulae (f1) to (f3): 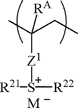 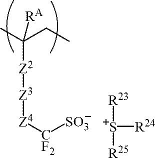 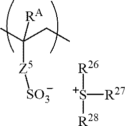
wherein R^{A} is each independently hydrogen or methyl,
Z¹ is a single bond, a C₁-C₆ aliphatic hydrocarbylene group, phenylene, naphthylene or a C₇-C₁₈ group obtained by combining the foregoing, or —O—Z¹¹—, —C(═O)—O—Z¹¹—or —C(—O)—NH—Z¹¹—, wherein Z¹¹ is a C₁-C₆ aliphatic hydrocarbylene group, phenylene, naphthylene or a C₇-C₁₈ group obtained by combining the foregoing, which may contain a carbonyl moiety, ester bond, ether bond or hydroxy moiety,
Z² is a single bond or ester bond,
Z³ is a single bond, —Z³¹—C(—O)—O—, —Z³¹—O— or —Z³¹—O—C(—O)—, wherein Z³¹ is a C₁-C₁₂ hydrocarbylene group, phenylene or a C₇-C₁₈ group obtained by combining the foregoing, which may contain a carbonyl moiety, ester bond, ether bond, iodine or bromine,
Z⁴ is methylene, 2,2,2-trifluoro-1,1-ethanediyl or carbonyl,
Z⁵ is a single bond, methylene, ethylene, phenylene, fluorinated phenylene, trifluoromethyl-substituted phenylene, —O—Z⁵¹—, —C(—O)—O—Z⁵¹—, or —C(—O)—NH—Z⁵¹—, wherein Z⁵¹ is a C₁-C₆ aliphatic hydrocarbylene group, phenylene, fluorinated phenylene, or trifluoromethyl-substituted phenylene group, which may contain a carbonyl moiety, ester bond, ether bond, hydroxy moiety or halogen,
R²¹ to R²⁸ are each independently halogen or a C₁-C₂₀ hydrocarbyl group which may contain a heteroatom, a pair of R²³ and R²⁴, or R²⁶ and R²⁷ may bond together to form a ring with the sulfur atom to which they are attached, and
M⁻ is a non-nucleophilic counter ion.

9. The resist composition of claim 1, further comprising a surfactant.

10. A pattern forming process comprising the steps of applying the resist composition of claim 1 onto a substrate to form a resist film thereon, exposing the resist film to high-energy radiation, and developing the exposed resist film in a developer.

11. The pattern forming process of claim 10 wherein the high-energy radiation is KrF excimer laser, ArF excimer laser, EB, or ELJN,’ of wavelength 3 to 15 nm.
